(19) United States
(12) Patent Application Publication
(10) Pub. No.: US 2016/0054658 A1
(43) Pub. Date: Feb. 25, 2016

(54) PATTERN FORMING METHOD, METHOD FOR MANUFACTURING ELECTRONIC DEVICE, AND ELECTRONIC DEVICE

(71) Applicant: FUJIFILM CORPORATION, Tokyo (JP)

(72) Inventors: Masahiro YOSHIDOME, Shizuoka (JP); Tsukasa YAMANAKA, Shizuoka (JP)

(73) Assignee: FUJIFILM CORPORATION, Tokyo (JP)

(21) Appl. No.: 14/918,949

(22) Filed: Oct. 21, 2015

Related U.S. Application Data
(63) Continuation of application No. PCT/JP2014/061628, filed on Apr. 24, 2014.

(30) Foreign Application Priority Data
May 2, 2013 (JP) 2013-097167

(51) Int. Cl. G03F 7/32; G03F 7/20

(52) U.S. Cl. CPC G03F 7/325; G03F 7/20; G03F 7/2041

(57) ABSTRACT

Provided is a pattern forming method including a step of applying a solvent (S) onto a substrate, a step of applying an actinic ray-sensitive or radiation-sensitive resin composition onto a substrate, on which the solvent (S) has been applied, to form an actinic ray-sensitive or radiation-sensitive film, a step of exposing the actinic ray-sensitive or radiation-sensitive film, and a step of developing the exposed actinic ray-sensitive or radiation-sensitive film with a developing liquid containing an organic solvent to form a negative-type pattern.

### CROSS-REFERENCE TO RELATED APPLICATIONS

This application is Continuation application of PCT Application No. PCT/JP2014/061628, filed Apr. 24, 2014 and based upon and claiming the benefit of priority from Japanese Patent Application No. 2013-097167, filed May 2, 2013, the entire contents of which are incorporated herein by reference.

### BACKGROUND OF THE INVENTION

1. Field of the Invention

The present invention relates to a pattern forming method which is suitably used for a process for manufacturing a semiconductor such as an IC, for the manufacture of a circuit board for a liquid crystal, a thermal head, or the like, and for a lithography process of photofabrication in addition to these; a method for manufacturing an electronic device; and an electronic device.

2. Description of the Related Art

After resists for a KrF excimer laser (248 nm) were developed, a pattern forming method using chemical amplification has been used in lithography for semiconductors.

The wavelength shortening of exposure light sources and realization of high numerical apertures (high NA) for projector lenses have advanced in order to make semiconductor elements finer. Thus, an exposure unit using an ArF excimer laser having a wavelength of 193 nm as a light source has recently been developed. A method in which the space between a projector lens and a sample is filled with a liquid having a high refractive index (hereinafter also referred to as an “immersion liquid”) (that is, a liquid immersion method) has been proposed as a technology for enhancing the resolving power. Further, EUV lithography in which exposure is carried out using an ultraviolet ray even at a short wavelength (13.5 nm) has also been proposed.

Recently, a pattern forming method using a developing liquid containing an organic solvent (hereinafter also referred to as an “organic solvent-based developing liquid”) is also being developed. For example, JP2008-292975A describes a pattern forming method including a step of developing a resist composition including a resin containing a repeating unit having a group capable of decomposing by the action of an acid to generate a polar group, using an organic solvent-based developing liquid.

### SUMMARY OF THE INVENTION

In order to stably form a high-precision fine pattern for manufacturing a high-integration and high-precision electronic device by further making a semiconductor element finer, there is a demand for the inhibition of generation of development residues (scum) or further improvement of the line width uniformity (Critical Dimension Uniformity: CDU) of a resist pattern in the case of forming a resist pattern using an organic solvent-based developing liquid.

Accordingly, the present invention has an object to provide a pattern forming method using an organic solvent-based developing liquid, in which the generation of scum is reduced, and further, a pattern having excellent line width uniformity (CDU) can be formed; a method for manufacturing an electronic device, including the pattern forming method; and an electronic device.

In one embodiment, the present invention is as follows.

[1] A pattern forming method including:

a step of applying a solvent (S) onto a substrate;

a step of applying an actinic ray-sensitive or radiation-sensitive resin composition onto a substrate, on which the solvent (S) has been applied, to form an actinic ray-sensitive or radiation-sensitive film;

a step of exposing the actinic ray-sensitive or radiation-sensitive film; and

a step of developing the exposed actinic ray-sensitive or radiation-sensitive film with a developing liquid containing an organic solvent to form a negative-type pattern.

[2] The pattern forming method as described in [1], in which the actinic ray-sensitive or radiation-sensitive resin composition contains a resin whose solubility in a developing liquid containing an organic solvent is decreased by the action of an acid, a compound capable of generating an acid by irradiation with actinic rays or radiation, and a solvent.

[3] The pattern forming method as described in [1] or [2], in which the vapor pressure of the solvent (S) at 20° C. is 0.7 kPa or less.

[4] The pattern forming method as described in any one of [1] to [3], in which the actinic ray-sensitive or radiation-sensitive film is formed in the state where the solvent (S) applied onto the substrate remains.

[5] The pattern forming method as described in any one of [1] to [4], in which application of the solvent (S) is carried out by ejecting the solvent (S) onto the substrate, and application of the actinic ray-sensitive or radiation-sensitive resin composition is carried out by ejecting the composition onto the substrate; the method includes rotating the substrate at a predetermined time from the completion of ejection of the solvent (S) to the initiation of ejection of the actinic ray-sensitive or radiation-sensitive resin composition to form the liquid film of the solvent (S), the rotational speed is 3000 rpm or less; and further, the time taken from the completion of ejection of the solvent (S) to the initiation of ejection of the actinic ray-sensitive or radiation-sensitive resin composition is 7.0 seconds or less.

[6] The pattern forming method as described in any one of [1] to [5], in which the exposure is carried out through an immersion liquid.

[7] The pattern forming method as described in any one of [1] to [6], in which the exposure is carried out at a wavelength of 193 nm or less.

[8] A method for manufacturing an electronic device, including the pattern forming method as described in any one of [1] to [7].

[9] An electronic device manufactured by the method for manufacturing an electronic device as described in [8].

According to the present invention, it became possible to provide a pattern forming method using an organic solvent-based developing liquid, in which the generation of scum can be inhibited, and further, a pattern having excellent line width uniformity (CDU) can be formed; a method for manufacturing an electronic device, including the pattern forming method; and an electronic device.

### DESCRIPTION OF THE PREFERRED EMBODIMENTS

Hereinafter, embodiments of the present invention will be described in detail.

In citations for a group (atomic group) in the present specification, when the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

Incidentally, “actinic ray(s)” or “radiation” as used herein means, for example, a bright line spectrum of a mercury lamp, far ultraviolet rays represented by an excimer laser, extreme ultraviolet (EUV) rays, X-rays, soft X-rays, electron beams (EB), or the like. In addition, in the present invention, light means actinic rays or radiation.

Furthermore, “exposure” as used herein includes, unless otherwise specified, not only exposure by a mercury lamp, far ultraviolet rays represented by an excimer laser, X-rays, EUV light, or the like, but also writing by particle rays such as electron beams and ion beams.

First, the pattern forming method according to the present invention will be described, and then, the actinic ray-sensitive or radiation-sensitive resin composition used in this pattern forming method will be described.

<Pattern Forming Method>

The pattern forming method according to the present invention includes:

a step of applying a solvent (S) onto a substrate,
a film forming step of applying an actinic ray-sensitive or radiation-sensitive resin composition onto a substrate, on which the solvent (S) has been applied, to form an actinic ray-sensitive or radiation-sensitive film,
an exposing step of exposing the actinic ray-sensitive or radiation-sensitive film, and
   a developing step of developing the exposed actinic ray-sensitive or radiation-sensitive film with a developing liquid containing an organic solvent to form a negative-type pattern.

In the pattern forming method according to the present invention, it becomes possible that the generation of scum is inhibited, and further, a pattern having improved line width uniformity is formed, by including a step of applying a predetermined solvent (S) onto a substrate (hereinafter also referred to as a “pre-wet step” or the like) before applying an actinic ray-sensitive or radiation-sensitive resin composition onto the substrate.

In the formation of a negative-type pattern using an organic solvent-based developing liquid, scum causes the delay of the dissolution in the organic solvent-based developing liquid at a bottom part in the unexposed areas of the actinic ray-sensitive or radiation-sensitive film, from which residues are generated. Since the pattern forming method of the present invention includes the pre-wet step, the actinic ray-sensitive or radiation-sensitive film is formed in the state where the solvent remains on the substrate, and as a result, it is presumed that the solubility in the organic solvent-based developing liquid in the unexposed areas of the actinic ray-sensitive or radiation-sensitive film is improved and thus, scum is reduced.

Furthermore, the solvent used in the pre-wet step is specified as a “solvent (S)”, and is clearly distinguished from, for example, solvents used in a developing step or rinsing step as described later, or solvents which can be contained in the actinic ray-sensitive or radiation-sensitive resin composition used in the pattern forming method of the present invention.

In one embodiment, the pattern forming method of the present invention may include a heating step, or may further include multiple heating steps.

Moreover, the pattern forming method of the present invention may include multiple exposing steps.

Furthermore, the pattern forming method of the present invention may include multiples developing steps, and in this case, a step of carrying out development using an organic developing liquid may be combined with a step of carrying out development using an alkali developing liquid.

In addition, the pattern forming method of the present invention may further include a rinsing step of carrying out cleaning using a rinsing liquid after the developing step.

Hereinafter, the respective steps will be described.

<Step of Applying Solvent (S)>

As a solvent (S) that can be used in the pre-wet step, any solvent can be used without particular limitation as long as the actinic ray-sensitive or radiation-sensitive resin composition as described later (hereinafter also referred to as the “composition of the present invention” or the like) is dissolved in the solvent. In one embodiment of the present invention, the solvent (S) has a vapor pressure at room temperature (20° C.) is preferably 0.7 kPa or less, more preferably 0.4 kPa or less, and still more preferably 0.3 kPa or less. As such, if the vapor pressure of the solvent (S) is a predetermined value or less, the solvent (S) remains in a sufficient amount for improving the solubility in the organic solvent-based developing liquid in the unexposed areas of the actinic ray-sensitive or radiation-sensitive film when the composition of the present invention is applied onto the substrate in the next step, and thus such a vapor pressure is preferred.

Examples of the solvent (S) include methyl 3-methoxypropionate (MMP), methyl amyl ketone (MAK), ethyl lactate (EL), propylene glycol monomethyl ether acetate (PGMEA), cyclohexanone, normal pentyl acetate, ethylene glycol, isopentyl acetate, butyl acetate, propylene glycol monomethyl ether (PGME), 1-octanone, 2-octanone, 1-nonanone, 2-nonanone, acetone, 4-heptanone, 1-hexanone, 2-hexanone, diisobutyl ketone, methylcyclohexanone, phenyl acetone, methyl ethyl ketone, methyl isobutyl ketone, acetyl acetone, acetonylacetone, ionone, diacetonyl alcohol, acetyl carbinol, acetophenone, methyl naphthyl ketone, isophorone, propylene carbonate, methyl acetate, ethyl acetate, isopropyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, 4-methyl-2-pentanol, n-heptyl alcohol, n-octyl alcohol, and n-decanol, glycol-based solvents such as ethylene glycol, diethylene glycol, and triethylene glycol, ethylene glycol monomethyl ether, propylene glycol monomethyl ether, ethylene glycol monoethyl ether, propylene glycol monoethyl ether, diethylene glycol monomethyl ether, triethylene glycol monoethyl ether, methoxymethylbutanol, dioxane, tetrahydrofuran, N-methyl-2-pyrrolidone, N,N-dimethylacetamide, N,N-dimethyl formamide, hexamethylphosphoric triamide, 1,3-dimethyl-2-imidazolidinone, toluene, xylene, pentane, hexane, octane, and decane. From the viewpoint of the vapor pressure as described above, MMP, MAK, EL, PGME, cyclohexanone, normal pentyl acetate, and ethylene glycol are preferred, MMP, MAK, EL, and PGME are more preferred, and MMP and MAK are still more preferred. In the pattern forming method of the present invention, the solvent (S) may be used alone or as a mixture of two or more kinds thereof.

A method for applying the solvent (S) onto the substrate is not particularly limited. For example, a liquid film of the solvent (S) may be formed by fixing the substrate in a spinner chuck by adsorption, ejecting the solvent (S) on the substrate at a wafer center position, and then rotating the substrate with a spinner, or by applying the solvent (S) while rotating the substrate. The liquid film thus formed may be non-continuous.

In the pattern forming method of the present invention, it is important that the composition of the present invention is applied onto the substrate in the next step in the state where the solvent (S) remains on the substrate, and thus, an actinic ray-sensitive or radiation-sensitive film is formed.

From this viewpoint, for example, the time taken from the completion of ejection of the solvent (S) to the initiation of ejection of the composition of the present invention is preferably 7.0 seconds or less, more preferably 4.0 seconds or less, and still more preferably 2.0 seconds or less. Further, in the case where the substrate is rotated so as to form a coating film of the solvent (S) at a predetermined time taken from the completion of ejection of the solvent (S) to the initiation of ejection of the composition of the present invention, the rotational speed is preferably 3000 rpm or less, more preferably 1500 rpm or less, and still more preferably 500 rpm or less. Further, the substrate may be rotated from the time of the initiation of ejection of the solvent (S) as described above, or may also be continuously rotated even after the initiation of the initiation of the composition of the present invention.

In the present invention, the substrate onto which the solvent (S) is applied is not particularly limited, and a substrate generally used in a process for manufacturing an inorganic substrate such as silicon, SiN, SiO₂, and TiN, an application-based inorganic substrate such as SOG, or a semiconductor such as an IC, or a process for manufacturing a circuit board such as a liquid crystal and a thermal head, and further, a lithography process for photofabrication in addition to these can be used.

Furthermore, the substrate surface may be treated with hexamethyldisilazane (HMDS) before the solvent (S) is applied onto the substrate. By carrying out the treatment with HMDS, it is possible to hydrophobilize the substrate to improve the applicability of the solvent, and therefore, from the viewpoint, it is preferable to carry out the treatment with HMDS.

Furthermore, if desired, an antireflection film formed on the substrate may be used as the substrate onto which the solvent (S) is applied. As the antireflection film, a known organic or inorganic antireflection film can be appropriately used.

In the pattern forming method of the present invention, a step of applying the actinic ray-sensitive or radiation-sensitive resin composition onto the substrate onto which the solvent (S) has been applied to form an actinic ray-sensitive or radiation-sensitive film, a step of exposing the actinic ray-sensitive or radiation-sensitive film, and a step of developing the actinic ray-sensitive or radiation-sensitive film with a developing liquid containing an organic solvent can be carried out by a generally known method.

<Film Forming Step>

For the application of the actinic ray-sensitive or radiation-sensitive resin composition onto the substrate onto which the solvent (S) has been applied, for example, the actinic ray-sensitive or radiation-sensitive resin composition may be applied onto the substrate at a wafer center position, and then the substrate may be rotated by a spinner to form an actinic ray-sensitive or radiation-sensitive film, in the same manner as the application of the above-described solvent (S), or the actinic ray-sensitive or radiation-sensitive resin composition may be applied while rotating the substrate to form an actinic ray-sensitive or radiation-sensitive film.

The rotational speed of the substrate in this case may be usually 4000 rpm or less, but from the viewpoint of the uniformity of the actinic ray-sensitive or radiation-sensitive film, it is preferable that the film is rotated at 900 rpm or less for a predetermined time, and then rotated at 1000 rpm or more for a predetermined time.

<Heating Step>

In one embodiment, it is also preferable that the pattern forming method of the present invention further includes a preheating (PB; Prebake) step after the film formation and before the exposing step.

Furthermore, in another embodiment, the pattern forming method of the present invention preferably also includes a post exposure heating (PEB; Post Exposure Bake) step after the exposing step and before the developing step.

Both PB and PEB are carried out at a heating temperature of preferably 70° C. to 130° C., and more preferably from 80° C. to 120° C.

For both PB and PEB, the time for the heating treatment is preferably from 30 seconds to 300 seconds, more preferably from 30 seconds to 180 seconds, and still more preferably from 30 seconds to 90 seconds.

The heating can be carried out using a device installed in an ordinary exposure-and-development machine, or may also be carried out using a hot plate or the like.

The baking accelerates the reaction in the exposed areas, and thus, the sensitivity and the pattern profile are enhanced.

<Exposing Step>

The light source wavelength used in the exposing method of the present invention is not particularly limited, and examples thereof include infrared rays, visible light, ultraviolet rays, far ultraviolet rays, extreme ultraviolet rays, X-rays, and electron beams, for example, far ultraviolet rays at a wavelength of preferably 250 nm or less, more preferably 220 nm or less, and particularly preferably 1 nm to 200 nm, specifically, a KrF excimer laser (248 nm), an ArF excimer laser (193 nm), an F₂ excimer laser (157 nm), X-rays, EUV (13 nm), electron beams, and the like, among which the KrF excimer laser, the ArF excimer laser, EUV, or the electron beams are preferred, and the ArF excimer laser is more preferred.

Furthermore, in the exposing step of the present invention, a liquid immersion exposure method can be applied. The liquid immersion exposure method can be combined with super-resolution technology such as a phase shift method and a modified illumination method.

The immersion liquid is preferably a liquid which is transparent to exposure wavelength and has a minimum temperature coefficient of a refractive index so as to minimize the distortion of an optical image projected on the resist film. In particular, in the case where the exposure light source is an ArF excimer laser (wavelength; 193 nm), water is preferably used in terms of easy availability and easiness of handling, in addition to the above-described viewpoints.

In the case of using water, an additive (liquid) that decreases the surface tension of water while increasing the interfacial activity may be added at a slight proportion. It is preferable that this additive does not dissolve a resist layer on a wafer, and gives a negligible effect on an optical coat at the undersurface of a lens element.

Such an additive is preferably, for example, an aliphatic alcohol having a refractive index substantially equal to that of water, and specific examples thereof include methyl alcohol, ethyl alcohol, and isopropyl alcohol. By adding an alcohol having a refractive index substantially equal to that of water, even when the alcohol component in water is evaporated and its content concentration is changed, an advantage in that the change in the refractive index of the liquid as a whole can be advantageously made very small is obtained.

On the other hand, in the case where materials opaque to light at 193 nm or impurities having a great difference in the refractive index from water are incorporated, the distortion of an optical image projected on a resist is caused. Therefore, the water to be used is preferably distilled water. Further, pure water after filtration through an ion exchange filter or the like may also be used.

The electrical resistance of water used as the immersion liquid is preferably 18.3 MΩcm or more, and Total Organic Concentration (TOC) is preferably 20 ppb or less. The water is preferably one which has been subjected to a deaeration treatment.

In addition, the lithography performance can be enhanced by increasing the refractive index of the immersion liquid. From such a viewpoint, an additive for increasing the refractive index, for example, may be added to water, or heavy water (D₂O) may be used in place of water.

The receding contact angle of the resist film formed using the actinic ray-sensitive or radiation-sensitive resin composition in the present invention is preferably 70° or more at 23±3° C. at a humidity of 45±5%, which is appropriate in the case of the exposure through a liquid immersion medium. The receding contact angle is more preferably 75° or more, and still more preferably from 75° to 85°.

When the receding contact angle is extremely small, the resist film cannot be appropriately used in the case of the exposure through a liquid immersion medium, and the effect of suppressing any residual water (watermark) defect cannot sufficiently exerted. For the realization of a desirable receding contact angle, it is preferable to incorporate the hydrophobic resin (HR) in the actinic ray-sensitive or radiation-sensitive resin composition. Alternatively, the receding contact angle may be increased by forming a coating layer (known as a “top coat”) with the hydrophobic resin composition on the resist film.

In the liquid immersion exposing step, the exposure head scans a wafer at a high speed, and follows the movement due to formation of the exposure pattern, and it is necessary for the immersion liquid to move on the wafer. Thus, the contact angle of the immersion liquid with respect to the resist film in the dynamic state becomes important, liquid droplets do not remain, and thus, the resist is required to have performance following the high-speed scan of the exposure head.

In the case of carrying out the liquid immersion exposure, a step of cleaning the surface of the film at any at least one point in time after the film forming step and before the exposing step; and after the exposing step and before the post exposure heating (PEB) step. By including this step, it becomes possible to inhibit generation of defects caused by the immersion liquid (aqueous immersion) remaining on the resist surface by the liquid immersion exposure (hereinafter also referred to as “residual moisture defects”).

This cleaning step is carried out by, for example, ejecting a pure water rinse while rotating the wafer at a predetermined speed on which the actinic ray-sensitive or radiation-sensitive film has been formed, and a paddle of the pure water rinse may be formed.

In addition, after the cleaning step, a step of removing pure water by inert gas blowing and/or spin drying may be included.

<Developing Step>

The developing step in the pattern forming method of the present invention is carried out using a developing liquid containing an organic solvent (organic developing liquid). Thus, a negative-type pattern is formed.

As the organic developing liquid, polar solvents such as a ketone-based solvent, an ester-based solvent, an alcohol-based solvent, an amide-based solvent, and an ether-based solvent, and hydrocarbon-based solvents can be used.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, and propyl lactate.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; and glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether-based solvent include, in addition to the glycol ether-based solvents, dioxane and tetrahydrofuran.

Examples of the amide-based solvent include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene, and aliphatic hydrocarbon-based solvents such as pentane, hexane, octane, and decane.

In particular, the organic developing liquid is preferably a developing liquid containing at least one organic solvent selected from the group consisting of a ketone-based solvent and an ester-based solvent, and particularly preferably a developing liquid containing butyl acetate as the ester-based solvent and methyl amyl ketone (2-heptanone) as the ketone-based solvent.

A plurality of these solvents may be mixed, or the solvent may be used by mixing it with a solvent other than ones described above or with water. However, in order to exhibit the effects of the present invention sufficiently, the moisture content ratio of the entire developing liquid is preferably less than 10% by mass, and it is more preferable to contain substantially no moisture content.

That is, the amount of the organic solvent used with respect to the organic developing liquid is preferably from 90% by mass to 100% by mass, and more preferably from 95% by mass to 100% by mass, with respect to the entire amount of the developing liquid.

The vapor pressure of the organic developing liquid at 20° C. is preferably 5 kPa or less, more preferably 3 kPa or less, and particularly preferably 2 kPa or less. By setting the vapor pressure of the organic developing liquid to 5 kPa or less, the evaporation of the developing liquid on a substrate or in a development cup is inhibited, and the temperature uniformity within a wafer plane is improved, whereby the dimensional uniformity within a wafer plane is enhanced.

An appropriate amount of a surfactant may be added to the organic developing liquid, if desired.

The surfactant is not particularly limited, and for example, an ionic or nonionic fluorine- and/or silicon-based surfactant can be used. Examples of such a fluorine- and/or silicon-based surfactant include surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540), JP1995-230165A (JP-H07-230165A), JP1996-62834A (JP-H08-62834A), JP1997-54432A (JP-H09-54432A), JP1997-5988A (JP-H09-5988A), and U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, among which the nonionic surfactant is preferred. The nonionic surfactant is not particularly limited, but a fluorine-based surfactant or a silicon-based surfactant is more preferably used.

The amount of the surfactant used is usually from 0.001% by mass to 5% by mass, preferably from 0.005% by mass to 2% by mass, and more preferably from 0.01% by mass to 0.5% by mass, with respect to the entire amount of the developing liquid.

As the developing method, for example, a method in which a substrate is immersed in a tank filled with a developing liquid for a certain period of time (a dip method), a method in which a developing liquid is heaped up to the surface of a substrate by surface tension and developed by resting for a certain period of time (a paddle method), a method in which a developing liquid is sprayed on the surface of a substrate (a spray method), a method in which a developing liquid is continuously ejected on a substrate rotated at a constant rate while scanning a developing liquid ejecting nozzle at a constant rate (a dynamic dispense method), or the like, can be applied.

If a variety of the developing methods as described above include a step in which a developing liquid is ejected from a development nozzle of a development apparatus toward a resist film, the ejection pressure of the developing liquid ejected (a flow rate per unit area of the developing liquid ejected) is preferably 2 mL/sec/mm² or less, more preferably 1.5 mL/sec/mm² or less, and still more preferably 1 mL/sec/mm² or less. The lower limit of the flow rate is not particularly limited, but is preferably 0.2 mL/sec/mm² or more, taking consideration of throughput. The details of this are particularly described in paragraphs “0022” to “0029” of JP2010-232550A, and the like.

In addition, after the step of carrying out development using a developing liquid containing an organic solvent, a step of stopping the development while replacing the solvent with another solvent may be carried out.

Furthermore, in the case where the pattern forming method of the present invention includes multiple developing steps, a step of carrying out development using an alkali developing liquid may be combined with a step of carrying out development using an organic developing liquid. Thus, obtaining a pattern corresponding to ½ of the spatial frequency of an optical image can be expected, as described in FIGS. 1 to 11 in U.S. Pat. No. 8,227,183B.

In the case where the pattern forming method of the present invention includes a step of carrying out development using an alkali developing liquid, the usable alkali developing liquid is not particularly limited, but generally, a 2.38%-by-mass aqueous tetramethylammonium hydroxide solution is preferred. Appropriate amounts of an alcohol and a surfactant can also be added to an aqueous alkali solution, and used.

The alkali concentration of the alkali developing liquid is usually 0.1% by mass to 20% by mass.

The pH value of the alkali developing liquid is usually in the range of 10.0 to 15.0.

Pure water is used as the rinsing liquid in the rinsing treatment carried out after the alkali development, or may also be used after adding an appropriate amount of a surfactant thereto.

<Rinsing Step>

It is preferable to include a rinsing step of carrying out cleaning using a rinsing liquid after carrying out the development using an organic developing liquid. The rinsing liquid is not particularly limited as long as it does not dissolve the resist pattern, and a solution containing an ordinary organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent are the same as those described for the developing liquid containing an organic solvent as described above.

In one embodiment of the present invention, after the developing step, it is preferable to carry out a step of carrying out cleaning using a rinsing liquid containing at least one organic solvent selected from the group consisting of a ketone solvent, an ester solvent, an alcohol solvent, and an amide solvent; it is more preferable to carry out a step of carrying out cleaning using a rinsing liquid containing an alcohol-based solvent or an ester-based solvent; it is particularly preferable to carry out a step of cleaning using a rinsing liquid containing a monohydric alcohol; and it is most preferable to carry out a step of cleaning using a rinsing liquid containing a monohydric alcohol having 5 or more carbon atoms.

Examples of the monohydric alcohol used in the rinsing step include linear, branched, or cyclic monohydric alcohols. Specifically, 1-hexanol, 2-hexanol, 4-methyl-2-pentanol, 1-pentanol, 3-methyl-1-butanol, or the like can be used.

A plurality of these respective solvents may be mixed, or the solvent may be used by mixing it with an organic solvent other than ones described above.

The moisture content of the rinsing liquid is preferably 10% by mass or less, more preferably 5% by mass or less, and most preferably 3% by mass or less. By setting the moisture content to 10% by mass or less, good developing characteristics can be obtained.

The vapor pressure of the rinsing liquid used after the step of carrying out development using a developing liquid containing an organic solvent at 20° C. is preferably from 0.05 kPa to 5 kPa, more preferably from 0.1 kPa to 5 kPa, and most preferably from 0.12 kPa to 3 kPa. By setting the vapor pressure of the rinsing liquid to a range from 0.05 kPa to 5 kPa, the temperature uniformity within a wafer plane is improved, and further, the dimensional uniformity within a wafer plane is enhanced by inhibition of swelling due to the penetration of the rinsing liquid.

The rinsing liquid can also be used after adding an appropriate amount of a surfactant thereto.

In the rinsing step, the wafer which has been subjected to development using a developing liquid containing an organic solvent is subjected to a cleaning treatment using the rinsing liquid containing an organic solvent. A method for the cleaning treatment is not particularly limited, and for example, a method in which a rinsing liquid is continuously ejected on a substrate rotated at a constant rate (a rotation application method), a method in which a substrate is immersed in a bath filled with a rinsing liquid for a certain period of time (a dip method), a method in which a rinsing liquid is sprayed on a substrate surface (a spray method), or the like, can be applied. Among these, a method in which a cleaning treatment is carried out using the rotation application method, a substrate is rotated at a rotational speed of 2000 rpm to 4000 rpm after cleaning, thereby removing the rinsing liquid from the substrate, is preferred. Further, it is preferable that a heating treatment (Post Bake) is included after the rinsing step. The residual developing liquid and the rinsing liquid between and inside the patterns are removed by the bake. The heating step after the rinsing step is usually carried out at 40° C. to 160° C., and preferably at 70° C. to 95° C., and typically for 10 seconds to 3 minutes, and preferably for 30 seconds to 90 seconds.

It is preferable that the organic developing liquid, the alkali developing liquid, and/or the rinsing liquid, which are used in the present invention, have a small content of various fine particles or impurities such as metal elements. In order to obtain such a chemical solution with small amounts of impurities, it is preferable to reduce the impurities, for example, by producing the chemical solution in a clean room or performing filtration through various filters such as a Teflon (registered mark) filter, a polyolefin-based filter, and an ion exchange filter. With regard to the metal element, any of metal element concentrations of Na, K, Ca, Fe, Cu, Mg, Mn, Li, Al, Cr, Ni, and Zn is preferably 10 ppm or less, and more preferably 5 ppm or less.

In addition, the container for storing the developing liquid or the rinsing liquid is not particularly limited, and a container made of a polyethylene resin, a polypropylene resin, a polyethylene-polypropylene resin, or the like, which is used in the application of electronic materials, may be suitably used, but in order to reduce the impurities eluted from the container, it is also preferable to select a container which is less likely to cause elution of a component from the inner wall of the container to the chemical solution. Examples of such a container include a container where the inner wall of the container is formed of a perfluororesin (for example, a FluoroPure PFA composite drum (inner surface coming into contact with a liquid; a PFA resin lining) manufactured by Entegris, and a steel-made drum (inner surface coming into contact with a liquid; and a zinc phosphate coat) manufactured by JFE).

Generally, the pattern obtained by the pattern forming method of the present invention is suitably used as, for example, an etching mask in a semiconductor device, but may also be used in other applications. Examples of other such applications include applications for guide pattern formation in Directed Self-Assembly (DSA) (see, for example, ACS Nano, Vol. 4, No. 8, pp. 4815-4823), that is, a so-called core material (core) in a spacer process (see, for example, JP1991-270227A (JP-H03-270227A) and JP2013-164509A).

The present invention also relates to a method for manufacturing an electronic device, including the pattern forming method of the present invention, and an electronic device manufactured by the manufacturing method. The electronic device of the present invention is suitably mounted on electric/electronic equipment (home electronics, OA/media-related equipment, optical equipment, telecommunication equipment, and the like).

<Actinic Ray-Sensitive or Radiation-Sensitive Resin Composition>

The actinic ray-sensitive or radiation-sensitive resin composition used in the pattern forming method according to the present invention (hereinafter also referred to as the “composition of the present invention”) contains a resin whose solubility in a developing liquid containing at least one organic solvent is decreased by the action of an acid, a compound capable of generating an acid by irradiation with actinic rays or radiation, and a solvent as the essential components.

[1] Resin Whose Solubility in Developing Liquid Containing Organic Solvent by Action of Acid Is Decreased

Examples of the resin whose solubility in a developing liquid containing an organic solvent is decreased by the action of an acid include a resin (hereinafter also referred to as an “acid-decomposable resin” or a “resin (A)”) having a group capable of decomposing by an action of an acid to generate a polar group (hereinafter also referred to as an “acid-decomposable group”), on either one or both of the main chain and the side chain of the resin.

It is preferable that the acid-decomposable group has a structure in which a polar group is protected by a group capable of leaving by decomposing by the action of an acid. Preferred examples of the polar group include a carboxyl group, a phenolic hydroxyl group, a fluorinated alcohol group (preferably a hexafluoroisopropanol group), and a sulfonic acid group.

As the acid-decomposable group, a group substituted with a group having a hydrogen atom capable of leaving by an acid is preferred.

Examples of the group capable of leaving by an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ to R₀₂ each independently represent a hydrogen atom, an alkyl group, a cycloalkyl group, an aryl group, an aralkyl group, or an alkenyl group.

The acid-decomposable group is preferably a cumyl ester group, an enol ester group, an acetal ester group, a tertiary alkyl ester group, or the like, and more preferably a tertiary alkyl ester group. Further, in the case where the pattern forming method of the present invention is carried out by exposure with KrF light or EUV light, or irradiation with electron beams, an acid-decomposable group having a phenolic hydroxyl group protected by an acid elimination group may be used.

The resin (A) preferably has a repeating unit having an acid-decomposable group.

Examples of this repeating unit include the following ones.

In the specific examples, Rx represents a hydrogen atom, CH₃, CF₃, or CH₂OH. Rxa and Rxb each represent an alkyl group having 1 to 4 carbon atoms. Xa₁ represents a hydrogen atom, CH₃, CF₃, or CH₂OH. Z represents a substituent, and in the case of being present in plural numbers, plural numbers of Z's may be the same as or different from each other. p represents 0 or a positive integer. Specific examples and preferred examples of Z are the same as the specific examples and the preferred examples of the substituents that each group such as Rx₁ to Rx₃ may have.

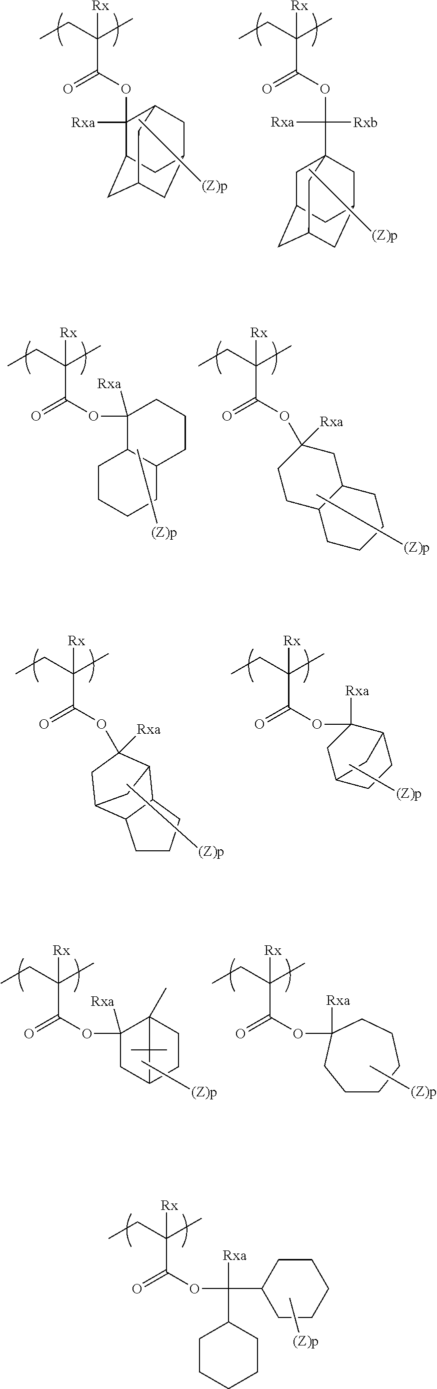

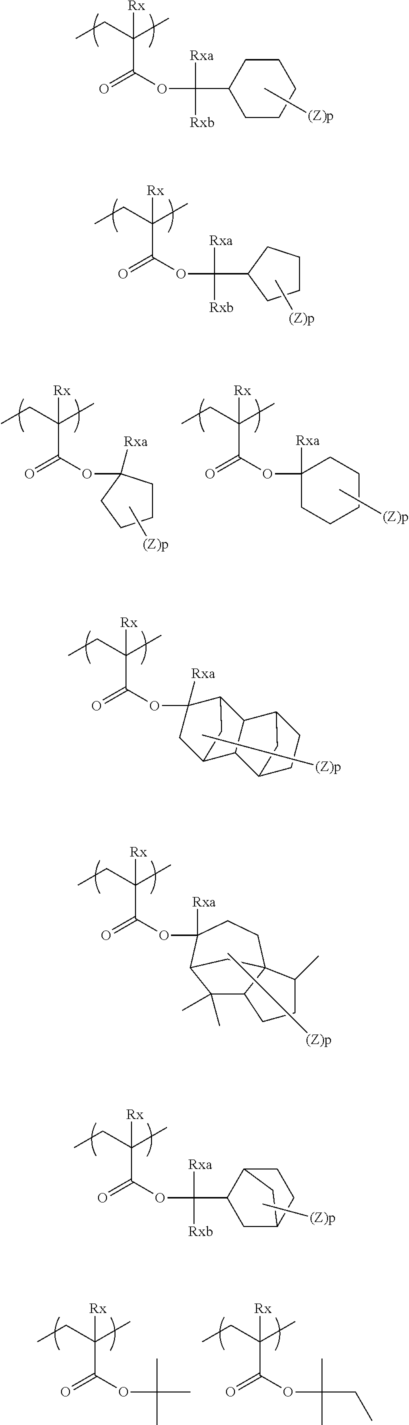

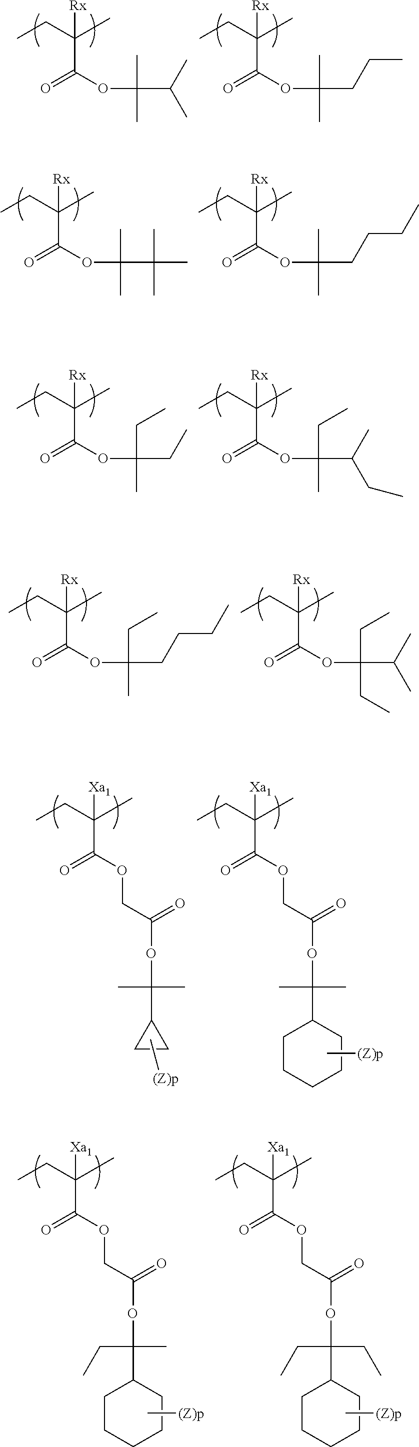

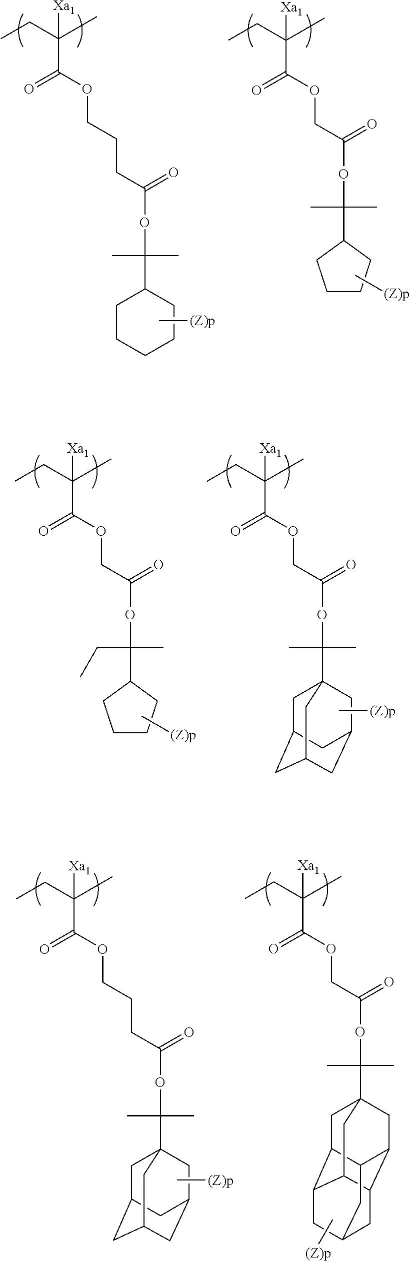

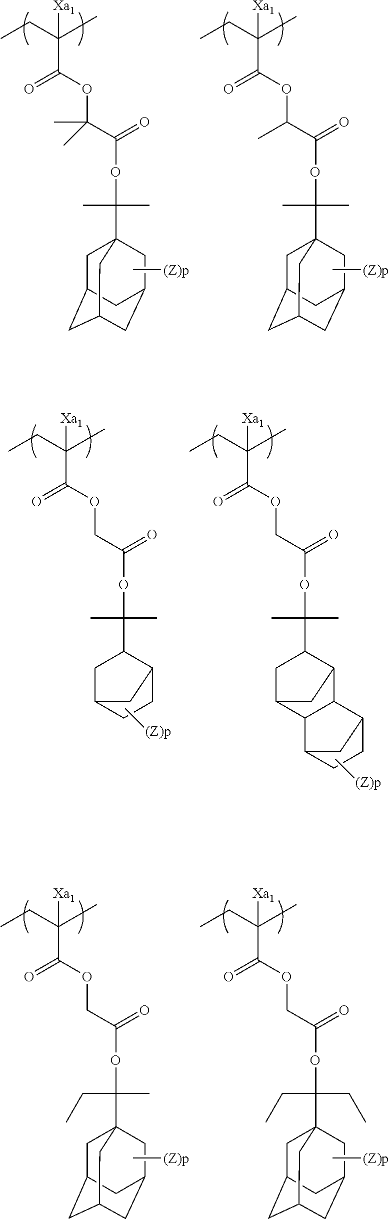

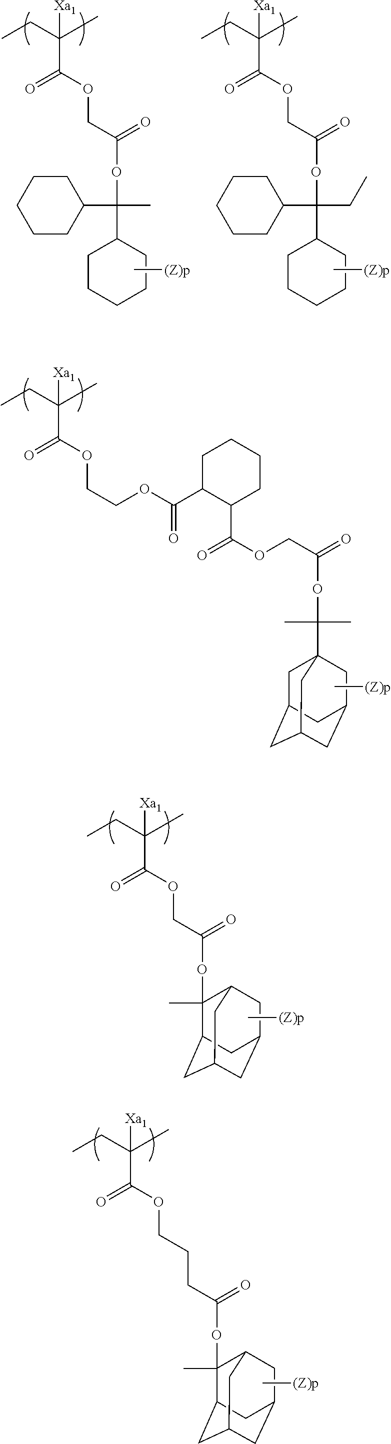

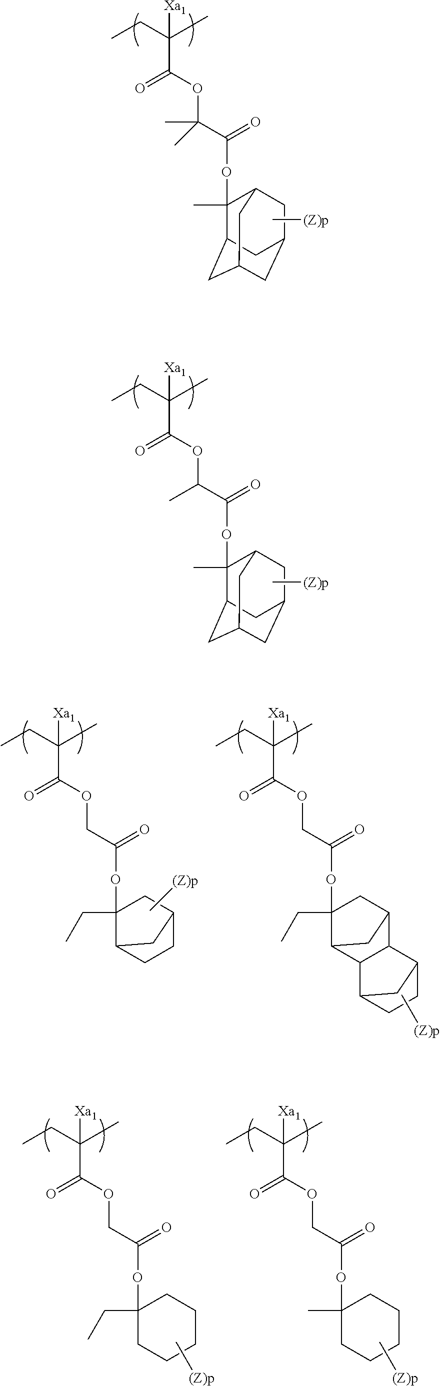

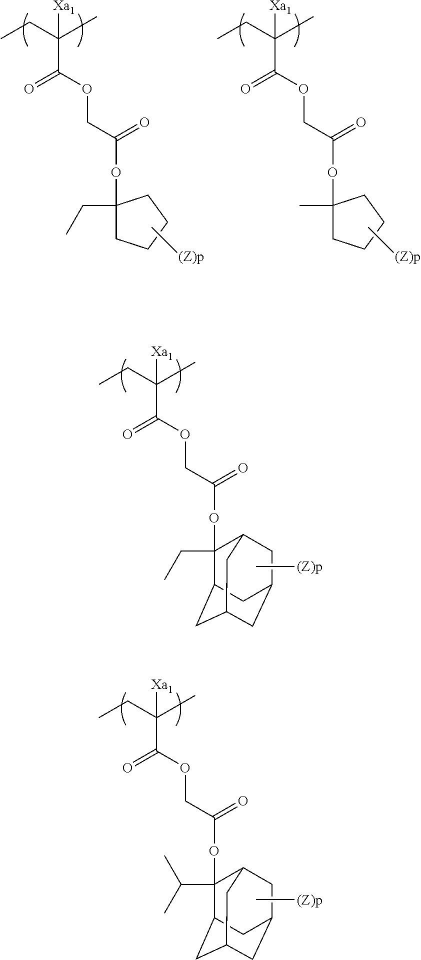

In specific examples below, Xa represents a hydrogen atom, an alkyl group, a cyano group, or a halogen atom.

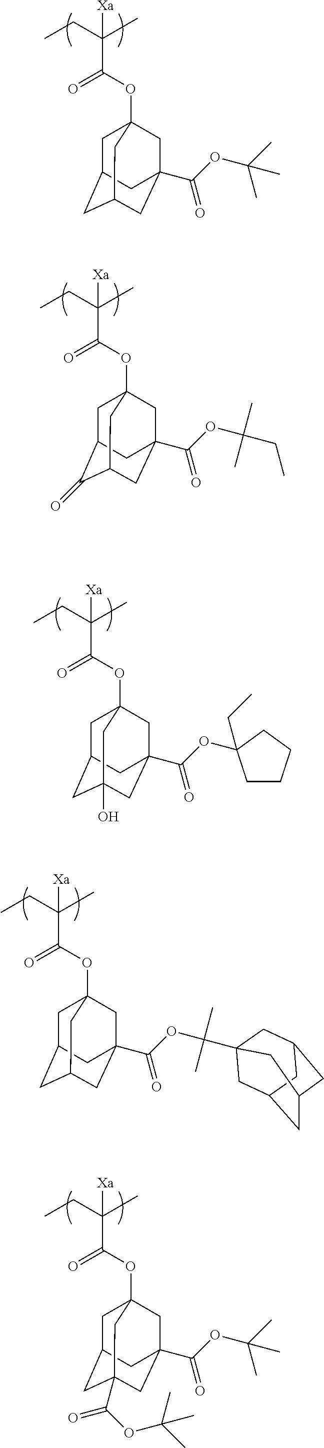

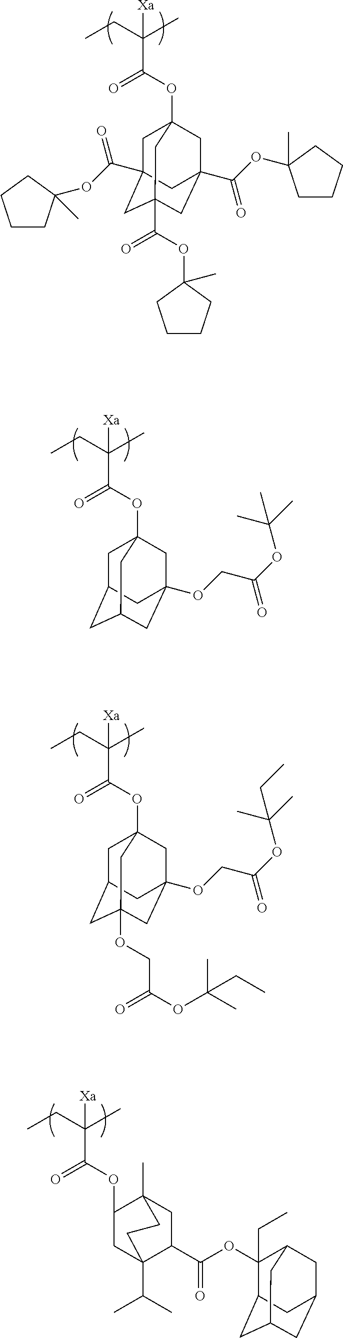

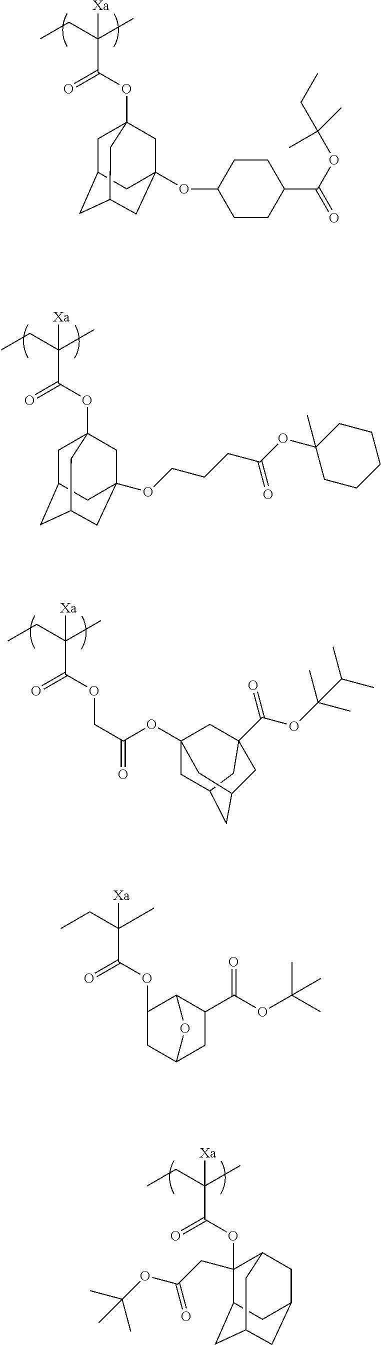

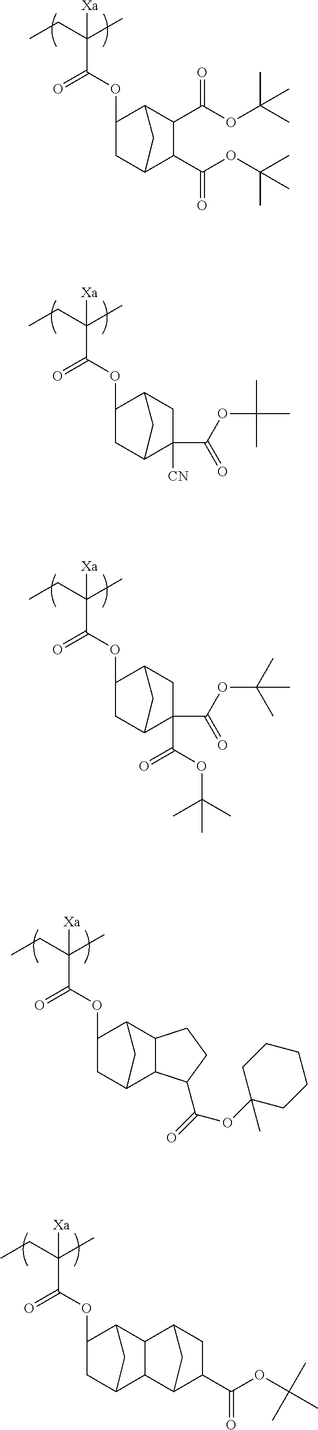

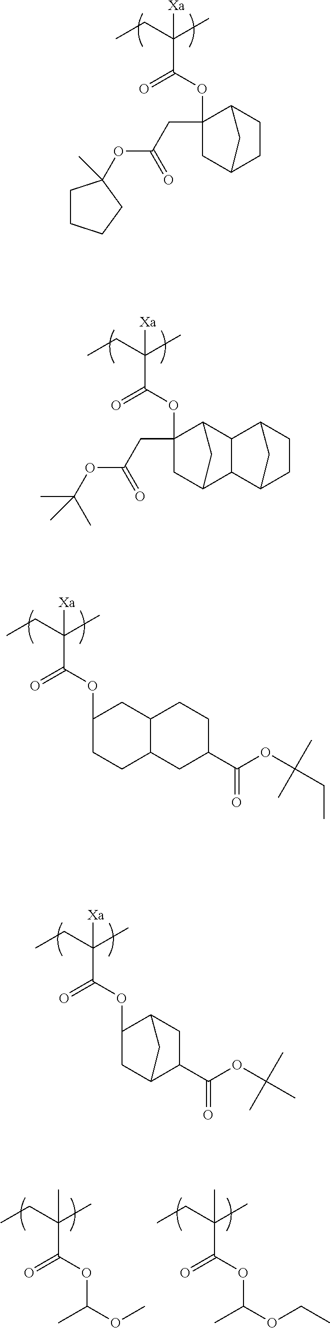

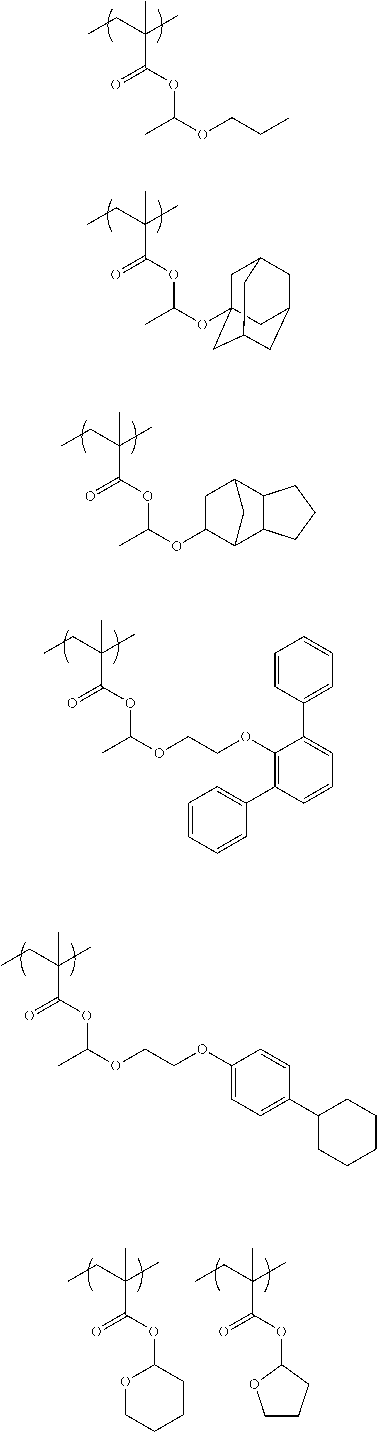

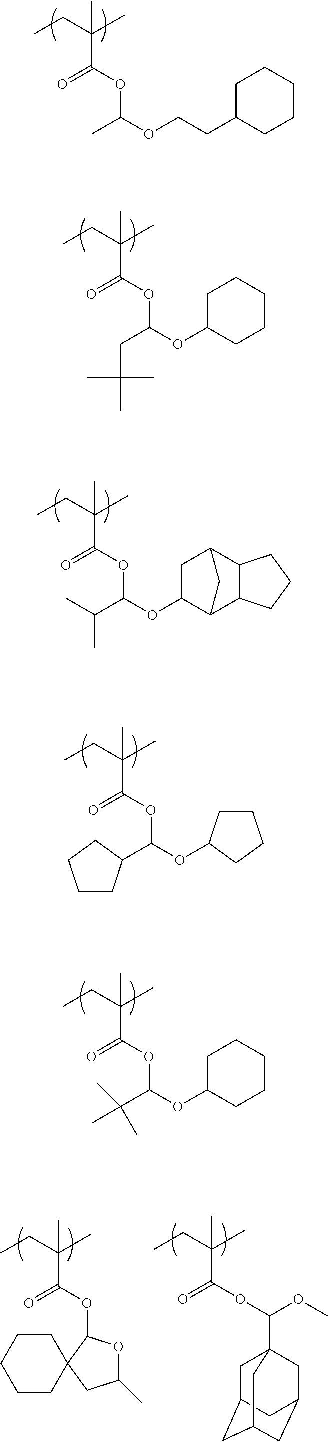

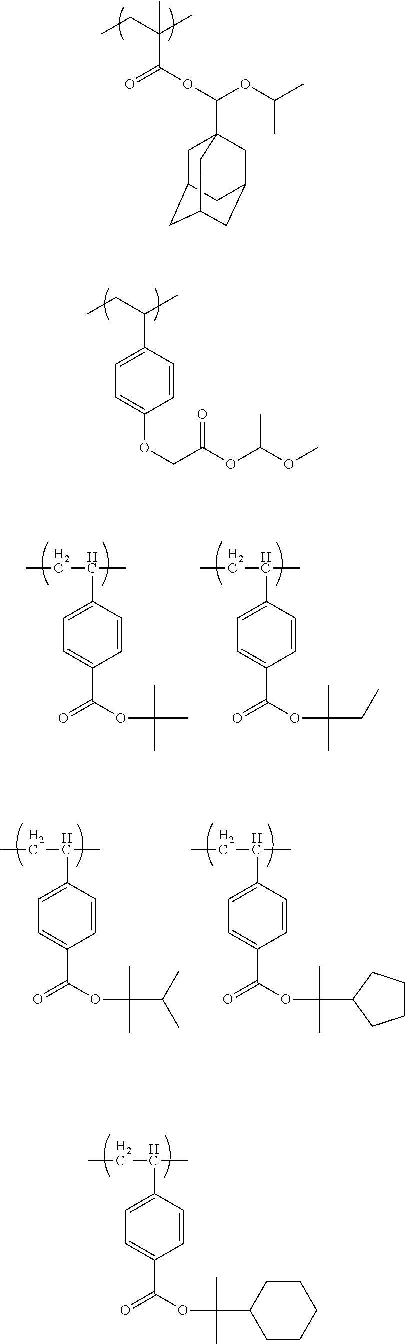

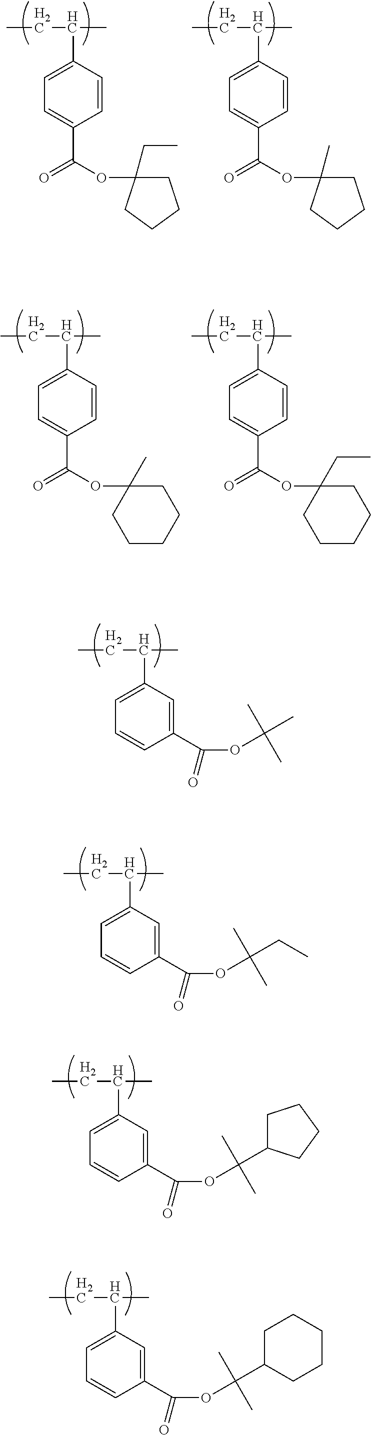

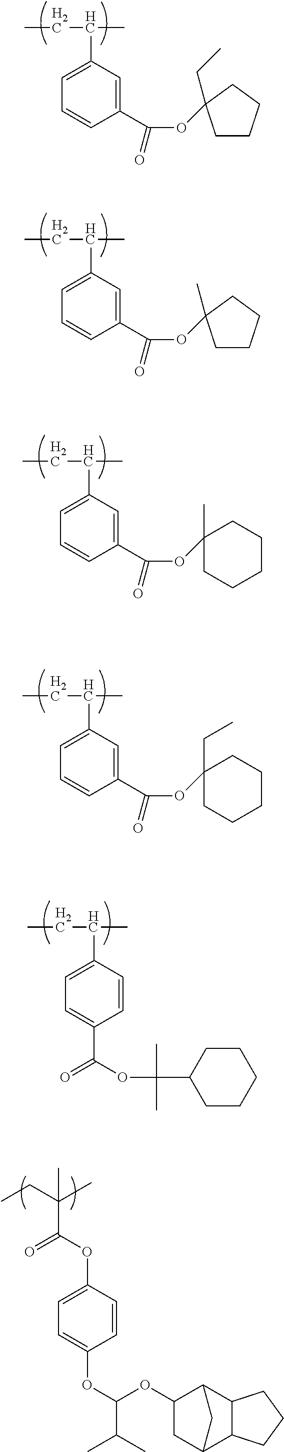

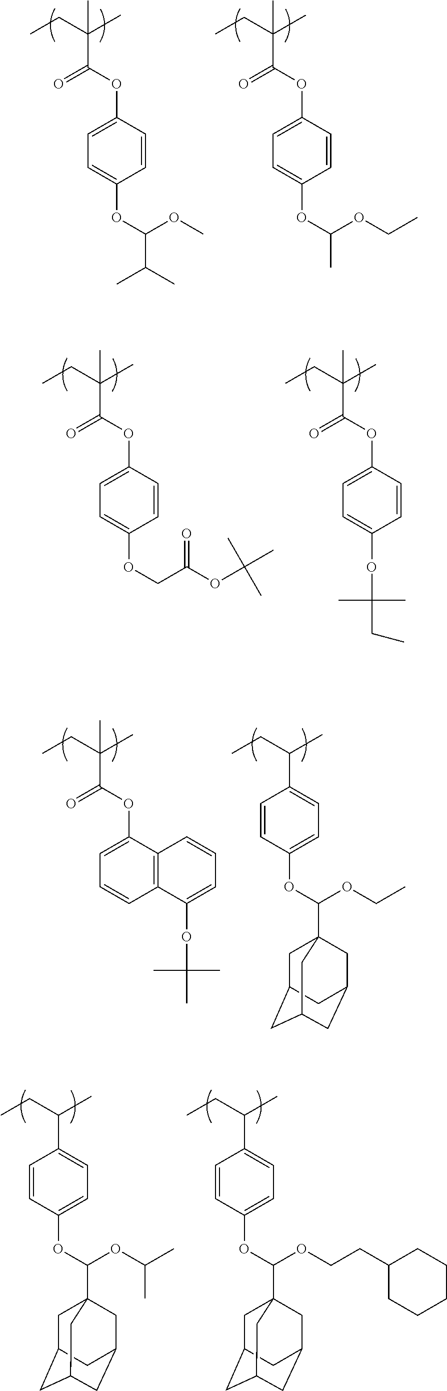

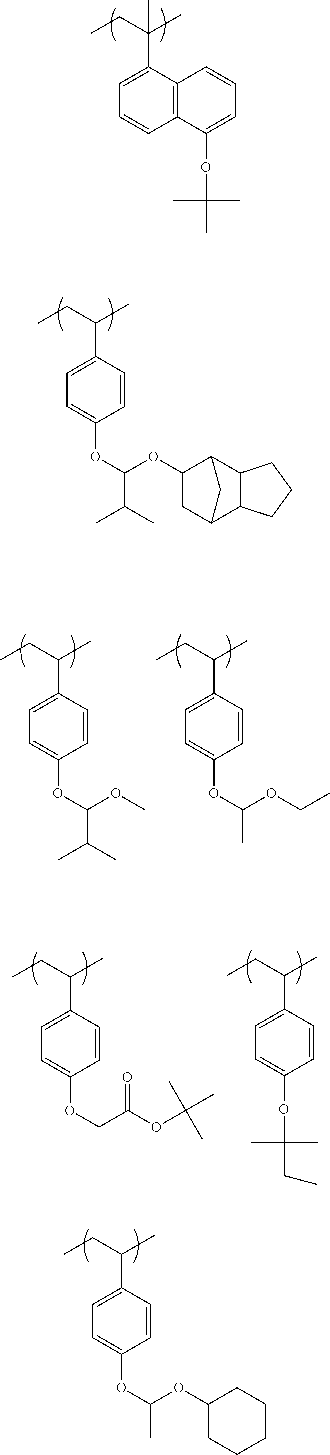

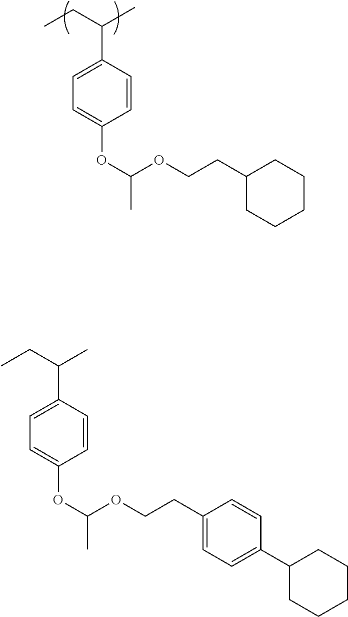

In specific examples below, Xaᵢ represents a hydrogen atom, CH₃, CF₃, or CH₂OH.

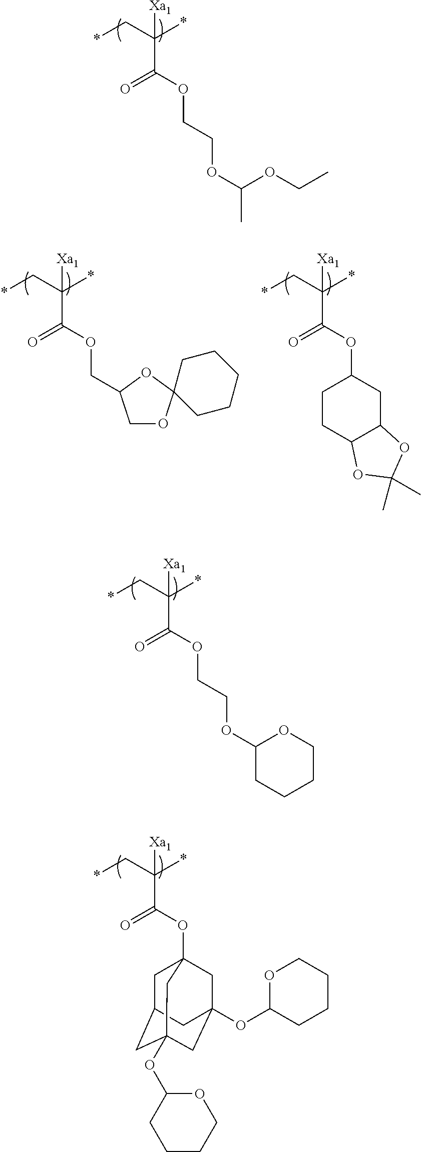

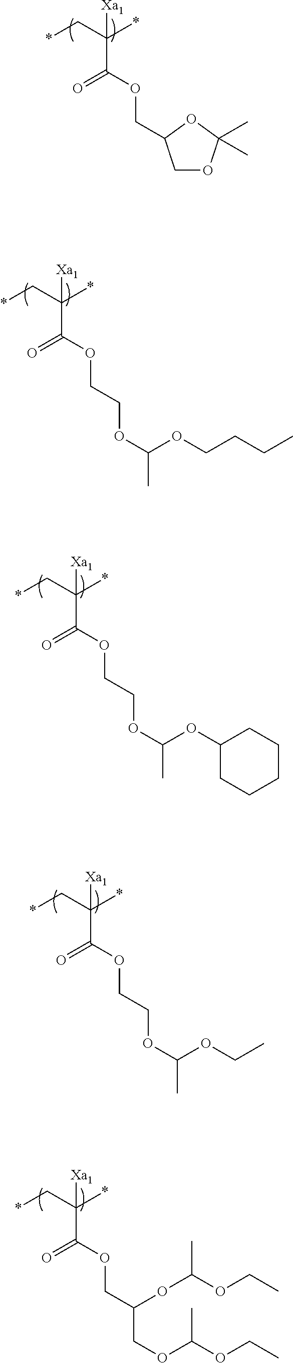

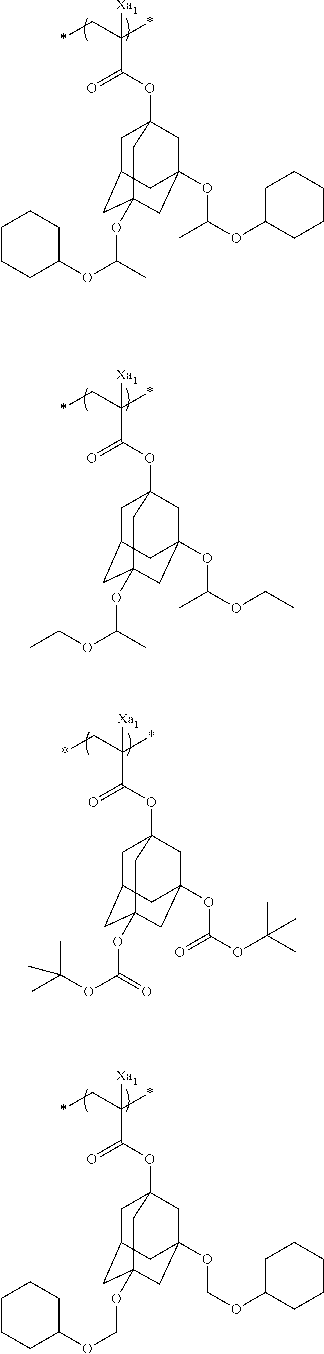

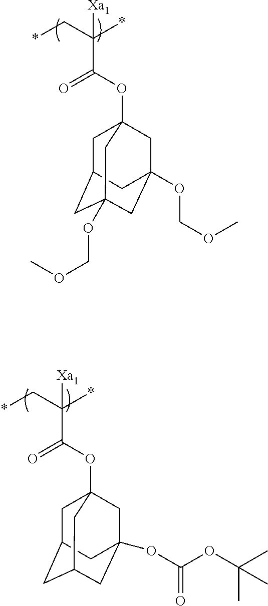

The repeating units having an acid-decomposable group can be used alone or in combination of two or more kinds thereof. In the case of using the two kinds in combination, the combination is not particularly limited, and preferred examples thereof include the following combinations.

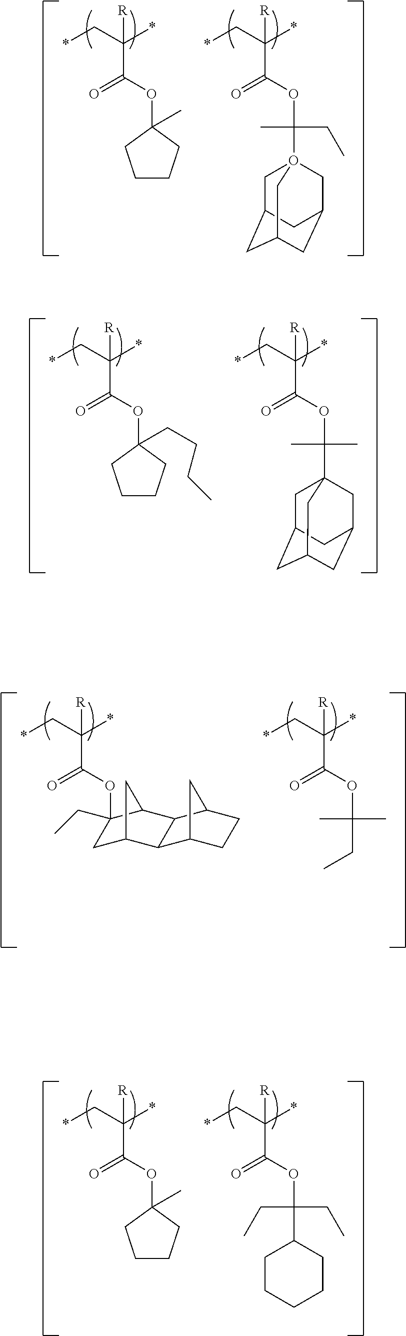

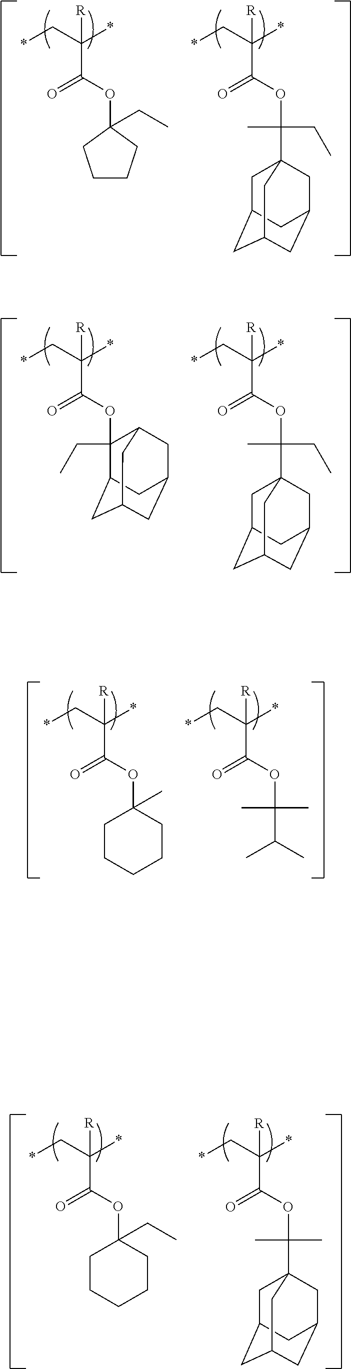

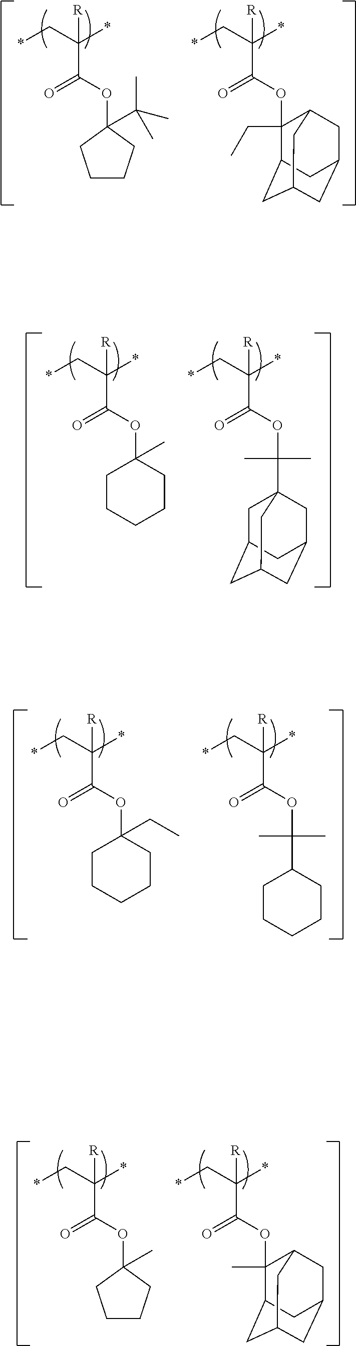

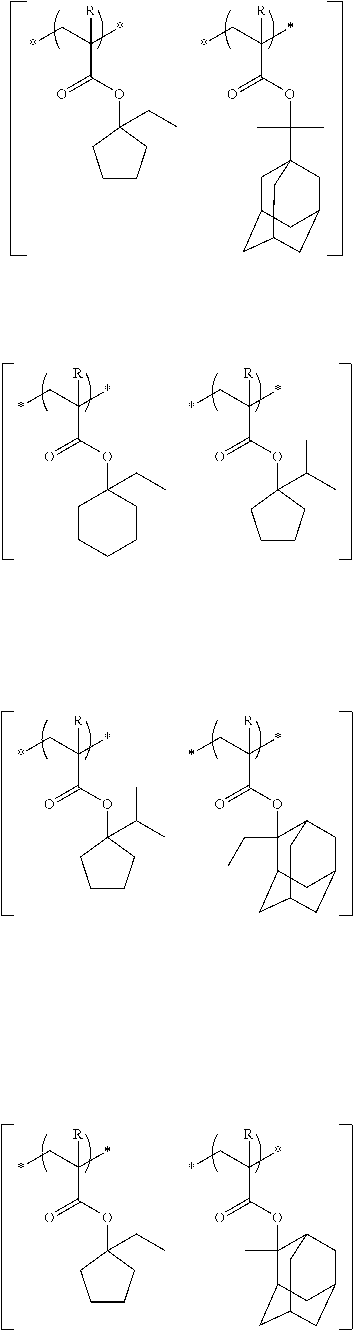

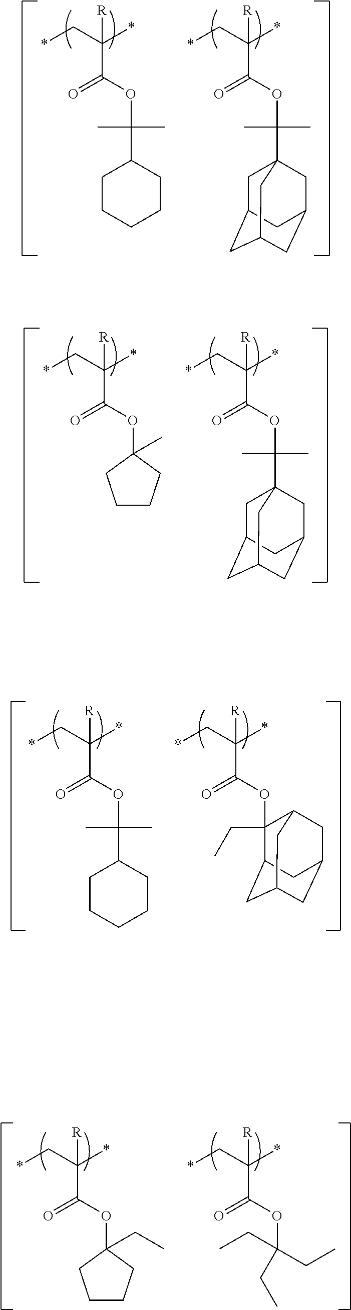

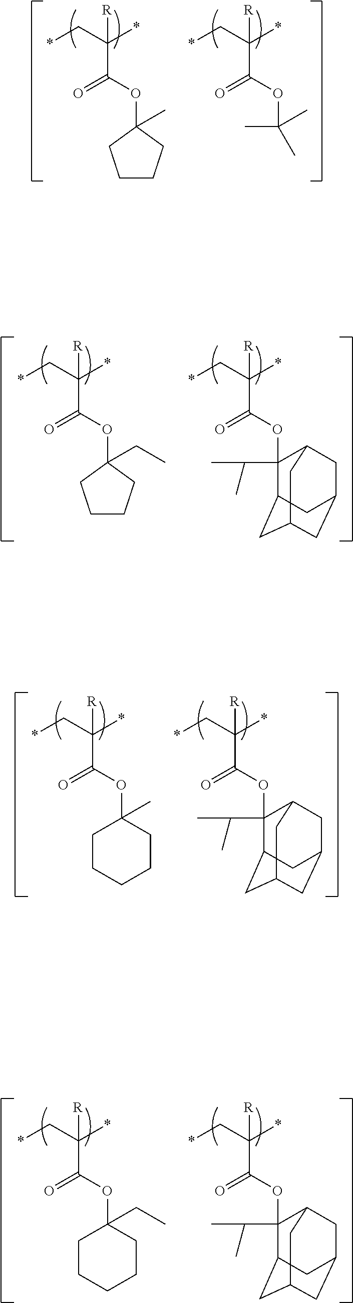

The content of the repeating units having an acid-decomposable group contained in the resin (A) (the total thereof in the case where a plurality of repeating units having acid-decomposable groups are present) is preferably 15% by mole or more, more preferably 20% by mole or more, still more preferably 25% by mole or more, and particularly preferably 40% by mole or more, with respect to all the repeating units in the resin (A).

The resin (A) may contain a repeating unit having a lactone structure or a sultone structure.

Specific examples of the repeating unit having a group having a lactone structure or a sultone structure are shown below, but the present invention is not limited thereto.

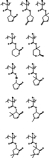

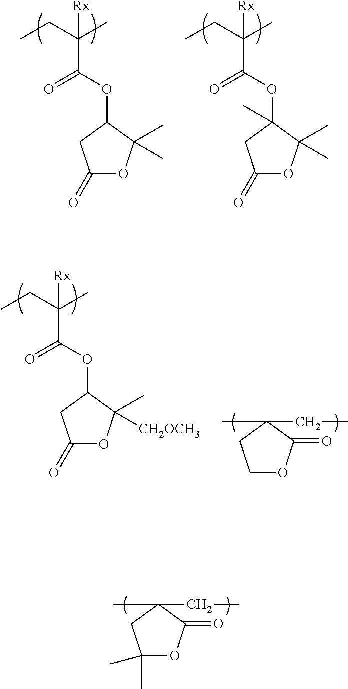

(in the formulae, Rx represents H, CH₃, CH₂OH, or CF₃)

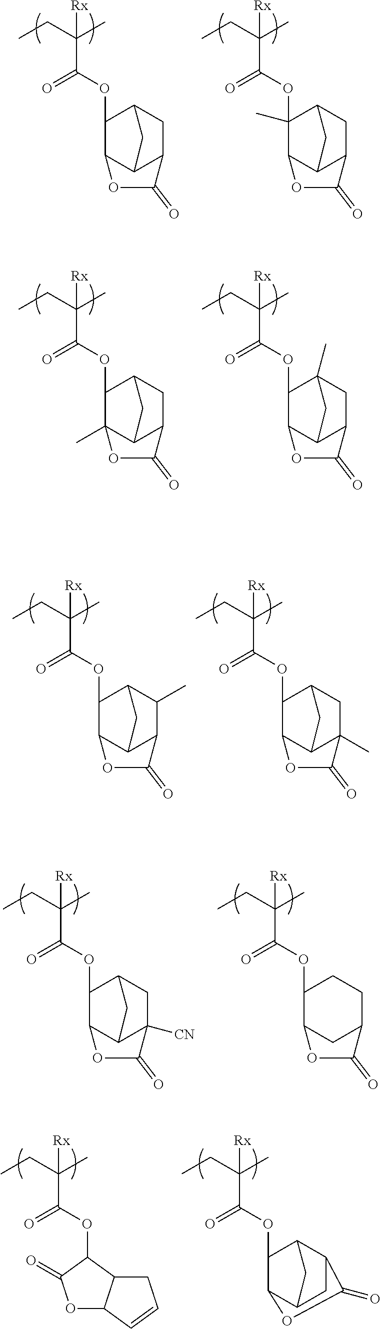

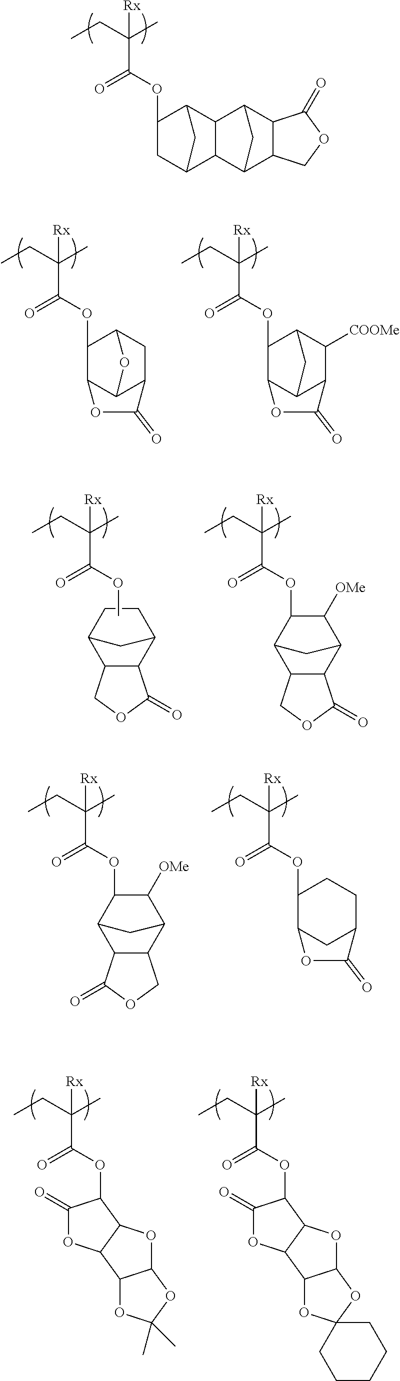

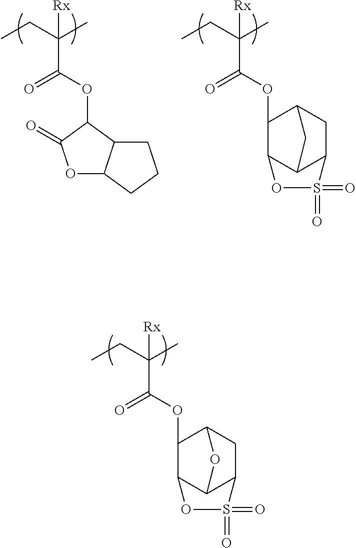

(in the formulae, Rx represents H, CH₃, CH₂OH, or CF₃)

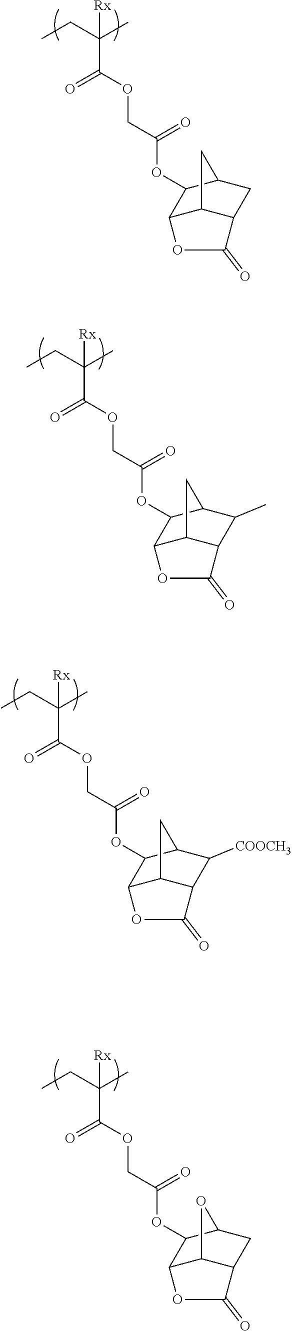

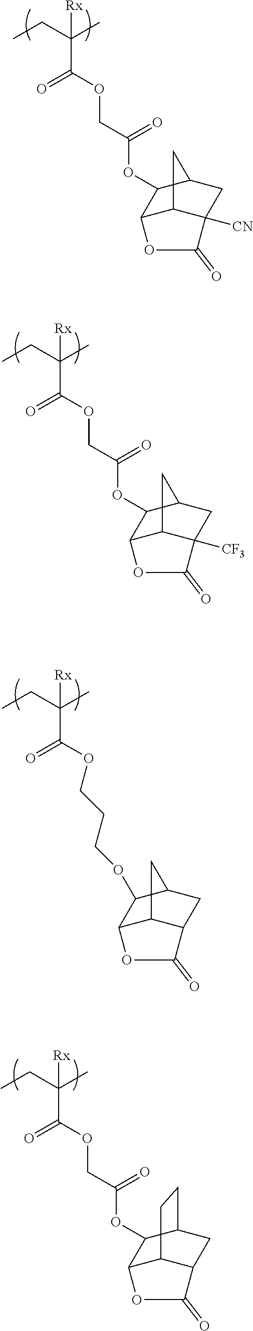

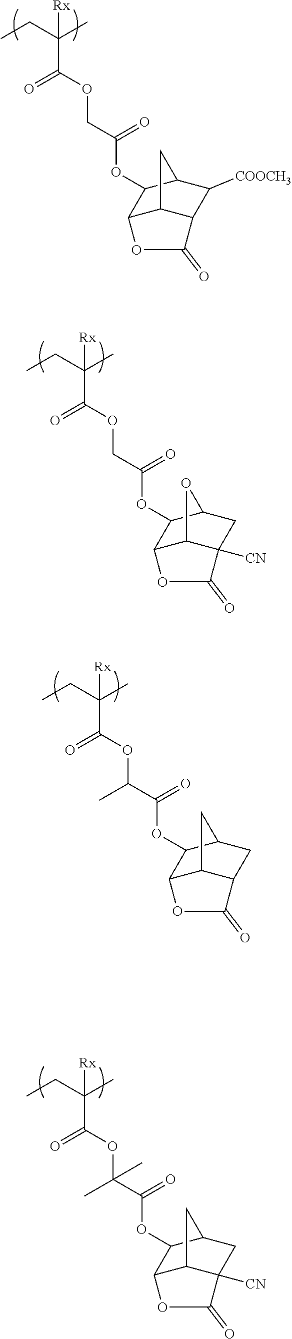

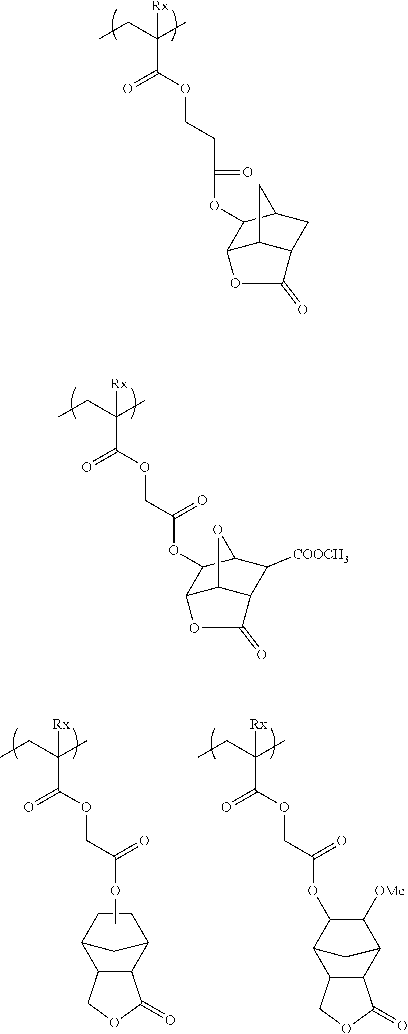

(in the formulae, Rx represents H, CH₃, CH₂OH, or CF₃)

It is also possible to use two or more kinds of repeating units having a lactone structure or a sultone structure in combination.

In the case where the resin (A) contains a repeating unit having a lactone structure or a sultone structure, the content of the repeating units having a lactone structure or a sultone structure is preferably from 5% by mole to 60% by mole, more preferably from 5% by mole to 55% by mole, and still more preferably from 10% by mole to 50% by mole, with respect to all the repeating units in the resin (A).

Furthermore, the resin (A) may contain a repeating unit having a cyclic carbonic ester structure. Specific examples thereof include the following ones, but the present invention is not limited thereto.

Incidentally, R_{A}¹ in the following specific examples represents a hydrogen atom or an alkyl group (preferably a methyl group).

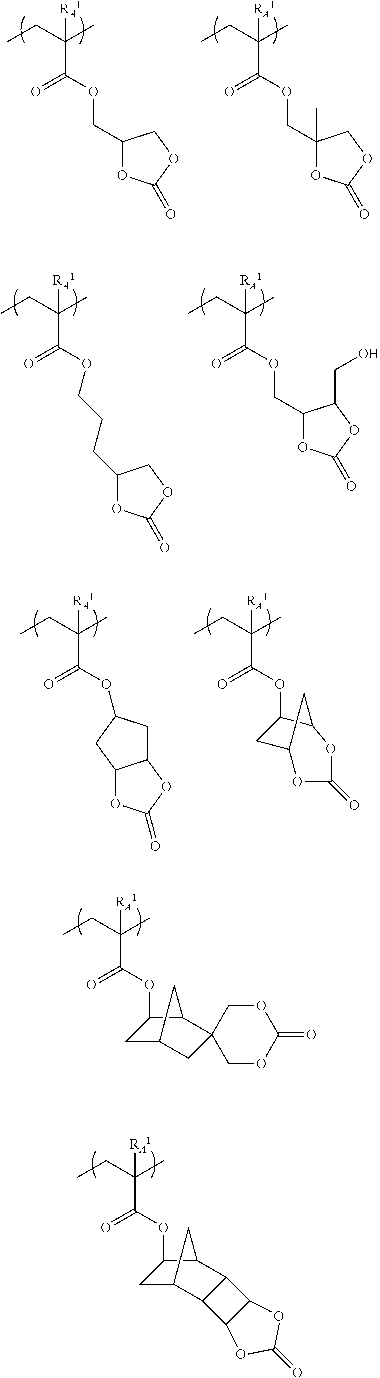

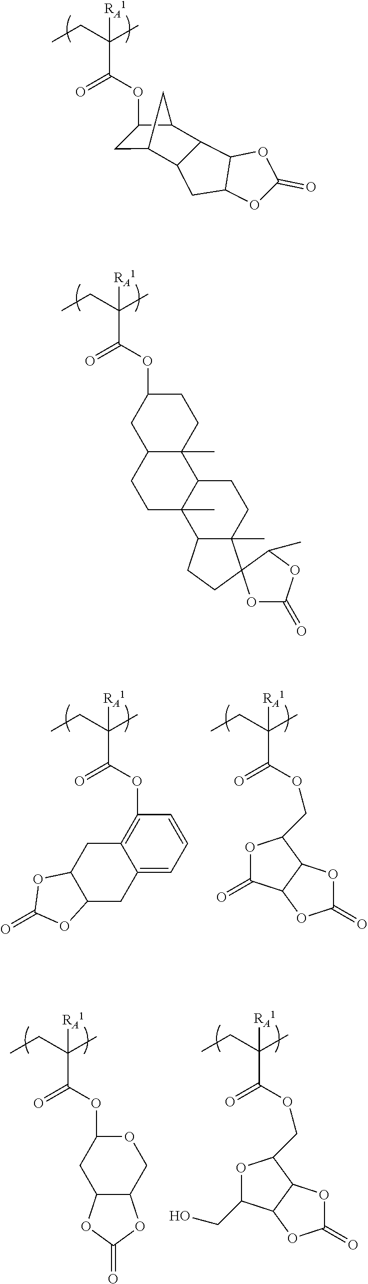

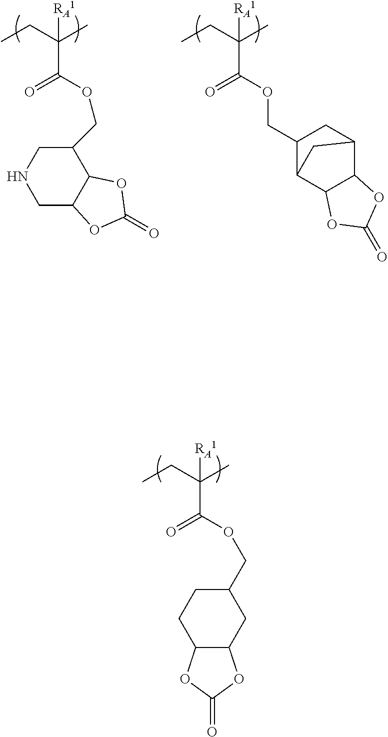

The resin (A) may contain a repeating unit having a hydroxyl group or a cyano group.

Specific examples of the repeating unit having a hydroxyl group or a cyano group are shown below, but the present invention is not limited thereto.

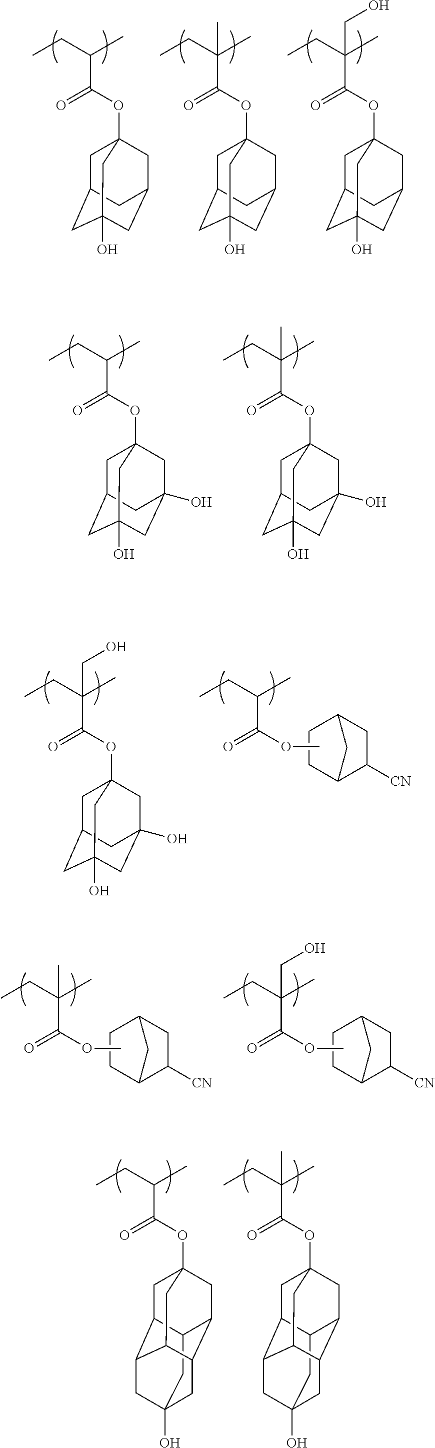

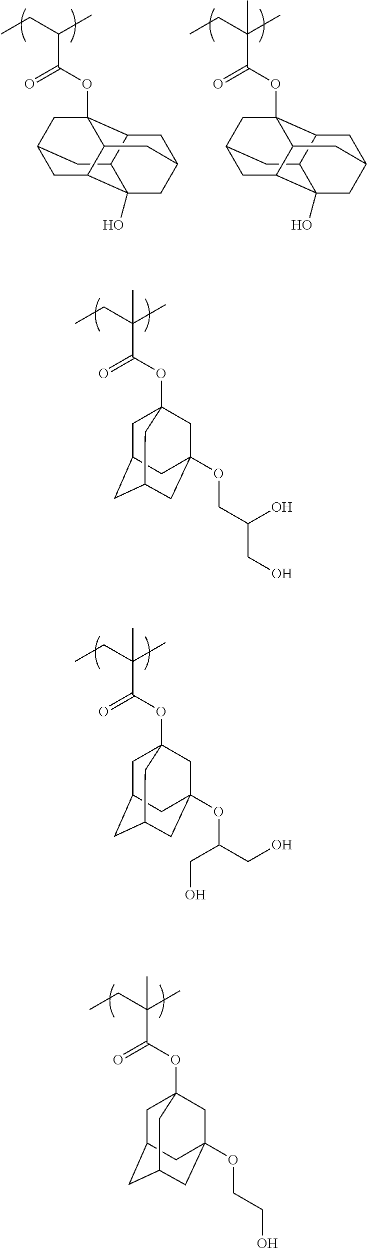

The resin (A) may have a repeating unit having an acid group.

Although the resin (A) may or may not contain a repeating unit having an acid group, in the case where the repeating unit having an acid group is contained, the content thereof is preferably 25% by mole or less, and more preferably 20% by mole or less, with respect to all the repeating units in the resin (A). In the case where the resin (A) contains a repeating unit having an acid group, the content of the repeating units having an acid group in the resin (A) is usually 1% by mole or more.

Specific examples of the repeating unit having an acid group are shown below, but the present invention is not limited thereto.

In the specific examples, Rx represents H, CH₃, CH₂OH, or CF₃.

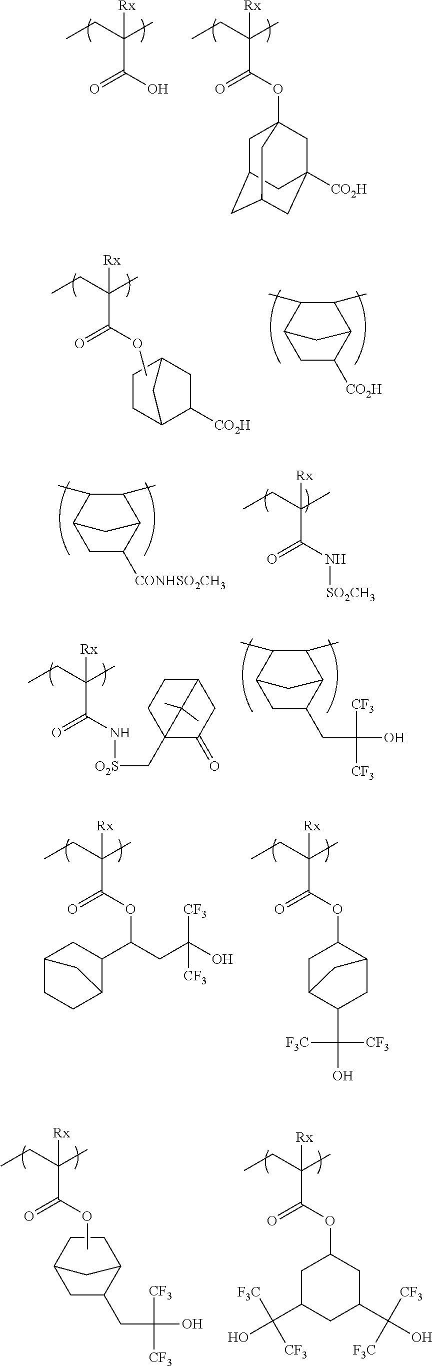

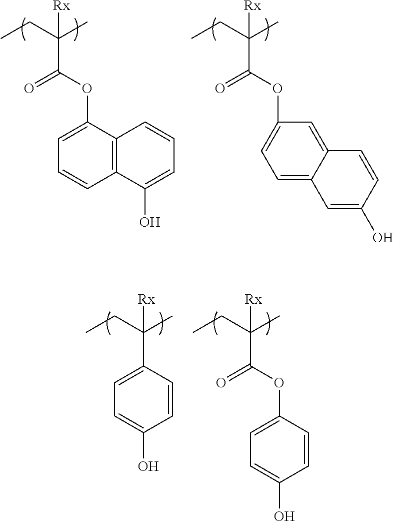

The resin (A) may further contain a repeating unit which has an alicyclic hydrocarbon structure and/or aromatic ring structure having no polar group (for example, the acid groups, a hydroxyl group, and a cyano group), and does not exhibit acid-decomposability. In the case where the resin (A) contains this repeating unit, the content of the repeating units is preferably from 3% by mole to 30% by mole, and still more preferably from 5% by mole to 25% by mole, with respect to all the repeating units in the resin (A).

Specific examples of the repeating unit having an alicyclic hydrocarbon structure containing no polar group and not exhibiting acid-decomposability are shown below, but the present invention is not limited thereto. In the formulae, Ra represents H, CH₃, CH₂OH, or CF₃.

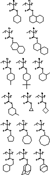

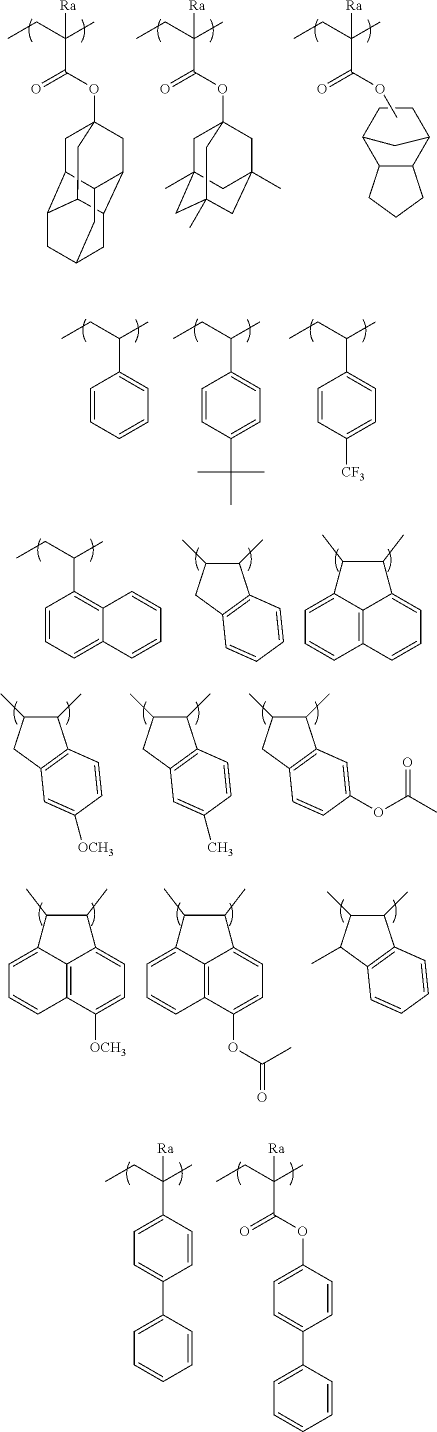

When the composition of the present invention is for ArF exposure, it is preferable that the resin (A) used in the composition of the present invention substantially does not have aromatic rings (specifically, the proportion of repeating units having an aromatic group in the resin is preferably 5% by mole or less, more preferably 3% by mole or less, and ideally 0% by mole, that is, the resin (A) does not have an aromatic group) in terms of transparency to ArF light. It is preferable that the resin (A) has a monocyclic or polycyclic alicyclic hydrocarbon structure.

The form of the resin (A) in the present invention may be any of random-type, block-type, comb-type, and star-type forms. The resin (A) can be synthesized by, for example, radical, cationic, or anionic polymerization of unsaturated monomers corresponding to respective structures. It is also possible to obtain a desired resin by polymerizing unsaturated monomers corresponding to precursors of respective structures, and then by carrying out a polymer reaction.

When the composition of the present invention contains a resin (D) as described later, it is preferable that the resin (A) contains neither a fluorine atom nor a silicon atom, from the viewpoint of compatibility with the resin (D).

The resin (A) used in the composition of the present invention is preferably a resin in which all the repeating units are composed of (meth)acrylate-based repeating units. In this case, all the repeating units may be methacrylate-based repeating units, all the repeating units may be acrylate-based repeating units, or all the repeating units may be composed of methacrylate-based repeating units and acrylate-based repeating units, but the acrylate-based repeating units preferably accounts for 50% by mole or less with respect to all the repeating units.

In the case where the composition of the present invention is irradiated with KrF excimer laser light, electron beams, X-rays, and high-energy light beams at a wavelength of 50 nm or less (EUV and the like), the resin (A) may further have a repeating unit having an aromatic ring. The repeating unit having an aromatic ring is not particularly limited, and examples thereof are shown in the description of the respective repeating units as described above, including a styrene unit, a hydroxystyrene unit, a phenyl (meth)acrylate unit, and a hydroxyphenyl (meth)acrylate unit. More specific examples of the resin (A) include a resin having a hydroxystyrene-based repeating unit and a hydroxystyrene-based repeating unit protected by an acid-decomposable group, a resin having the repeating unit having an aromatic ring and a resin having a repeating unit having a carboxylic acid moiety of a (meth)acrylic acid protected by an acid-decomposable group.

The resin (A) in the present invention can be synthesized and purified in accordance with an ordinary method (for example, radical polymerization). For example, with respect to the synthesis and purification method, reference can be made to the descriptions of paragraphs “0201” to “0202” of JP2008-292975, and the like.

The weight-average molecular weight of the resin (A) in the present invention is preferably 7,000 or more as mentioned above, preferably from 7,000 to 200,000, more preferably from 7,000 to 50,000, still more preferably from 7,000 to 40,000, and particularly preferably from 7,000 to 30,000, as measured by a GPC method, and calculated in terms of polystyrene. When the weight-average molecular weight is lower than 7000, the solubility in an organic developing liquid becomes too high, and as a result, there is a concern that it may fail to form precise patterns.

The dispersity (molecular-weight distribution) of the resin used is generally from 1.0 to 3.0, preferably from 1.0 to 2.6, more preferably from 1.0 to 2.0, and particularly preferably from 1.4 to 2.0. The narrower the molecular-weight distribution of the resin, the more excellent resolution and resist profile are achieved, and in addition, the smoother side wall of a resist pattern and the more excellent roughness are obtained.

In the chemical amplification resist composition of the present invention, the blending ratio of the resin (A) in the entire composition is preferably from 30% by mass to 99% by mass, and more preferably 60% by mass to 95% by mass, with respect to the total solid content.

In addition, in the present invention, the resins (A) may be used alone or in combination of a plurality thereof.

Specific examples (in which the compositional ratio of the repeating units is a molar ratio) of the resin (A) are shown below, but the present invention is not limited thereto. Incidentally, embodiments of the case where a structure corresponding to the acid generator (B) as described later is supported on the resin (A) are also exemplified.

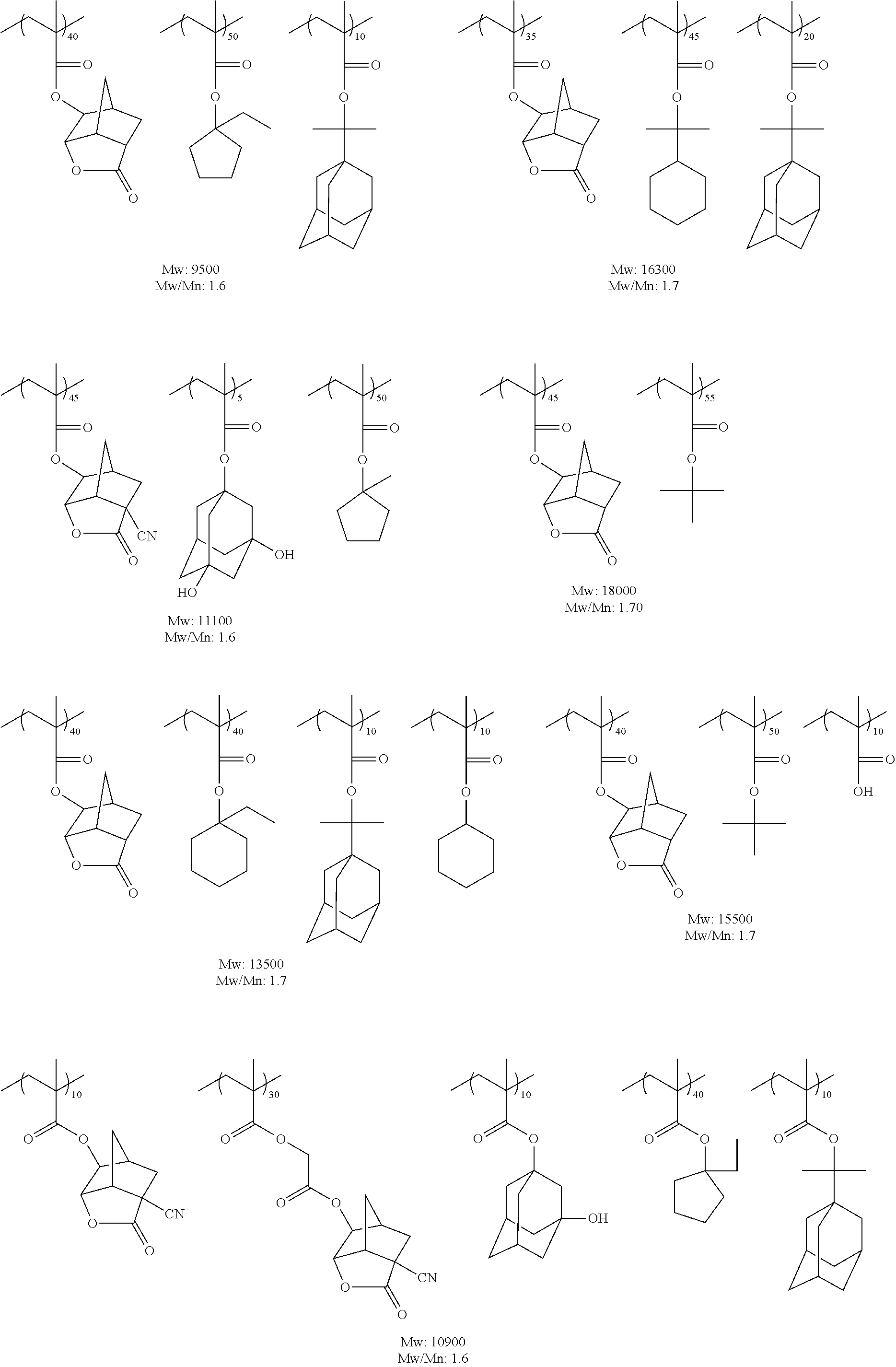

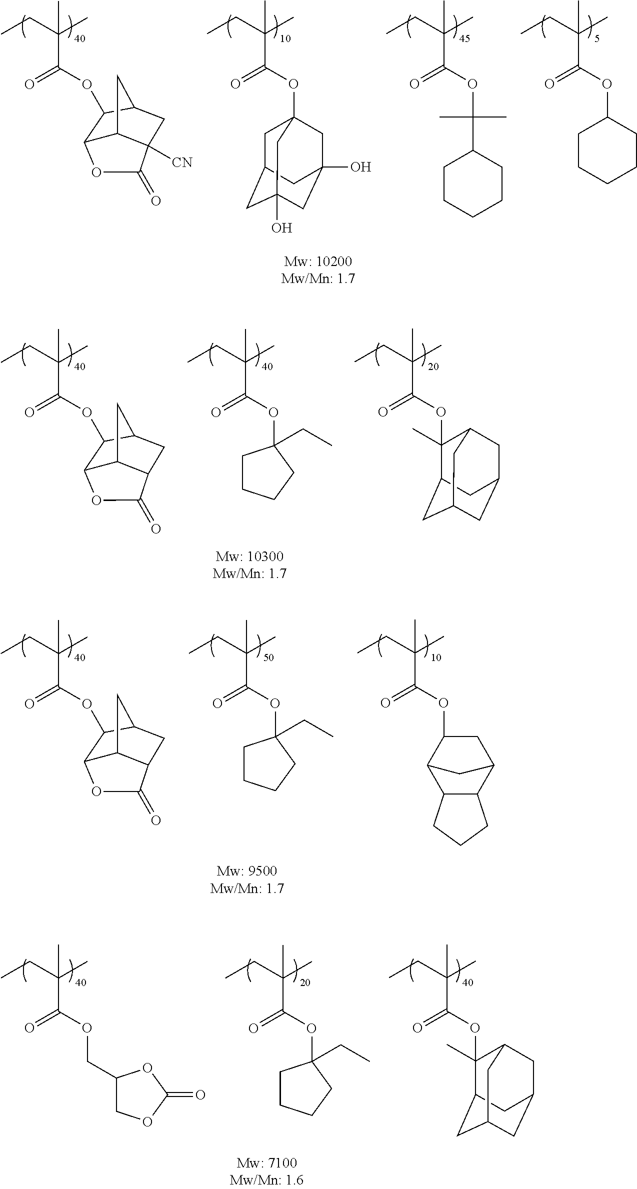

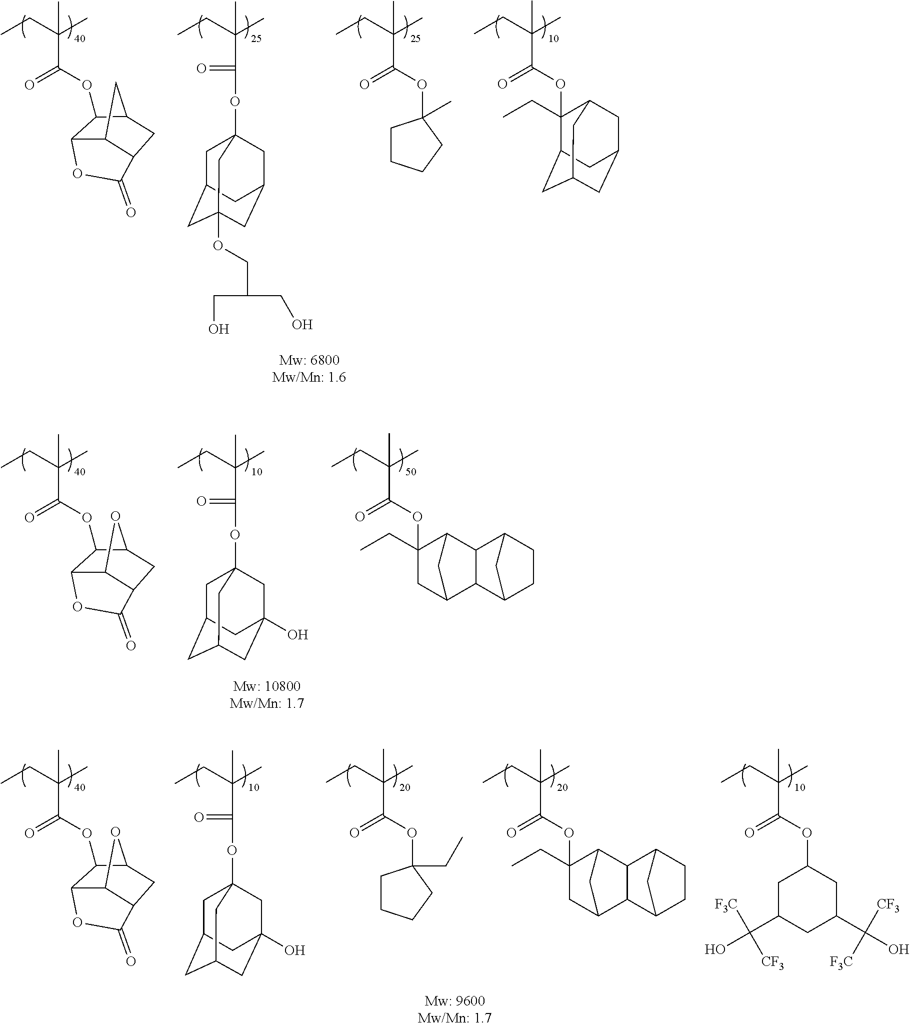

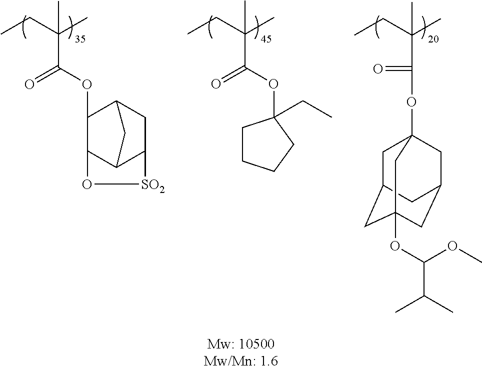

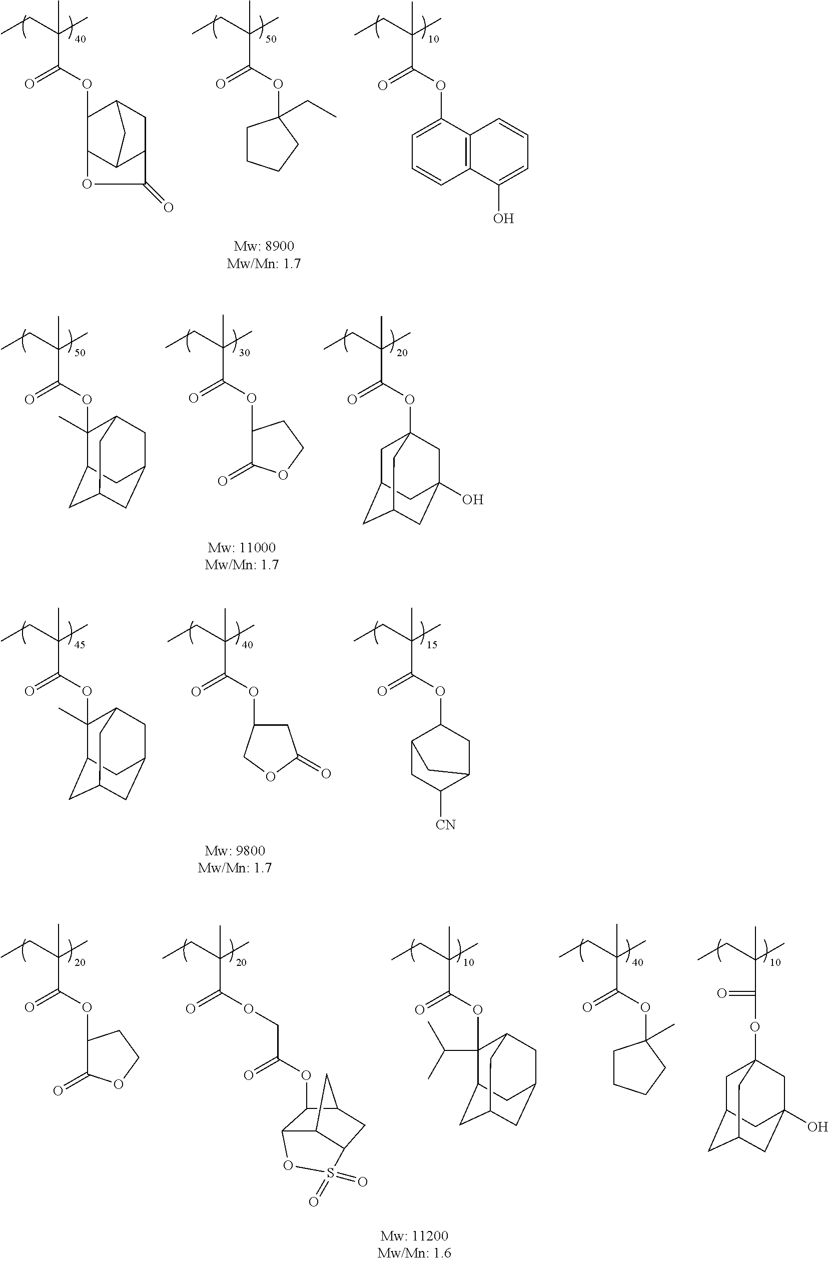

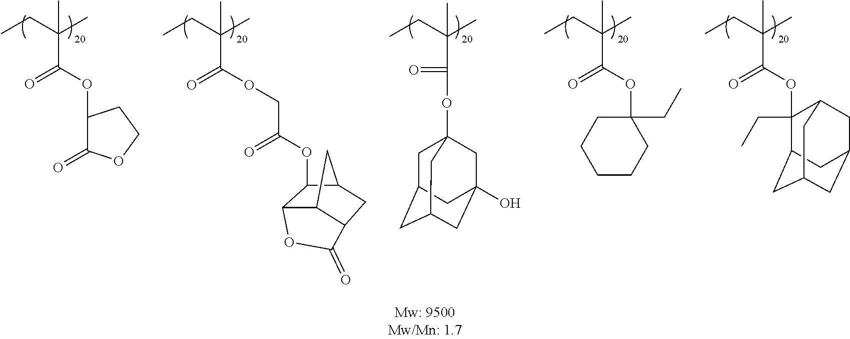

The resins exemplified below are the examples of the resins which can be suitably used, in particular, during EUV exposure or electron beam exposure.

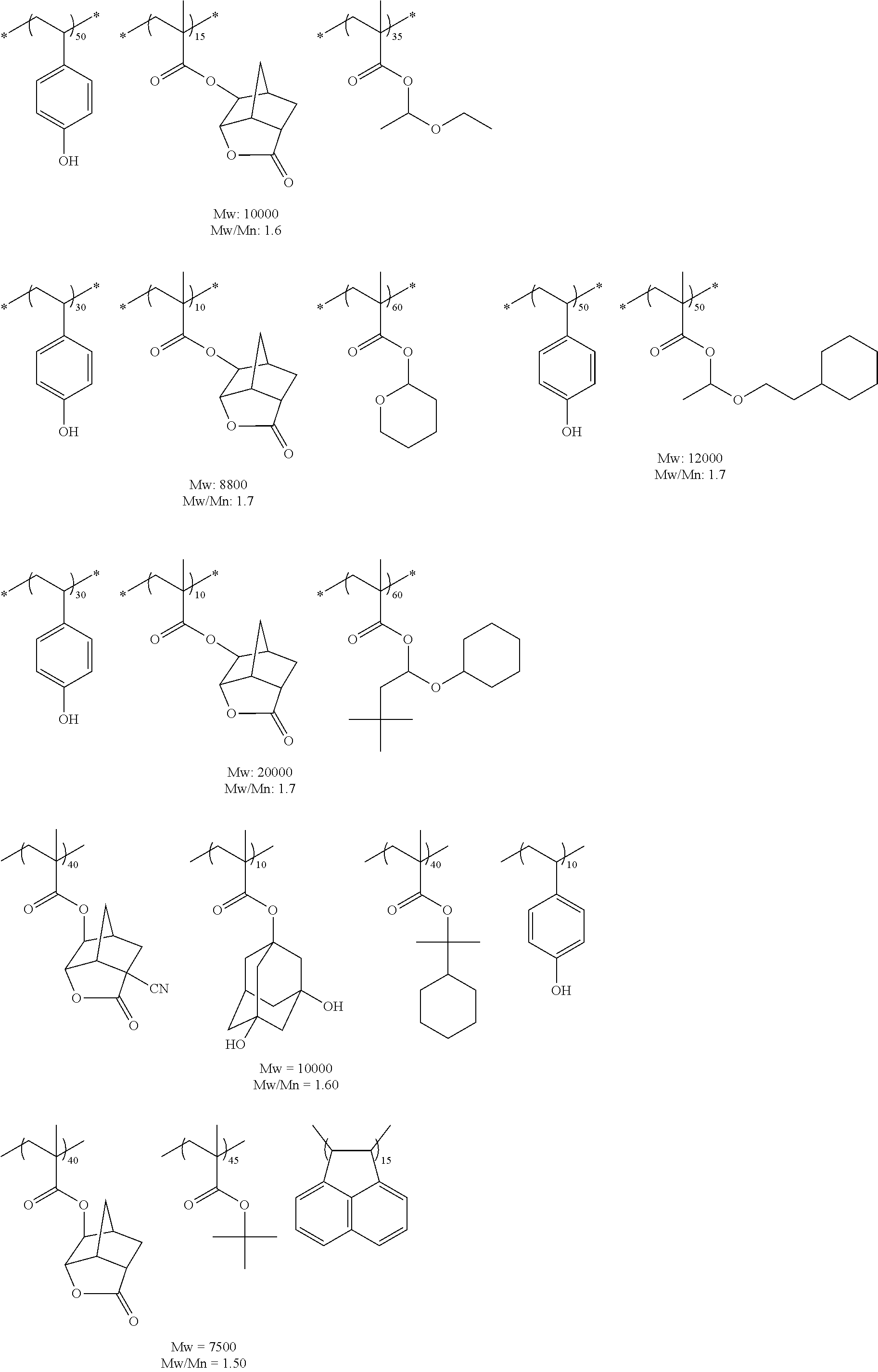

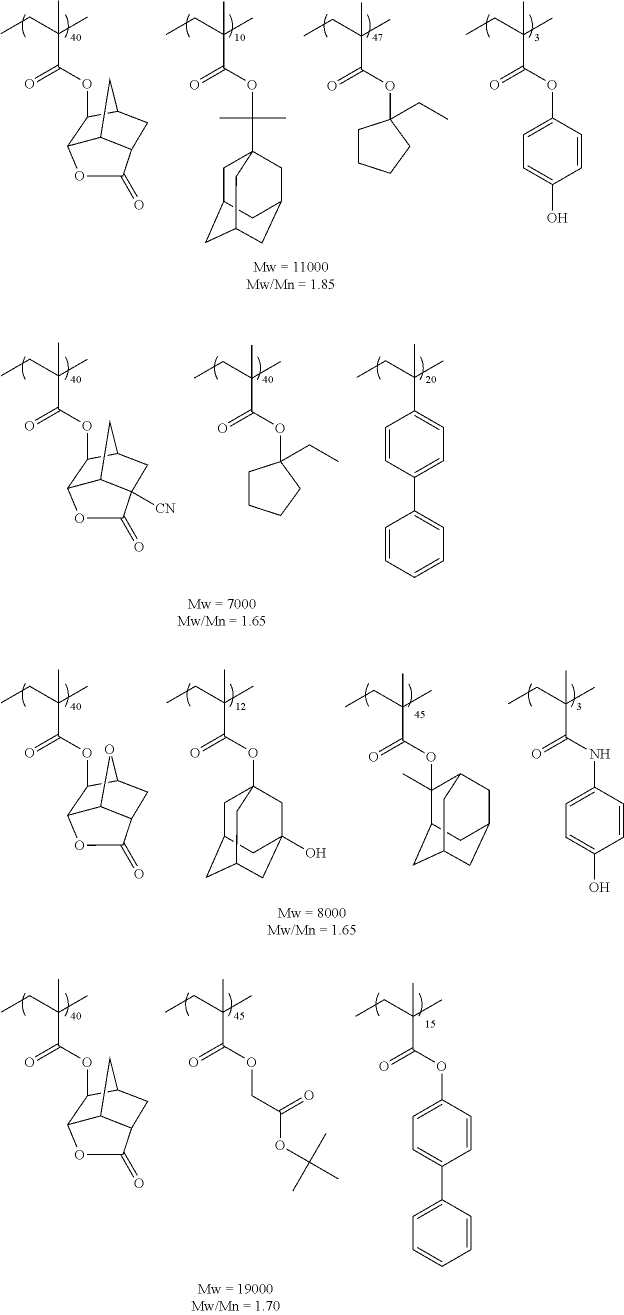

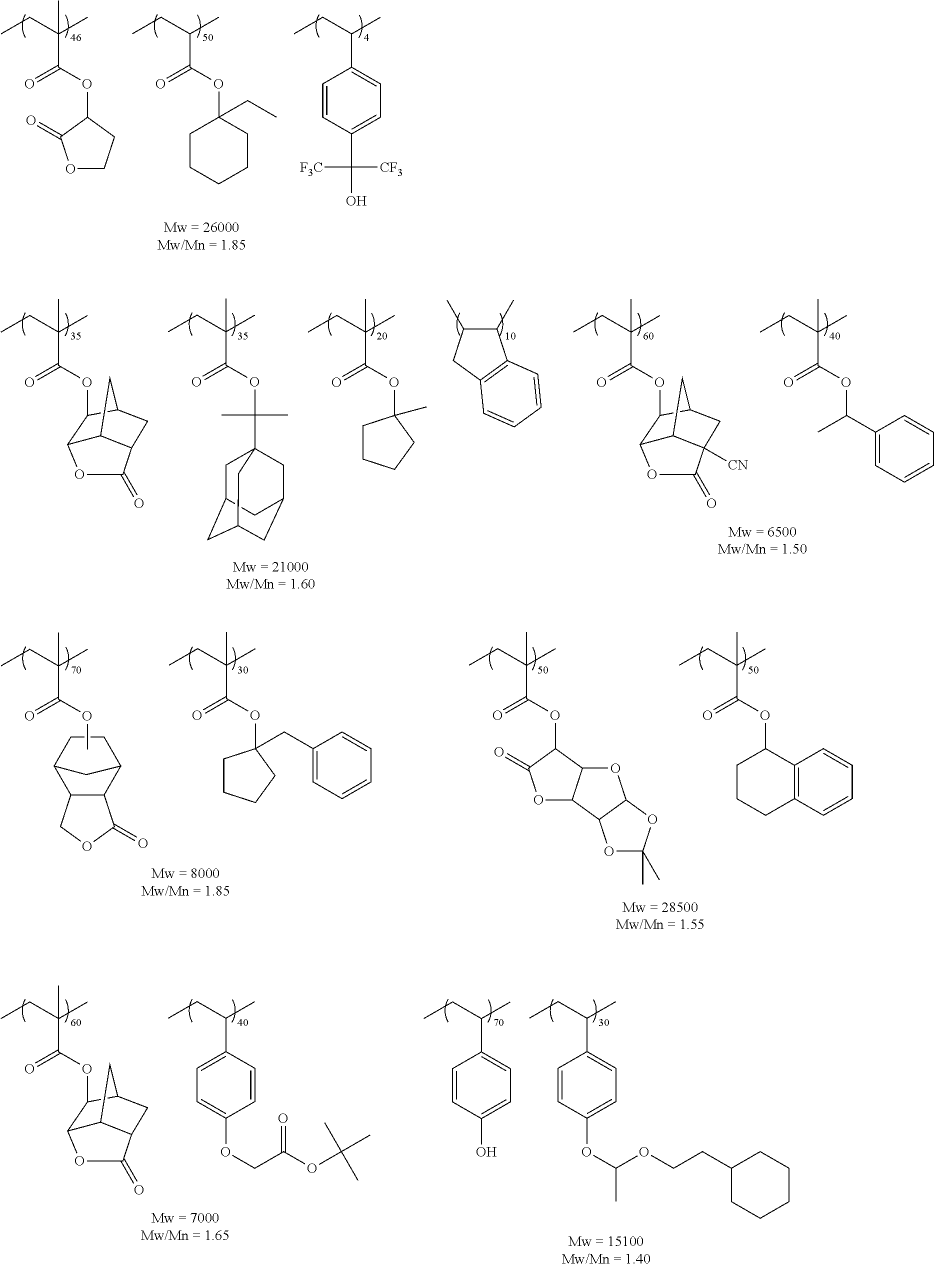

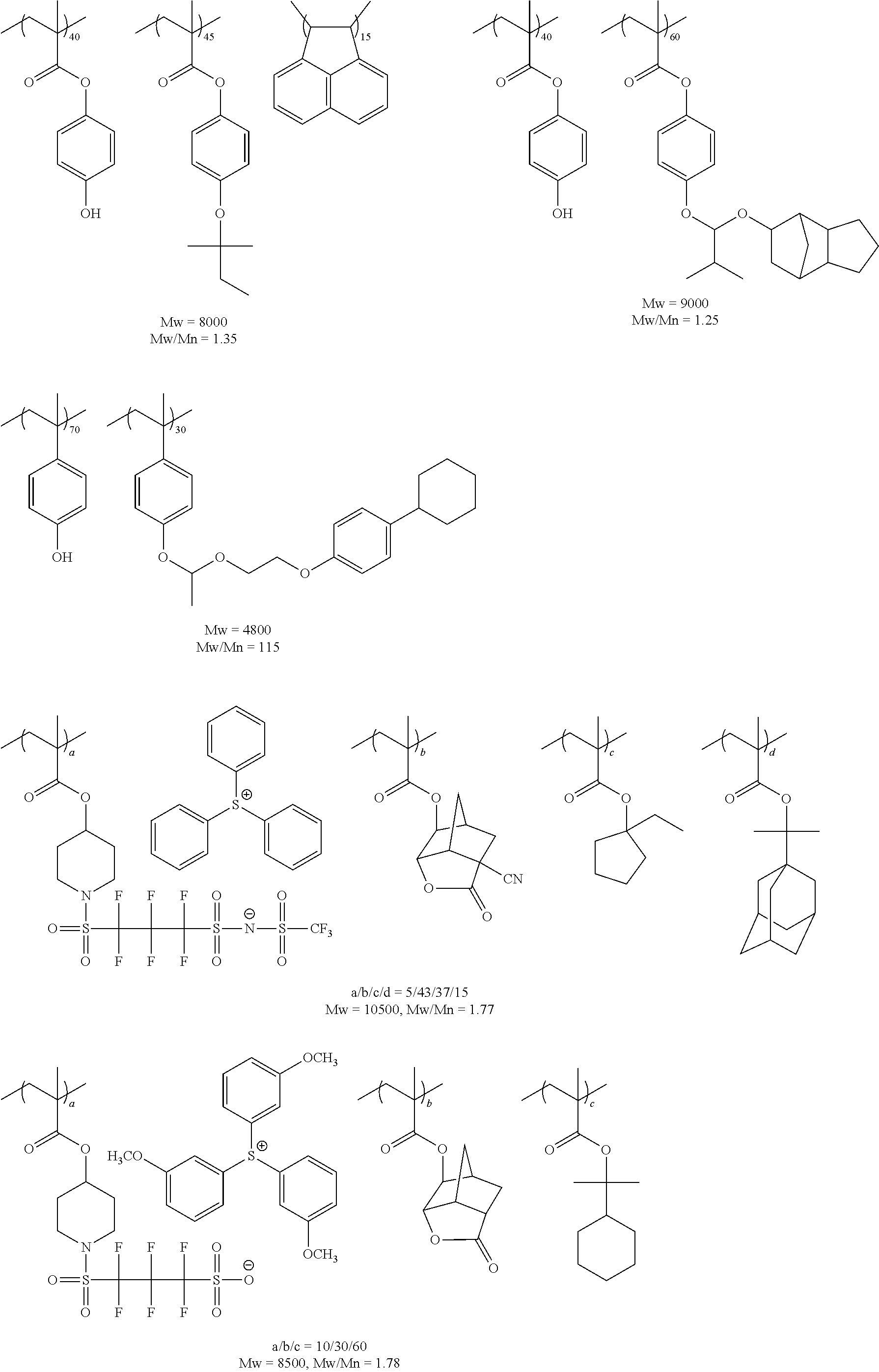

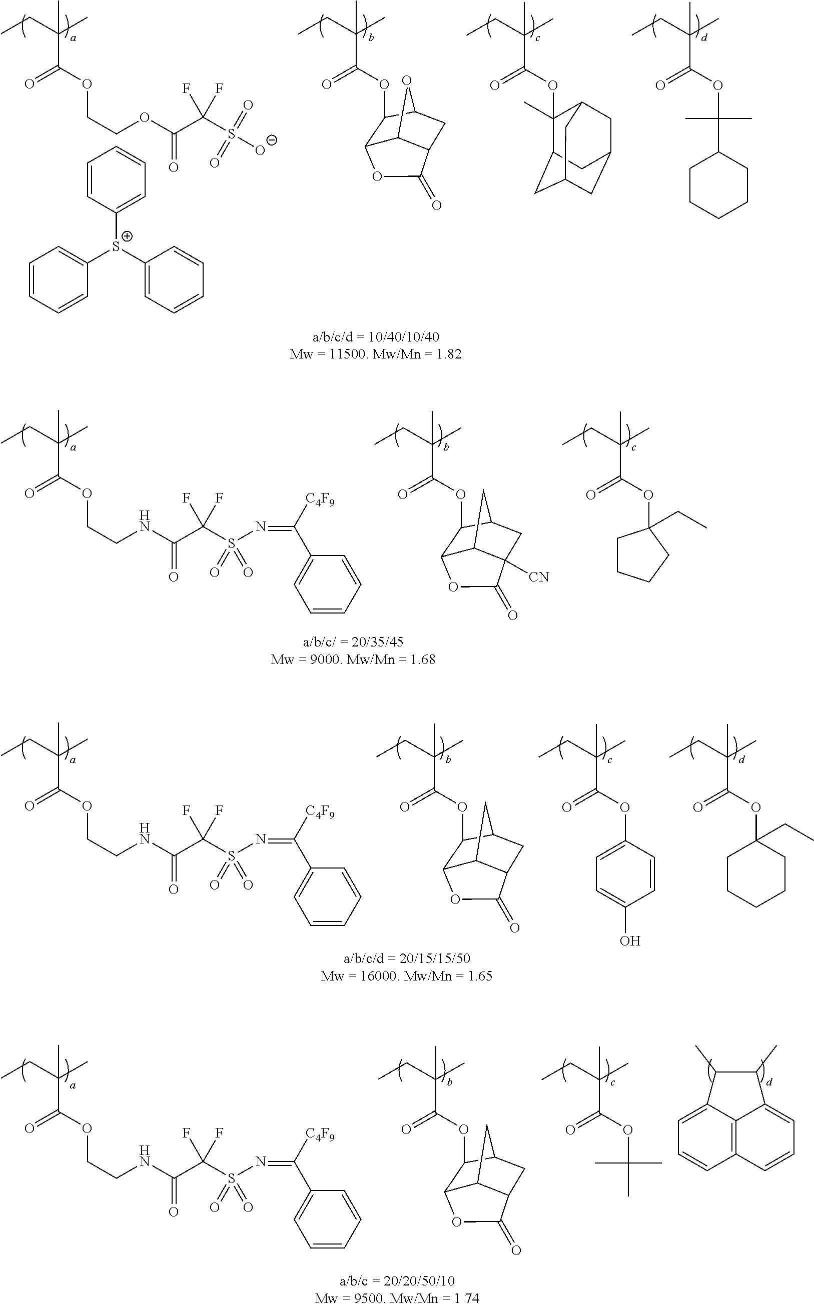

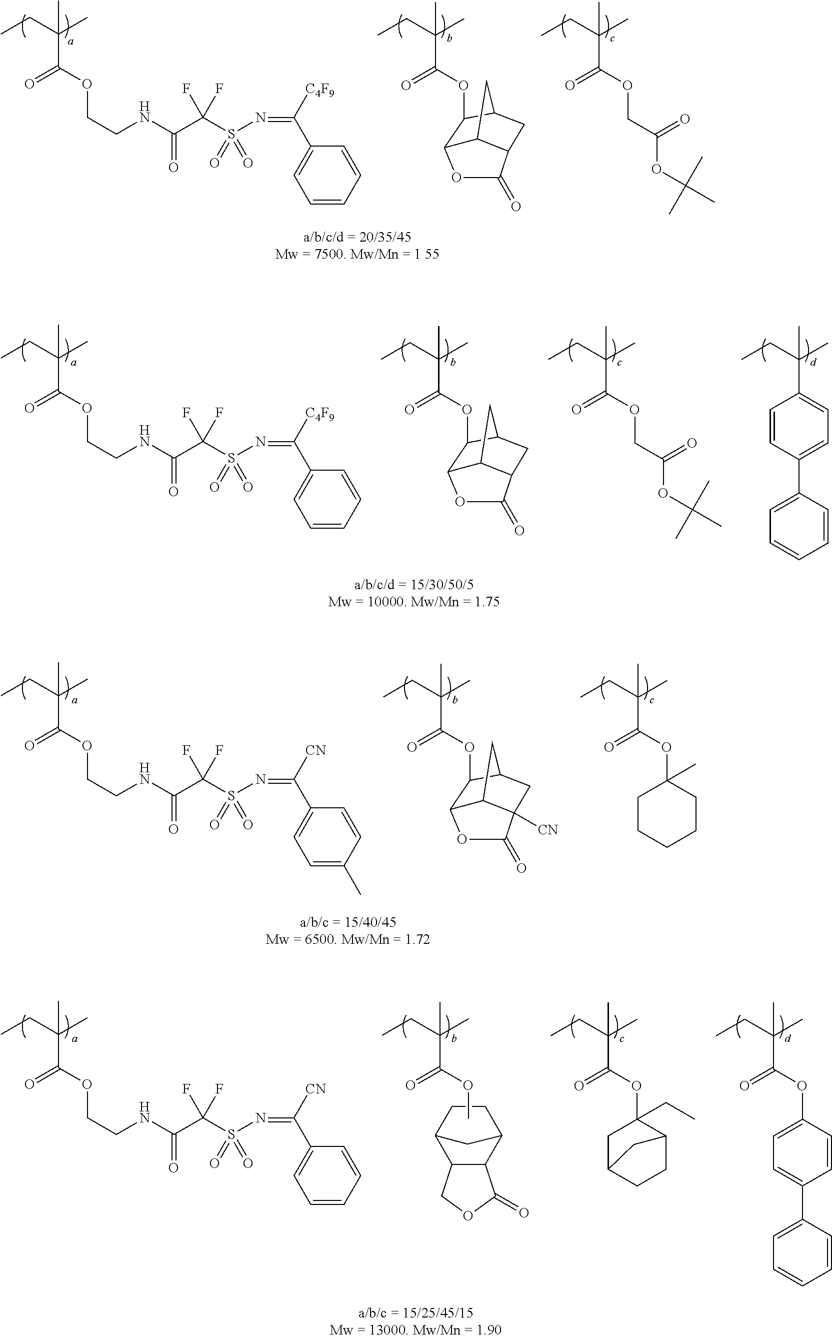

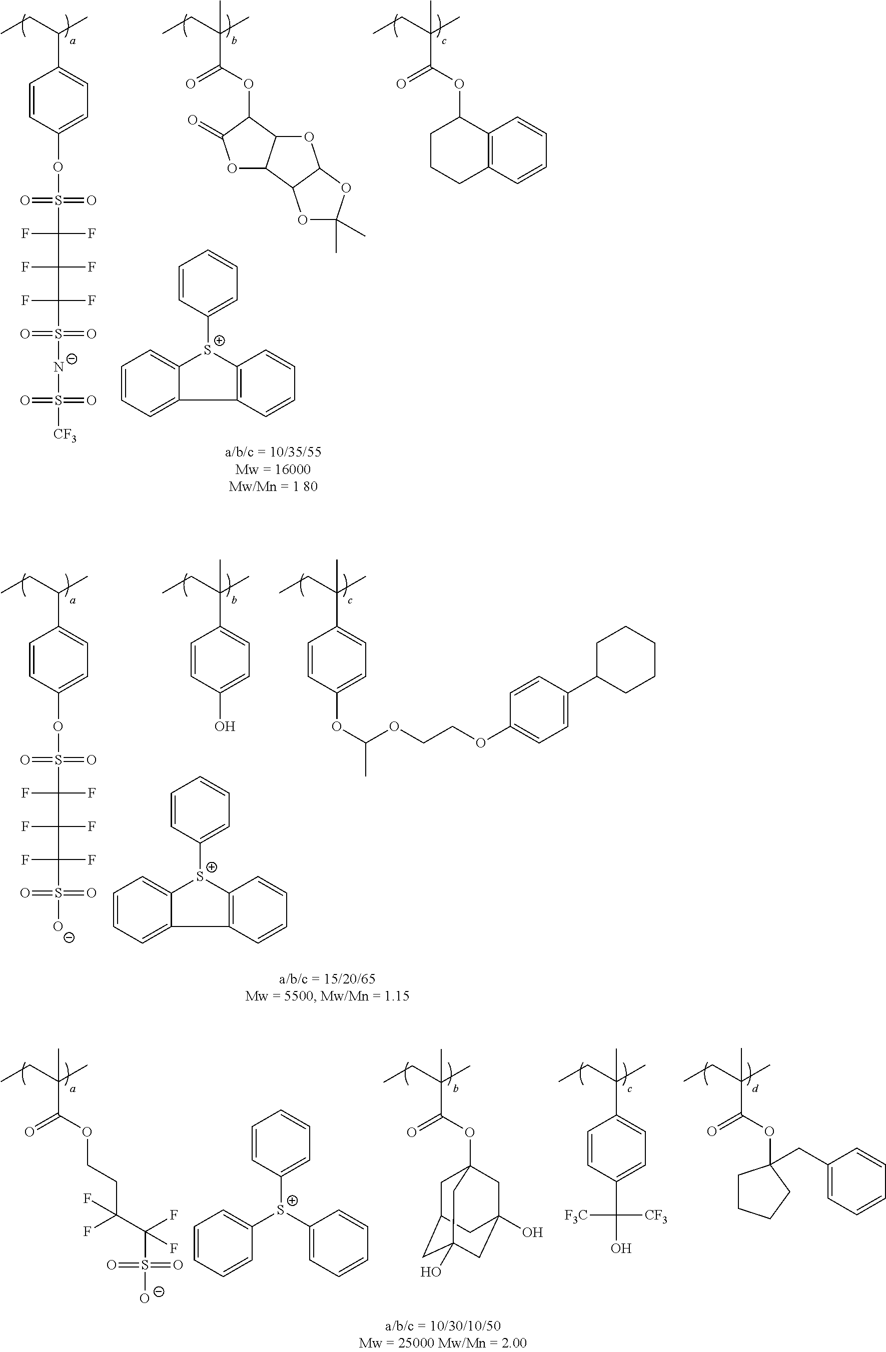

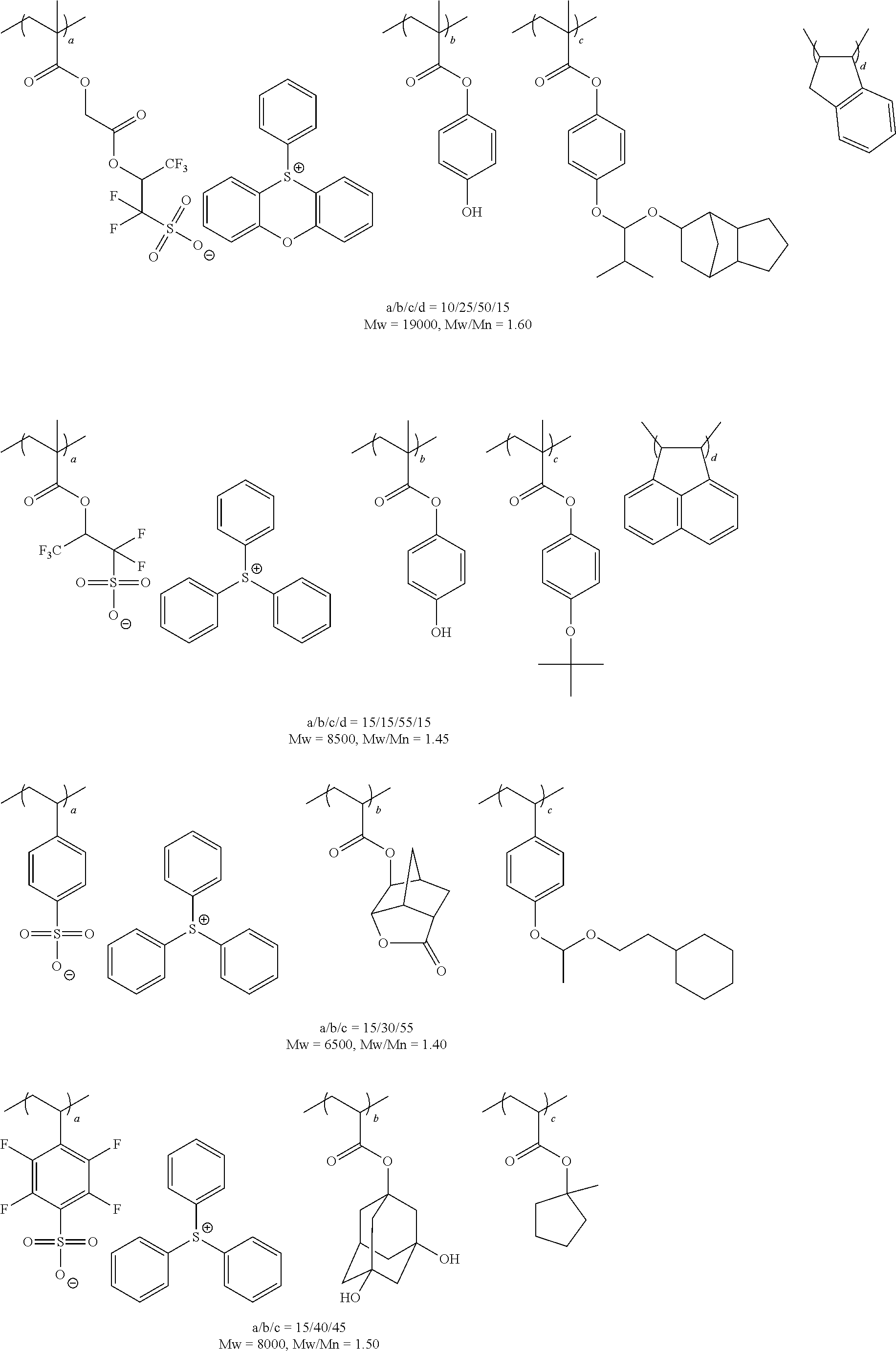

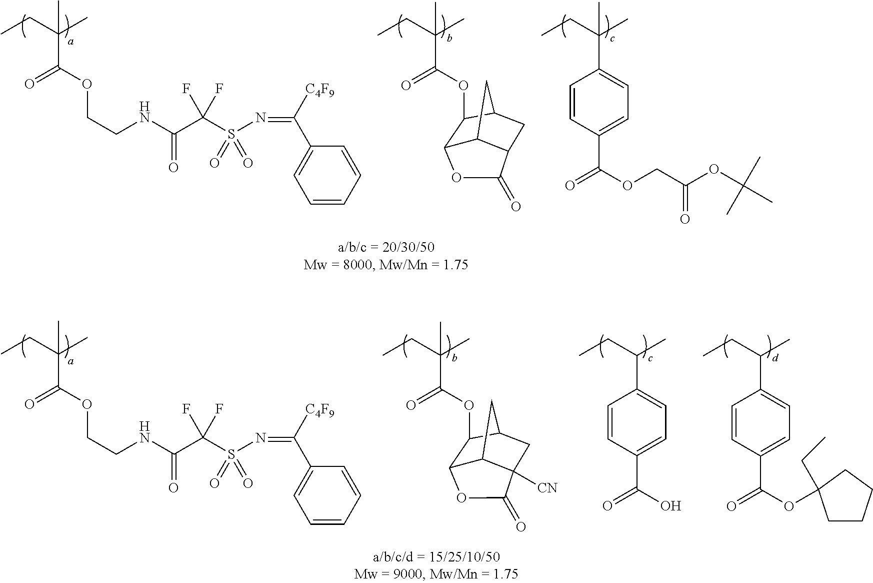

[2] Compound Capable of Generating Acid by Irradiation with Actinic Rays or Radiation

The composition in the present invention typically contains a compound capable of generating an acid by irradiation with actinic rays or radiation (hereinafter also referred to as a “compound (B)” or an “acid generator”). The compound (B) capable of generating an acid by irradiation with actinic rays or radiation is preferably a compound capable of generating an organic acid by irradiation with actinic rays or radiation.

The acid generator which is appropriately selected from a photoinitiator for cationic photopolymerization, a photoinitiator for radical photopolymerization, a photodecoloring agent for a dye, a photodiscoloring agent, a known compound capable of generating an acid by irradiation with actinic rays or radiation, which is used for a microresist or the like, and a mixture thereof can be used.

Examples thereof include a diazonium salt, a phosphonium salt, a sulfonium salt, an iodonium salt, imide sulfonate, oxime sulfonate, diazodisulfone, disulfone, and o-nitrobenzyl sulfonate.

Among the acid generators, particularly preferred examples are shown below.

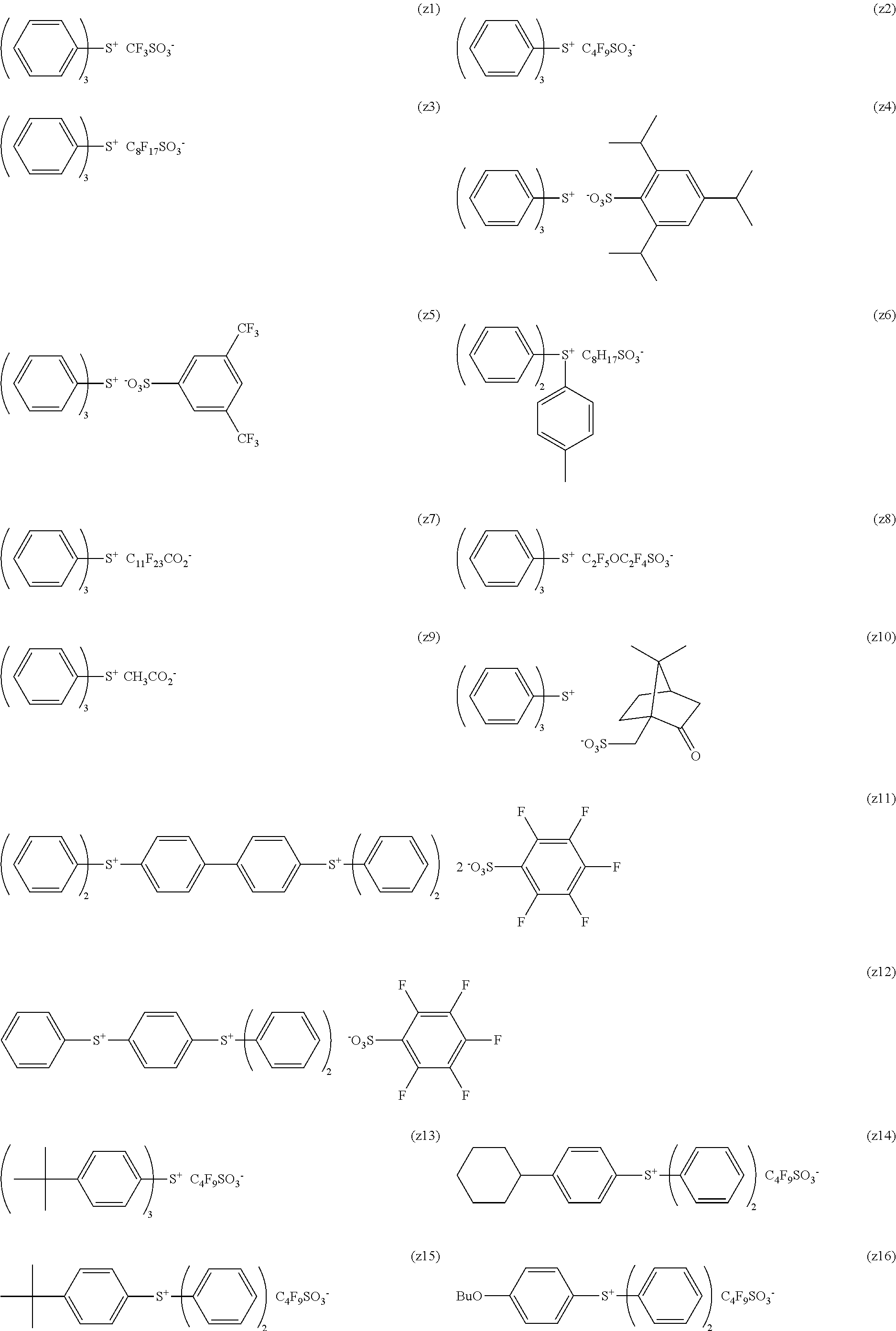

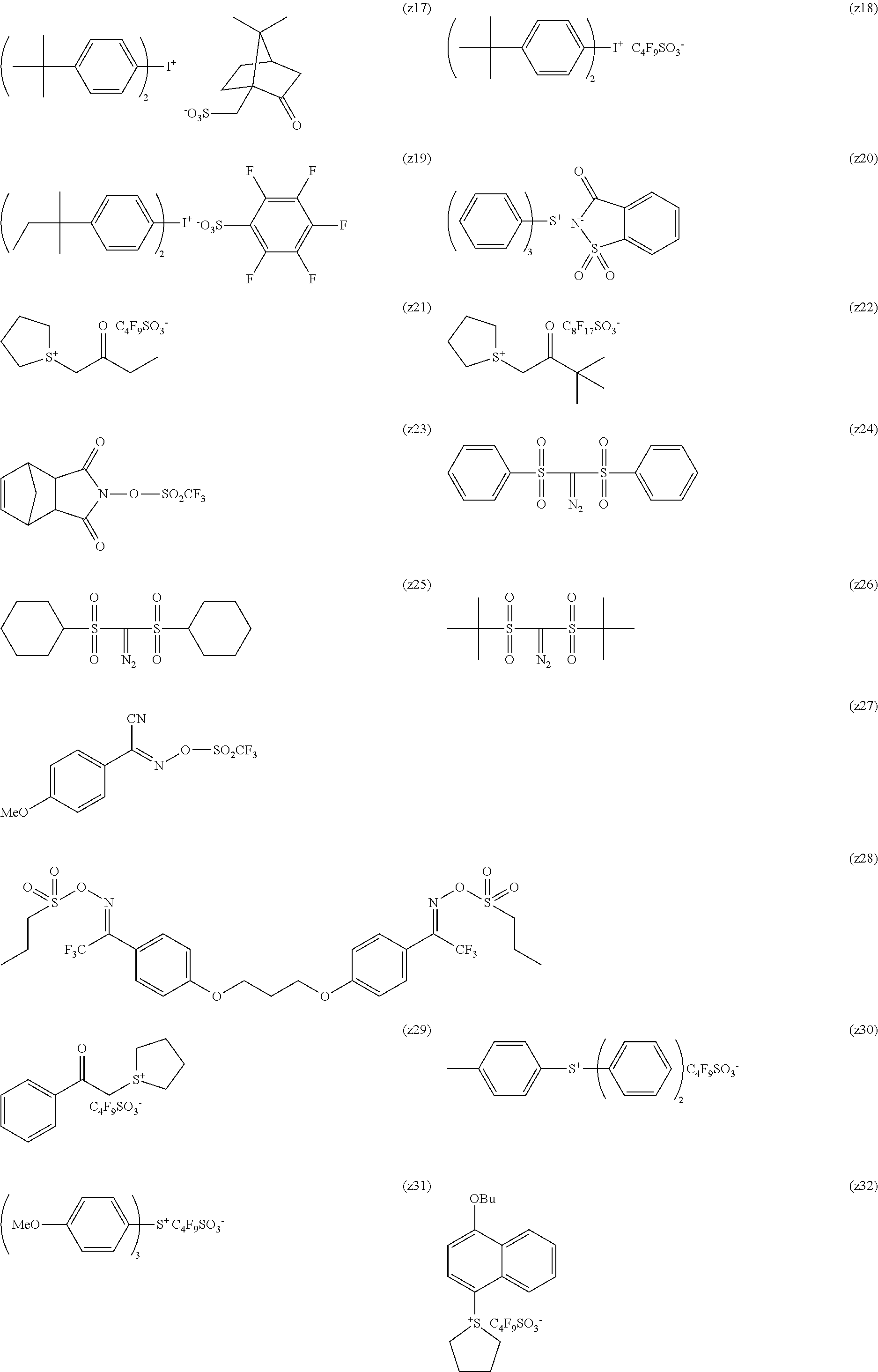

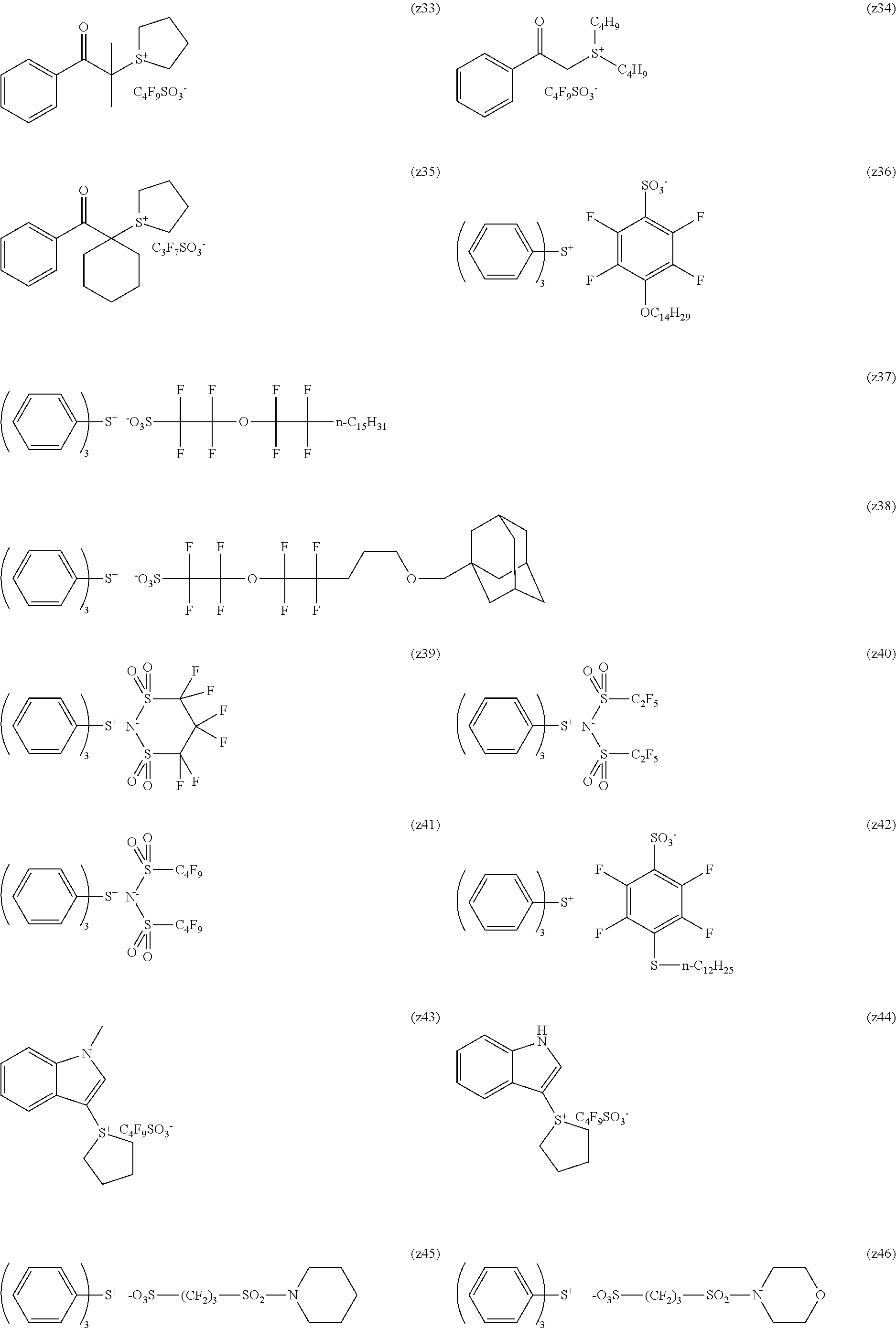

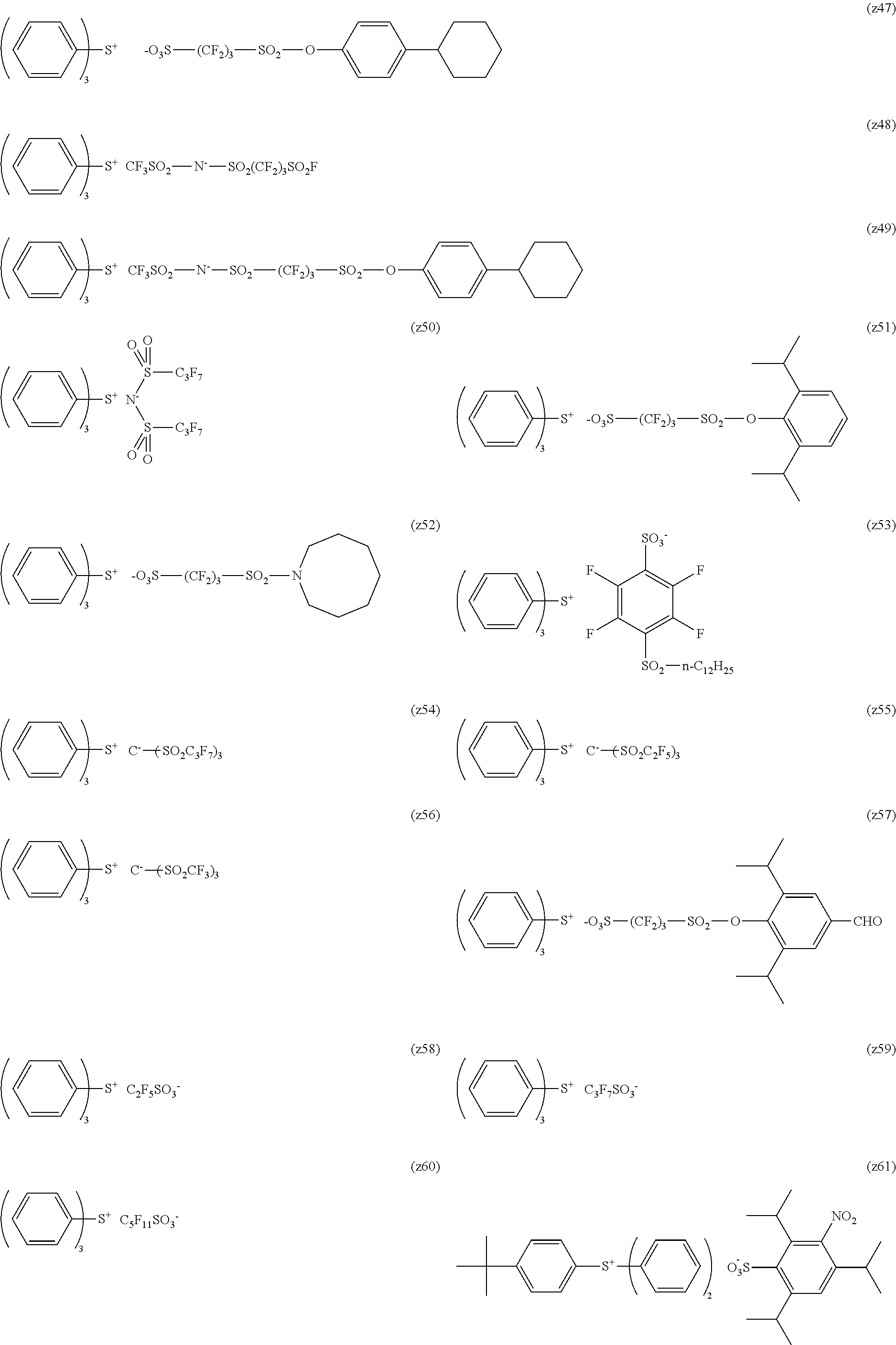

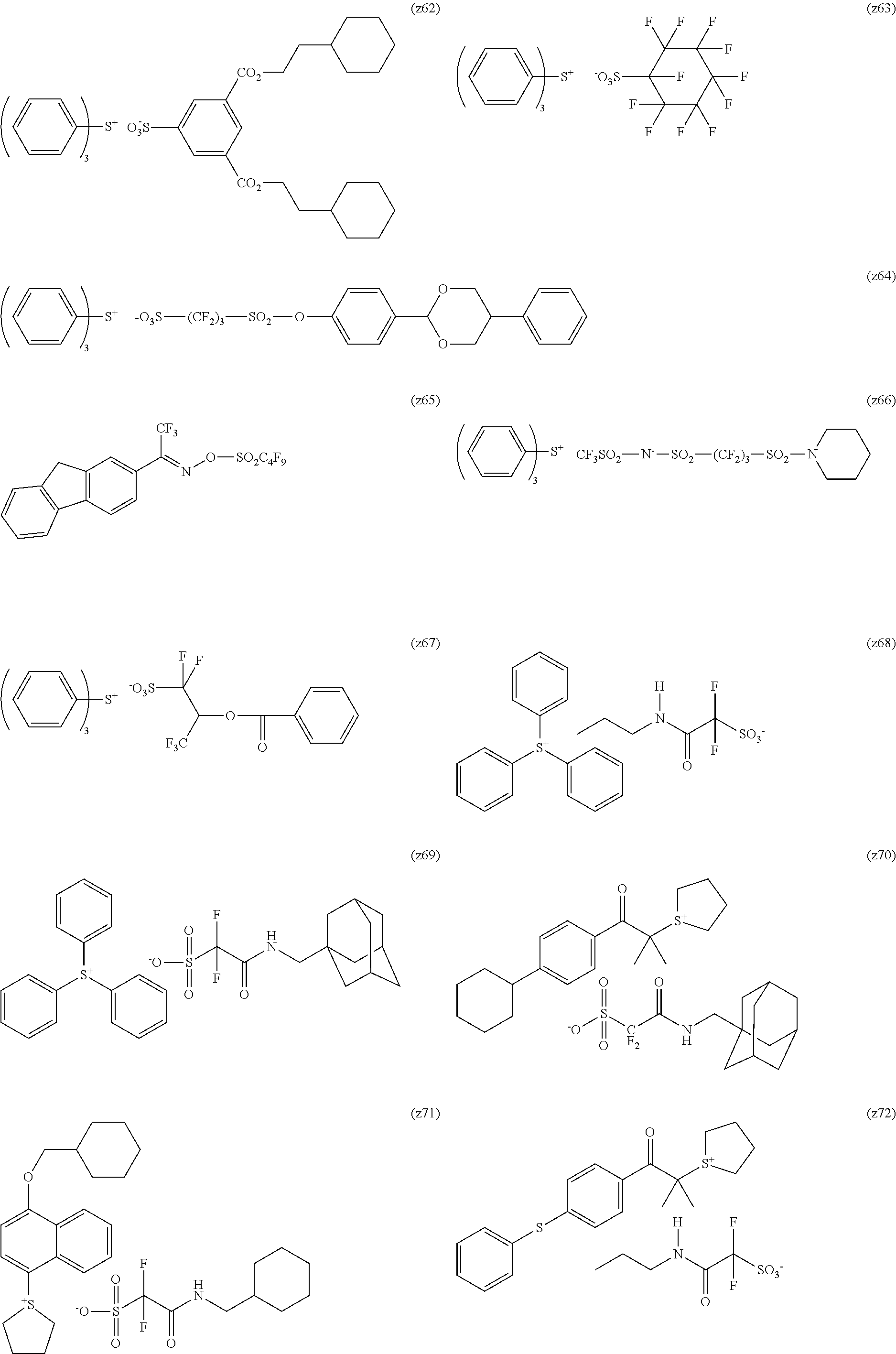

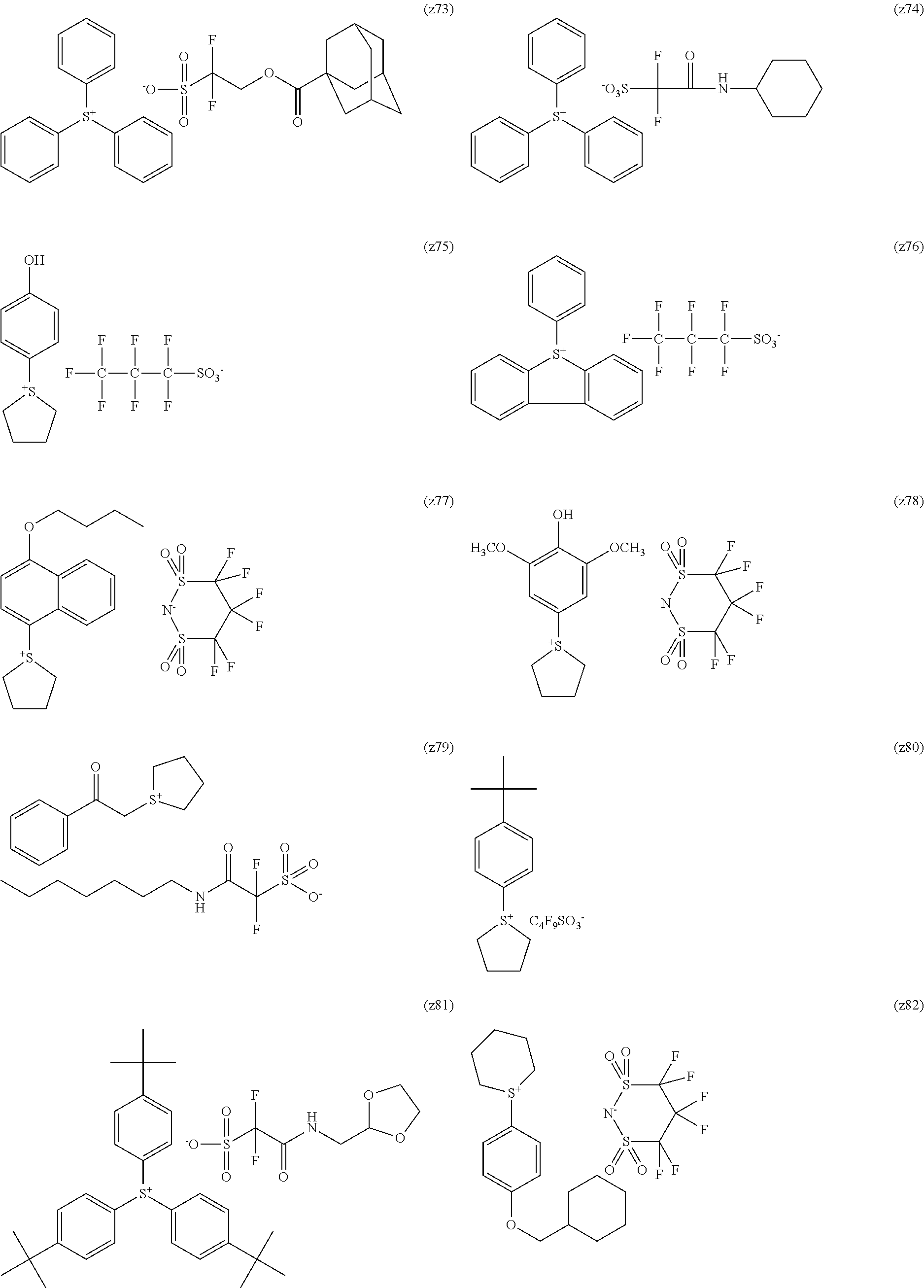

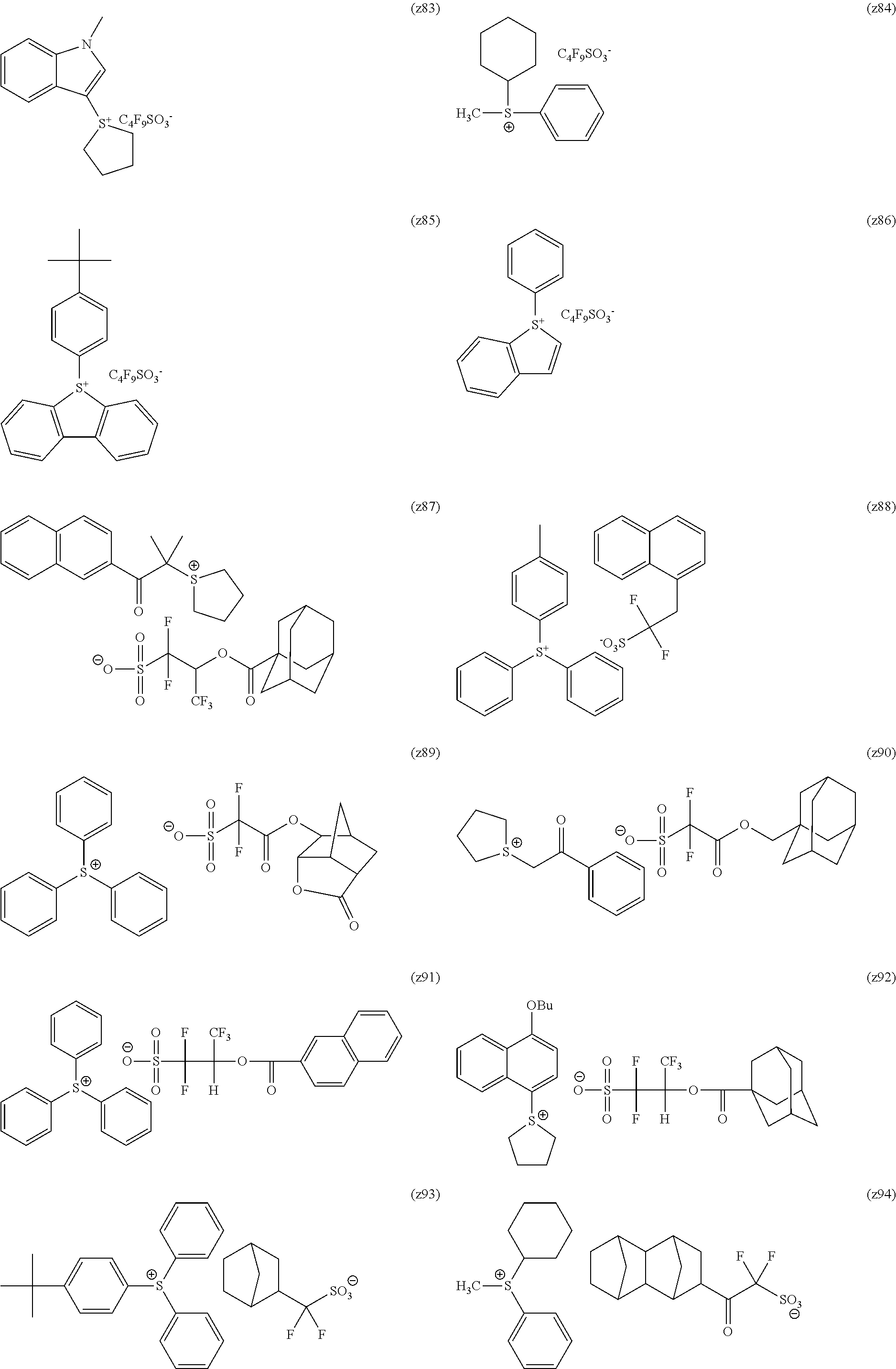

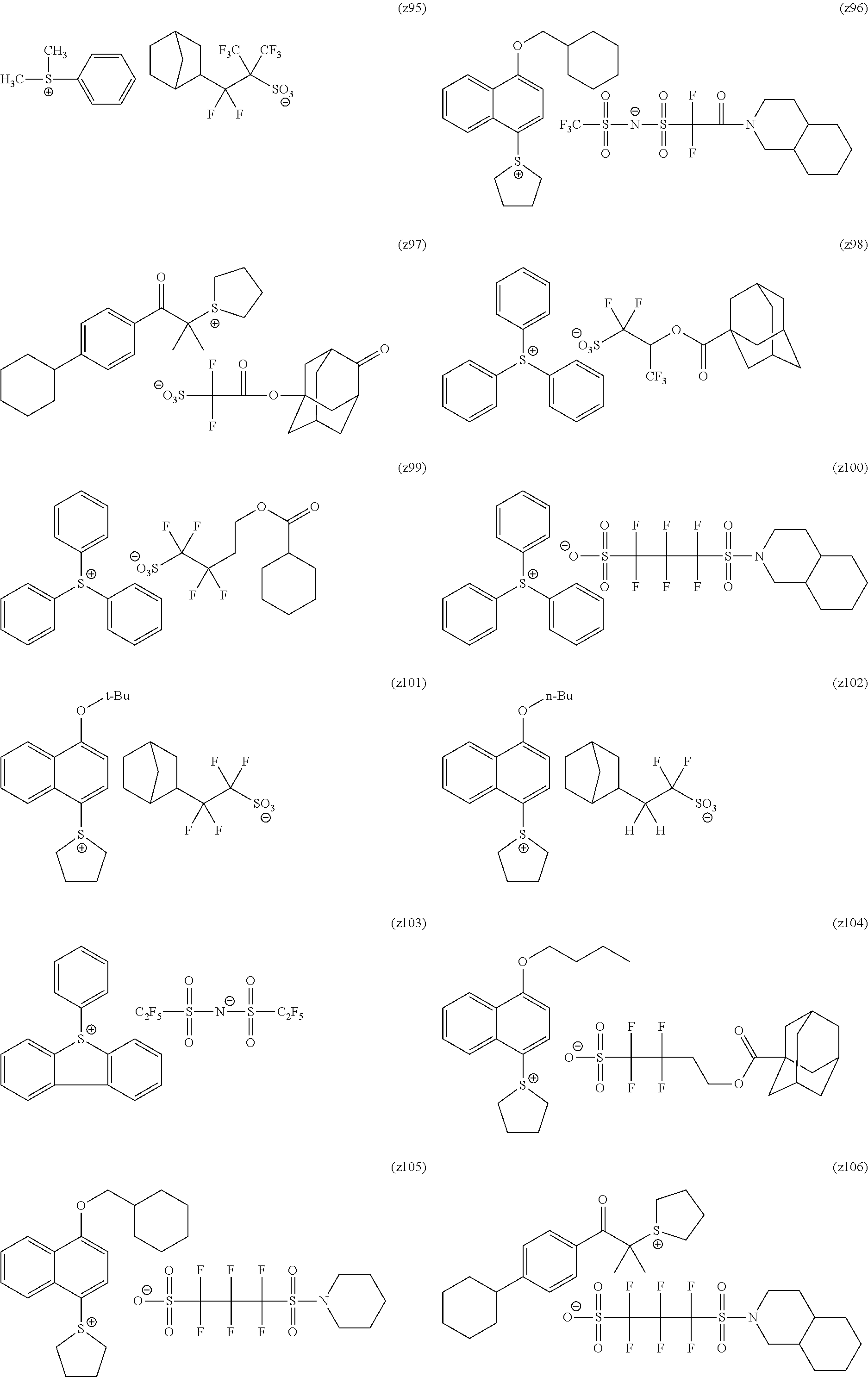

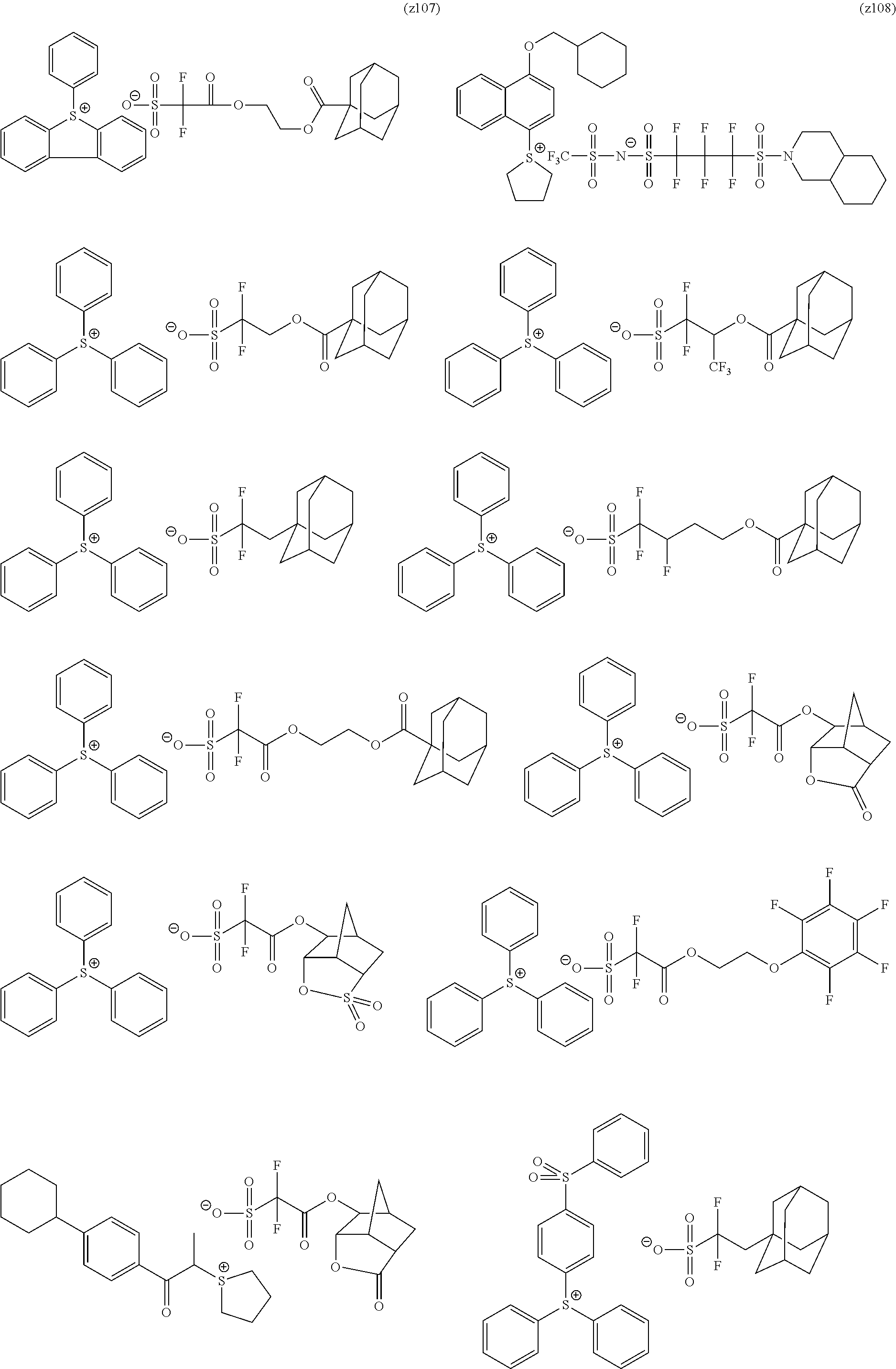

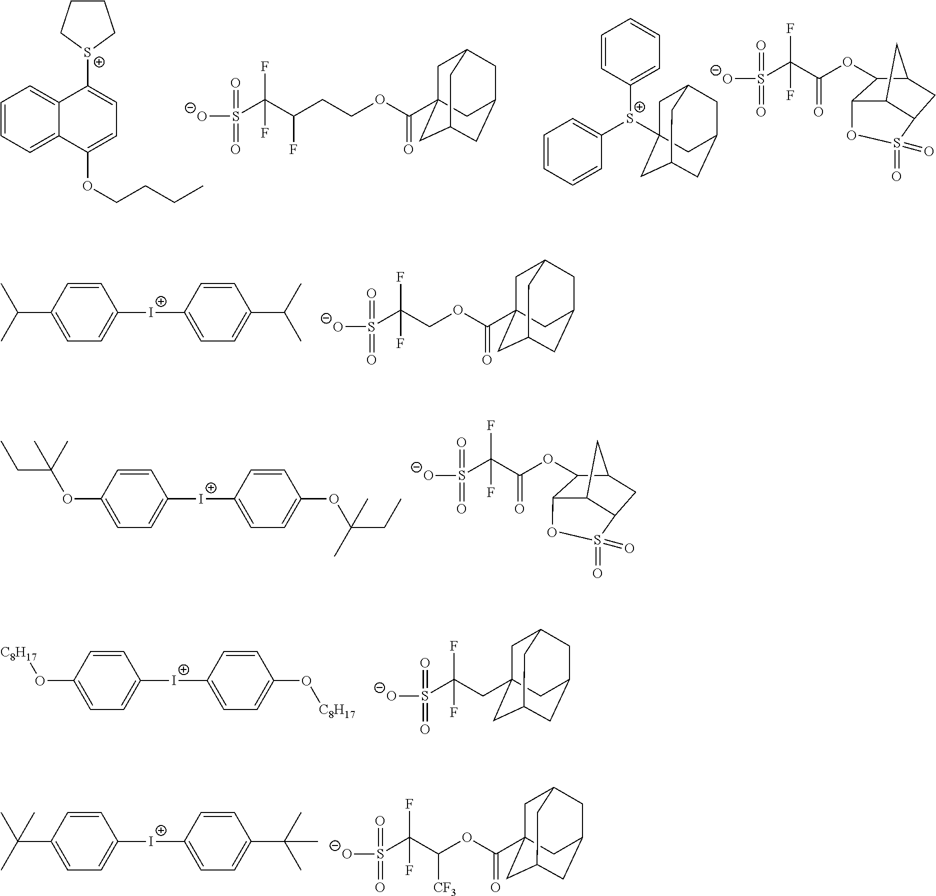

The acid generators can be synthesized by a known method, and can be synthesized in accordance with the methods described in, for example, JP2007-161707A, “0200” to “0210” of JP2010-100595A, “0051” to “0058” of WO2011/093280A, “0382” to “0385” of WO2008/153110A, JP2007-161707A, and the like.

The acid generators can be used alone or in combination of two or more kinds thereof.

The content of the compound capable of generating an acid by irradiation with actinic rays or radiation in the composition is preferably from 0.1% by mass to 30% by mass, more preferably from 0.5% by mass to 25% by mass, still more preferably from 3% by mass to 20% by mass, and particularly preferably from 3% by mass to 15% by mass, with respect to the total solid content of the composition of the present invention.

Incidentally, depending on the actinic ray-sensitive or radiation-sensitive resin composition, there is also an embodiment (B′) in which the structure corresponding to the acid generator is supported on the resin (A). Specific examples of such an embodiment include the structures described in JP2011-248019A (in particular, the structures described in paragraphs “0164” to “0191”, and the structures included in the resin described in Examples of paragraph “0555”). In addition, even in the embodiment in which the structure corresponding to the acid generator is supported on the resin (A), the actinic ray-sensitive or radiation-sensitive resin composition may further contain an acid generator which is not supported on the resin (A).

Examples of the embodiment (B′) include, but are not limited to, the repeating units as described below.

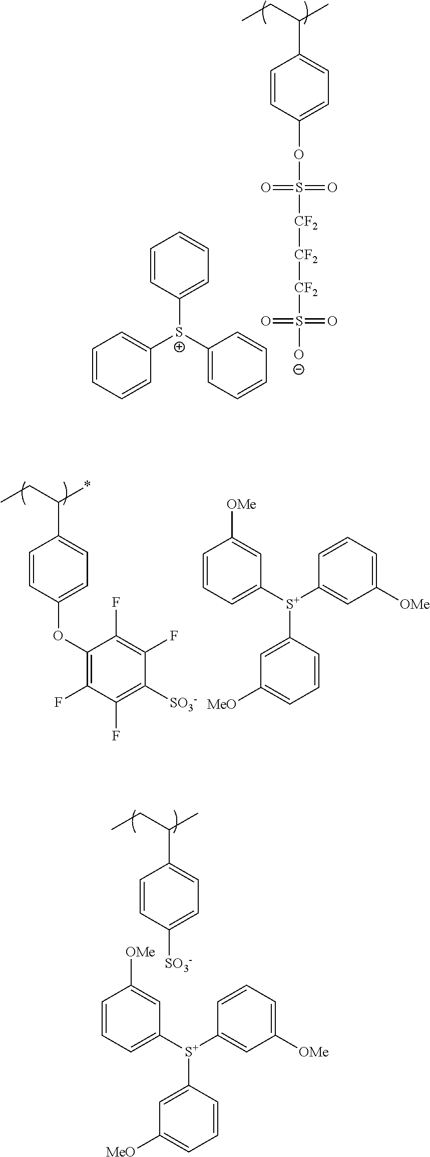

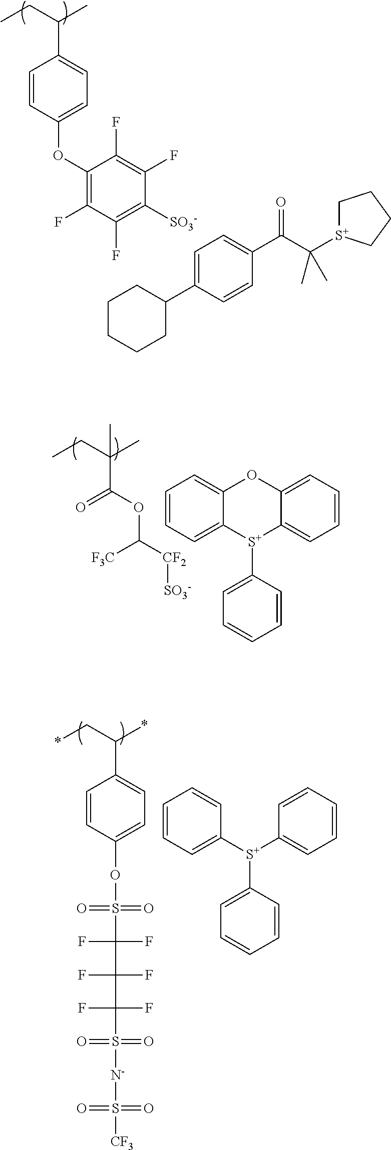

[3] Solvent

The composition of the present invention typically contains a solvent.

Examples of the solvent that can be used in the preparation of the composition of the present invention include organic solvents such as alkylene glycol monoalkyl ether carboxylate, alkylene glycol monoalkyl ether, alkyl lactate ester, alkyl alkoxypropionate, cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of these solvents include ones described in, for example, “0441” to “0445” of US 2008/0187860A.

In the present invention, a mixed solvent of a solvent containing a hydroxyl group in the structure and a solvent containing no hydroxyl group may be used as the organic solvent.

The solvent containing a hydroxyl group and the solvent containing no hydroxyl group can be suitably selected from the exemplary compounds as mentioned above. However, as the solvent containing a hydroxyl group, alkylene glycol monoalkyl ether, alkyl lactate, or the like is preferred, and propylene glycol monomethyl ether (PGME, alternative name: 1-methoxy-2-propanol) or ethyl lactate is more preferred. Further, as the solvent containing no hydroxyl group, alkylene glycol monoalkyl ether acetate, alkyl alkoxy propionate, a monoketone compound which may contain a ring, cyclic lactone, alkyl acetate, or the like is preferred. Among these, propylene glycol monomethyl ether acetate (PGMEA, alternative name: 1-methoxy-2-acetoxypropane), ethylethoxypropionate, 2-heptanone, γ-butyrolactone, cyclohexanone, and butyl acetate are particularly preferred, and propylene glycol monomethyl ether acetate, ethylethoxypropionate, and 2-heptanone are most preferred.

The mixing ratio (mass) of the solvent containing a hydroxyl group to the solvent containing no hydroxyl group is from 1/99 to 99/1, preferably from 10/90 to 90/10, and more preferably from 20/80 to 60/40. A mixed solvent having 50% by mass or more of the solvent containing no hydroxyl group is particularly preferred in view of application uniformity.

The solvents may be used alone or as a mixture of two or more kinds thereof. The solvent preferably contains propylene glycol monomethyl ether acetate, and is preferably a solvent composed of propylene glycol monomethyl ether acetate alone or a mixed solvent of two or more kinds of solvents including propylene glycol monomethyl ether acetate.

[4] Hydrophobic Resin (D)

The composition of the present invention may contain a hydrophobic resin (hereafter also referred to as a “hydrophobic resin (D)” or simply a “resin (D)”), particularly when the composition is applied to liquid immersion exposure. Incidentally, it is preferable that the hydrophobic resin (D) is different from the resin (A).

Accordingly, the hydrophobic resin (D) is unevenly distributed to the film surface layer, and in the case where the liquid immersion medium is water, the static/dynamic contact angle of the resist film surface with respect to water is improved, which can enhance the followabiltiy of the immersion liquid. Further, in the case of BUY exposure, it can be expected that a so-called outgas is inhibited, which is thus preferable.

It is preferable that the hydrophobic resin (D) is designed to be unevenly distributed to the interface as mentioned above, but in contrast to a surfactant, the resin (D) is not necessarily required to have a hydrophilic group in the molecule, and may not contribute to uniform mixing of polar/nonpolar materials.

From the viewpoint of uneven distribution to the film surface layer, it is preferable that the hydrophobic resin (D) contains at least any one kind of a “fluorine atom”, a “silicon atom”, and a “CH₃ partial structure contained in the side chain portion of the resin”, and it is more preferable that the resin (D) contains two or more kinds thereof.

The weight-average molecular weight of the hydrophobic resin (D) in terms of standard polystyrene is preferably from 1,000 to 100,000, more preferably from 1,000 to 50,000, and still more preferably from 2,000 to 15,000.

Furthermore, the hydrophobic resins (D) may be used alone or in combination of two or more kinds thereof.

The content of the hydrophobic resin (D) in the composition is preferably from 0.01% by mass to 10% by mass, more preferably from 0.05% by mass to 8% by mass, and still more preferably from 0.1% by mass to 7% by mass, with respect to the total solid content of the composition of the present invention.

In the hydrophobic resin (D), similarly to the resin (A), it is certain that the content of impurities such as metals is small, but the content of residual monomers or oligomer components is also preferably from 0.01% by mass to 5% by mass, more preferably from 0.01% by mass to 3% by mass, and still more preferably from 0.05% by mass to 1% by mass. Within these ranges, a chemical amplification resist composition free from in-liquid extraneous materials and a change in sensitivity with aging or the like can be obtained. Further, in view of a resolution, a resist profile, the side wall of a resist pattern, a roughness, and the like, the molecular weight distribution (Mw/Mn, also referred to as a dispersity) is preferably in the range of 1 to 5, more preferably 1 to 3, and still more preferably 1 to 2.

As the hydrophobic resin (D), various commercial products may be used, or the resin may be synthesized by an ordinary method (for example, radical polymerization). Examples of the general synthesis method include a batch polymerization method of dissolving monomer species and an initiator in a solvent and heating the solution, thereby carrying out the polymerization, and a dropping polymerization method of adding dropwise a solution containing monomer species and an initiator to a heated solvent for 1 hour to 10 hours, among which the dropping polymerization method is preferred.

The reaction solvent, the polymerization initiator, the reaction conditions (a temperature, a concentration, and the like) and the method for purification after reaction are the same as ones described for the resin (A), but in the synthesis of the hydrophobic resin (D), the concentration at the reaction is preferably from 30% by mass to 50% by mass. More specifically, the method described in, for example, paragraphs “0320” to “0329” of JP2008-292975A, can be exemplified.

Specific examples of the hydrophobic resin (D) are shown below. Further, the molar ratio of the repeating units (the respective repeating units being shown in order starting from the left side), the weight-average molecular weight, and the dispersity of the respective resins are shown in the following tables.

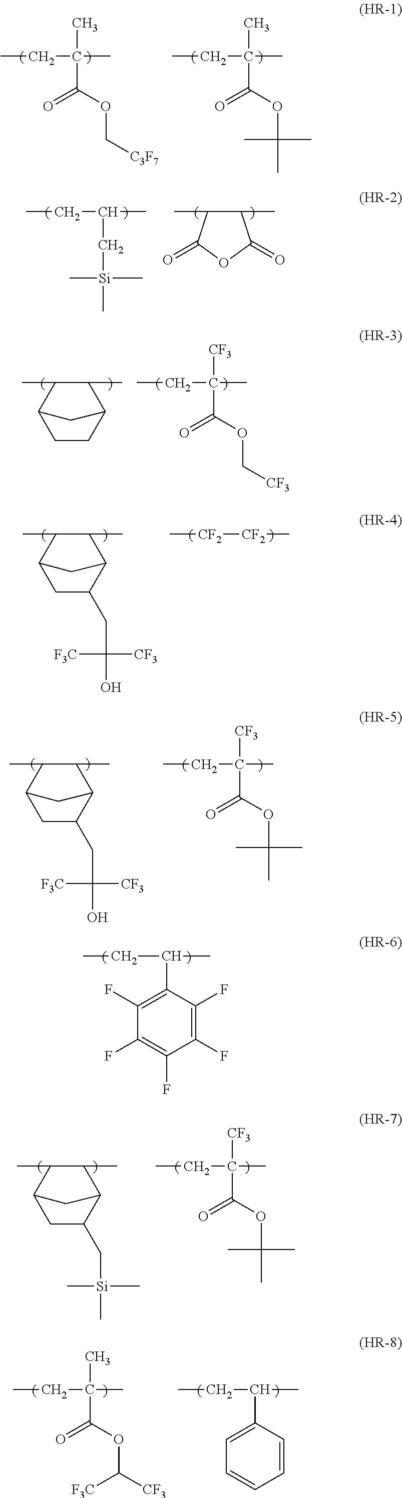

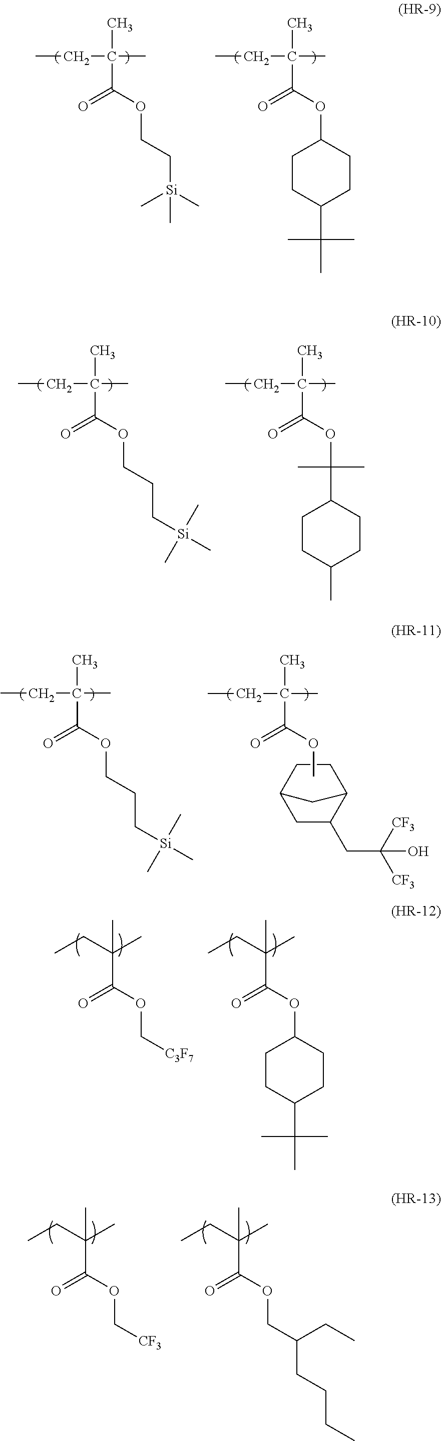

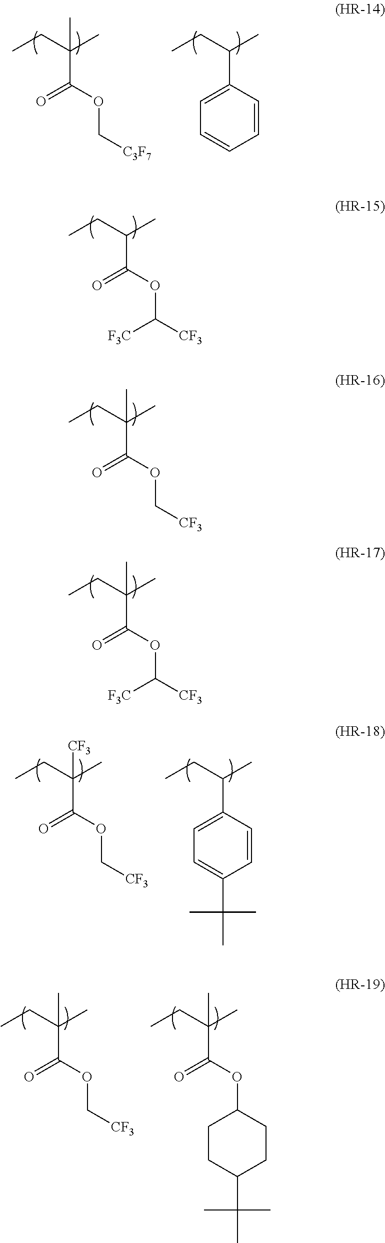

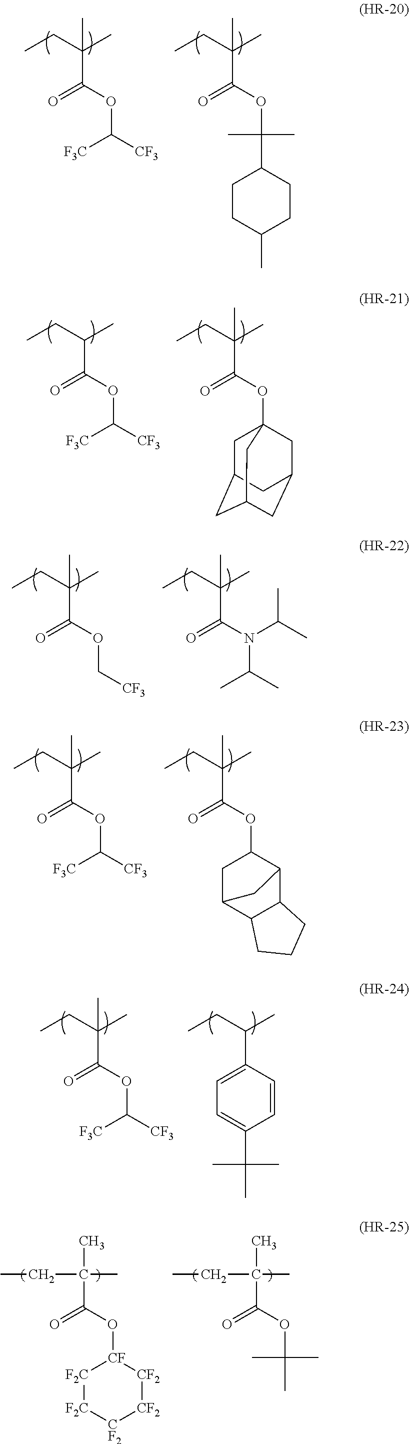

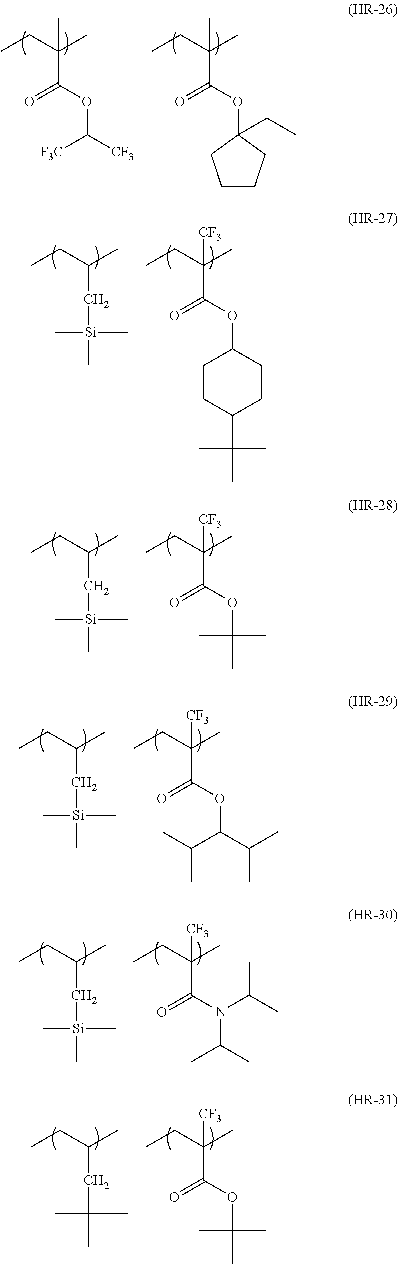

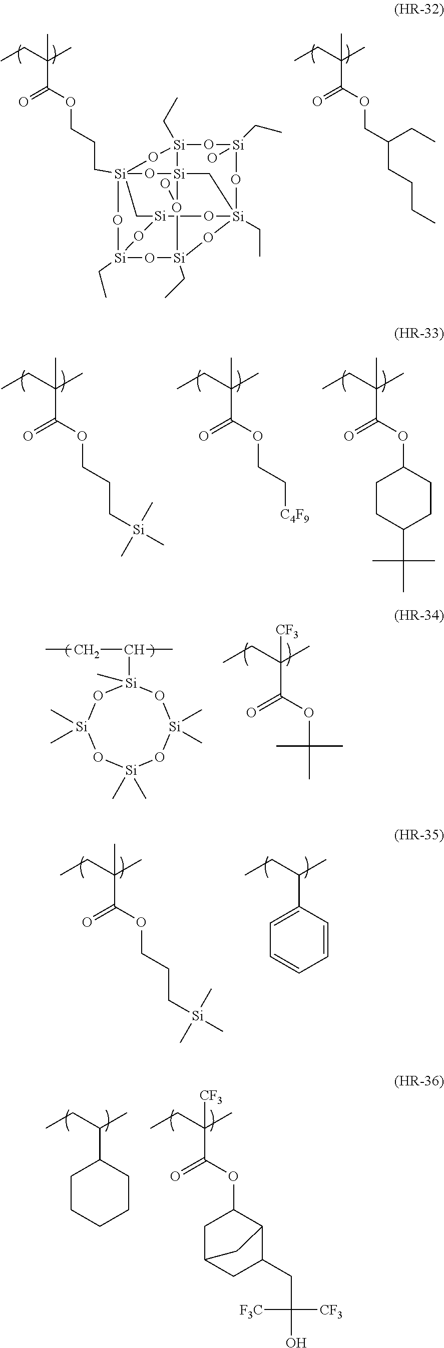

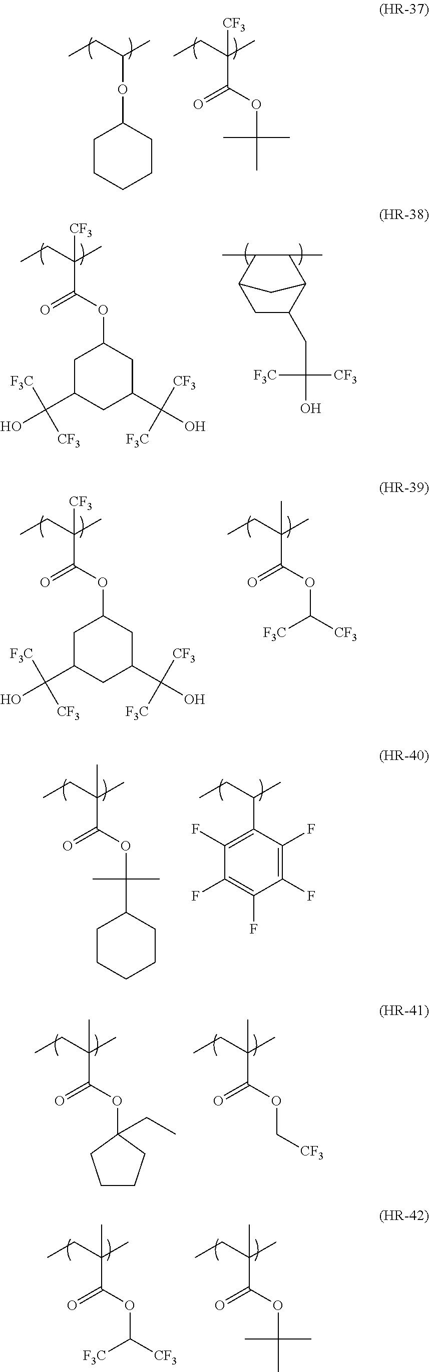

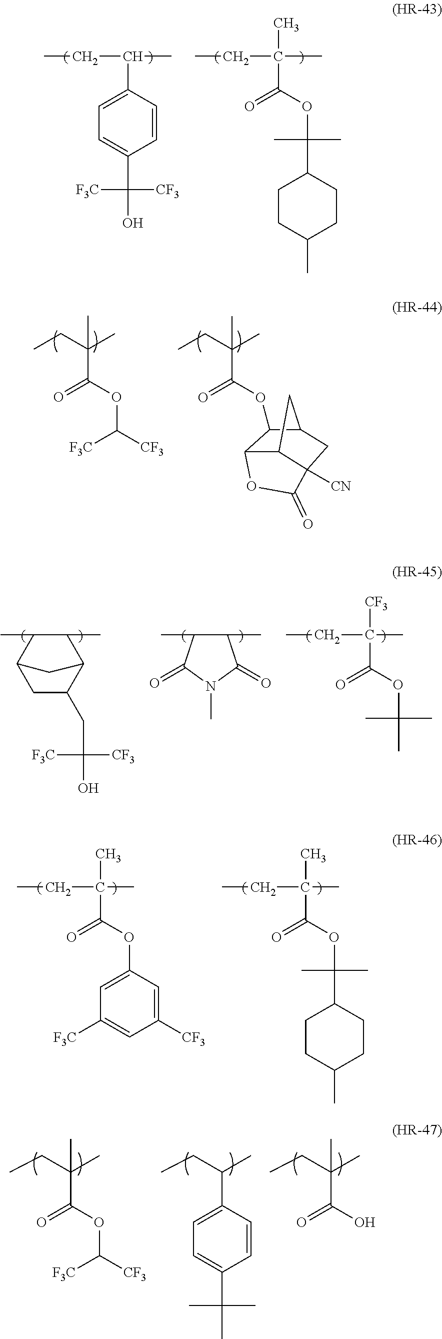

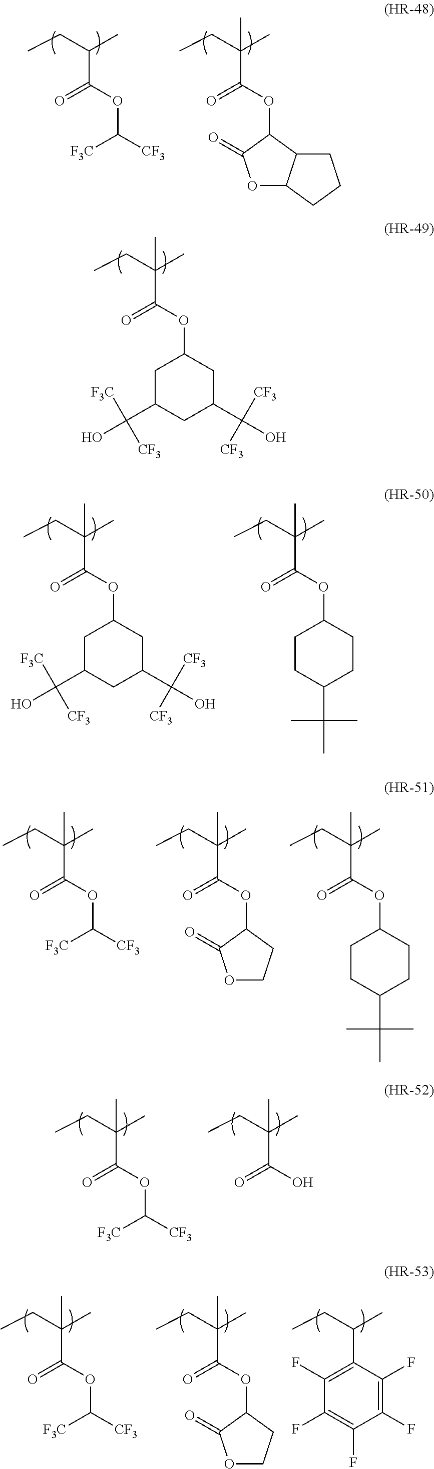

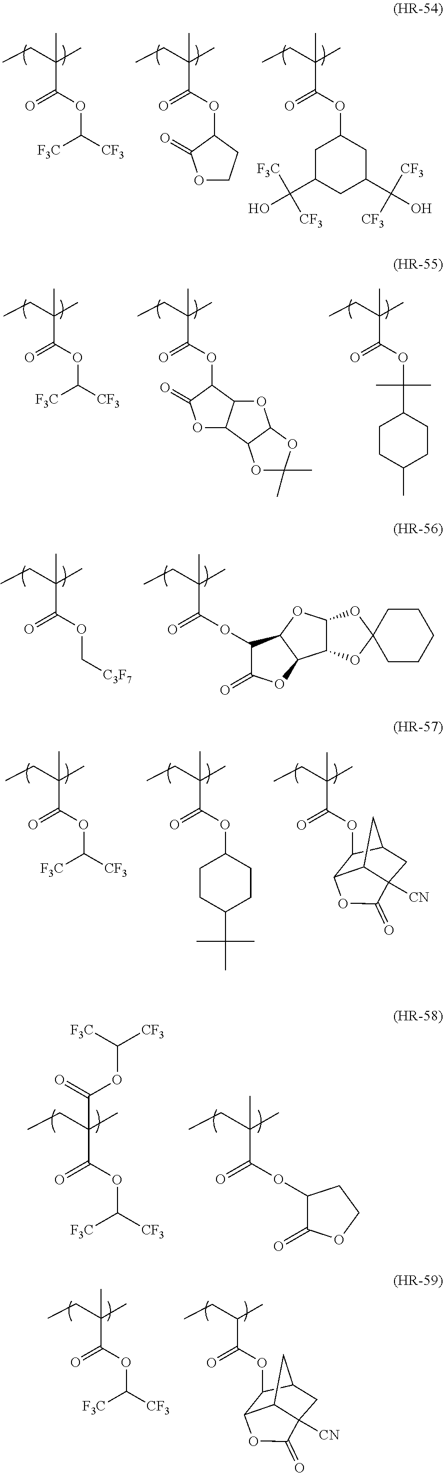

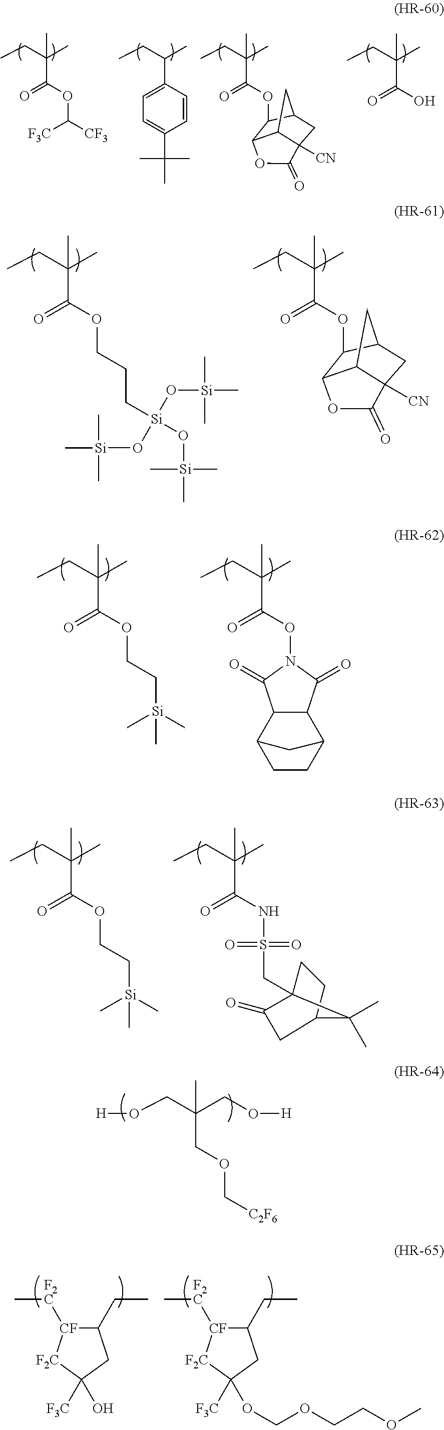

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

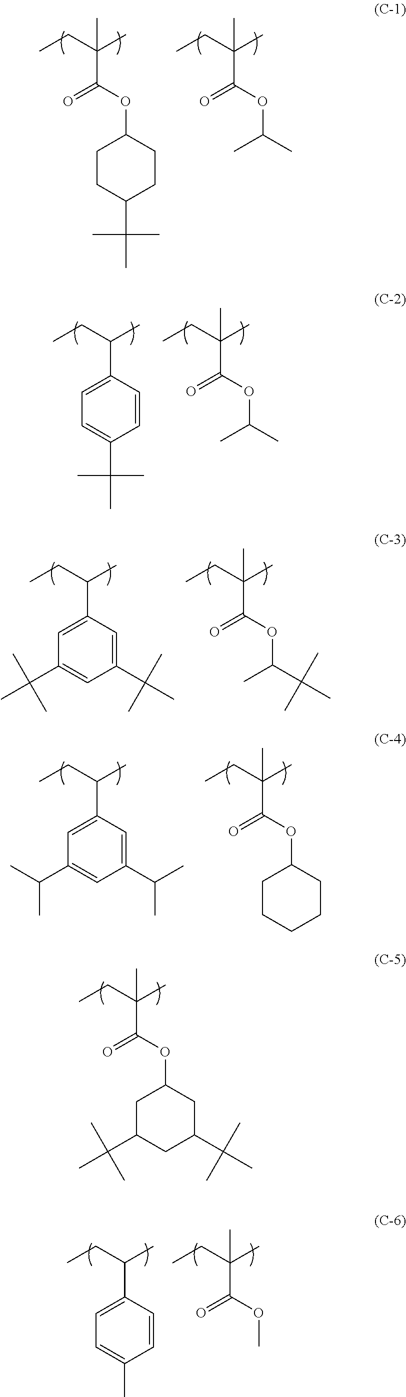

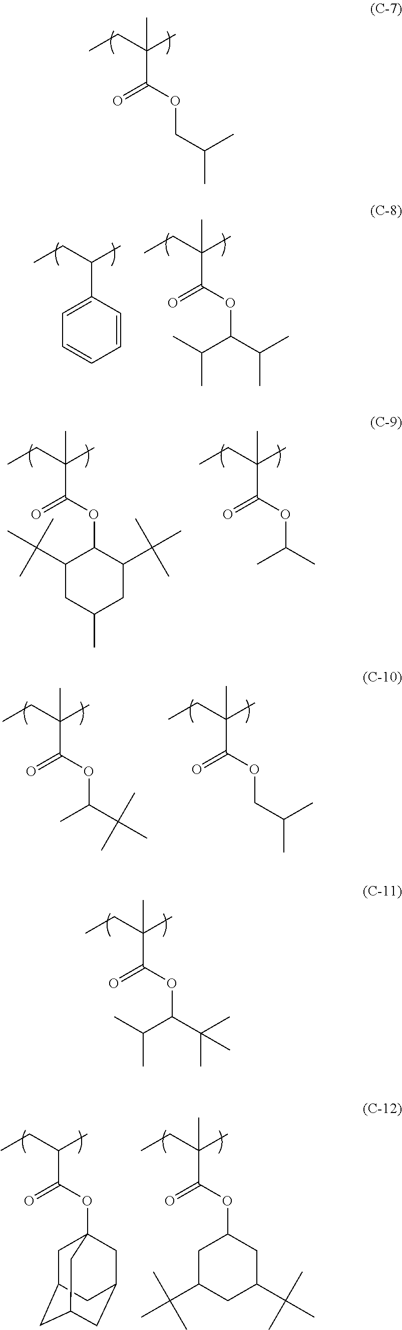

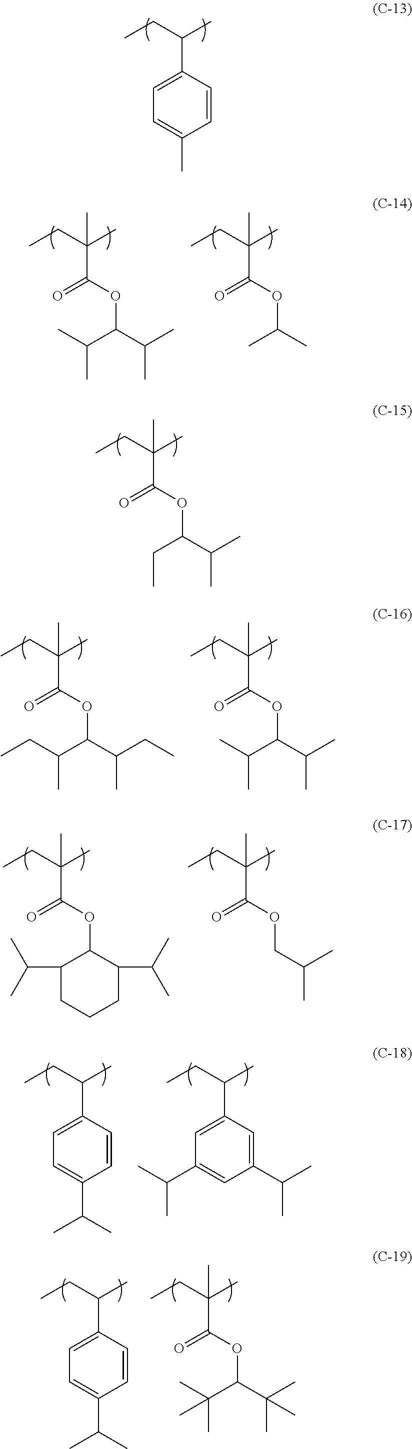

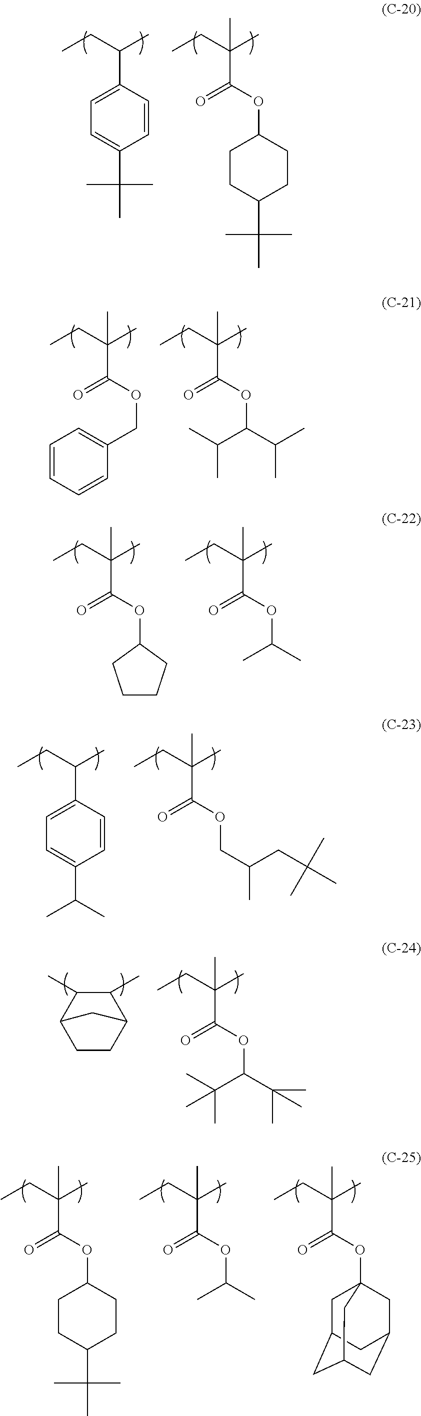

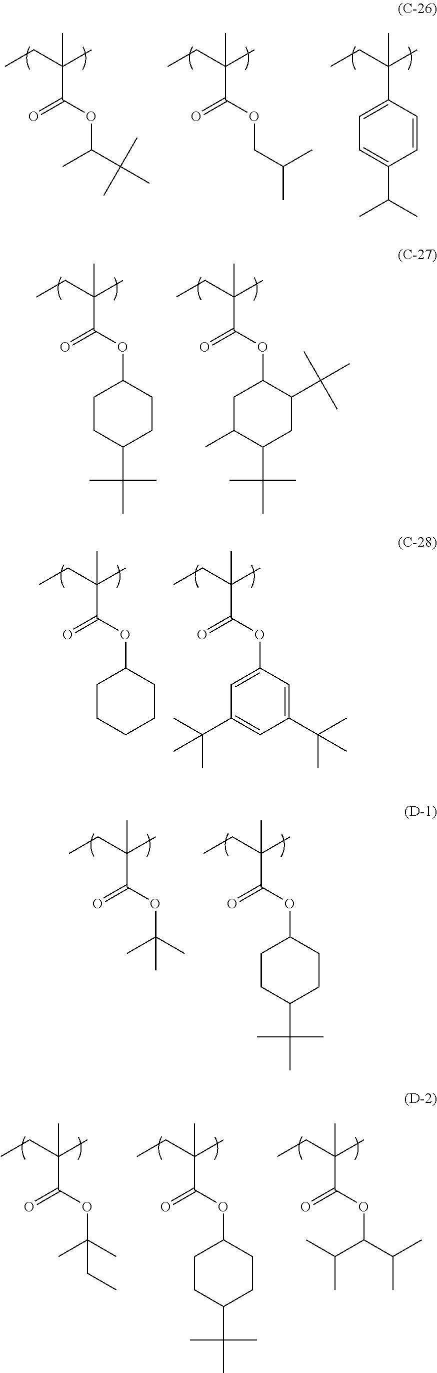

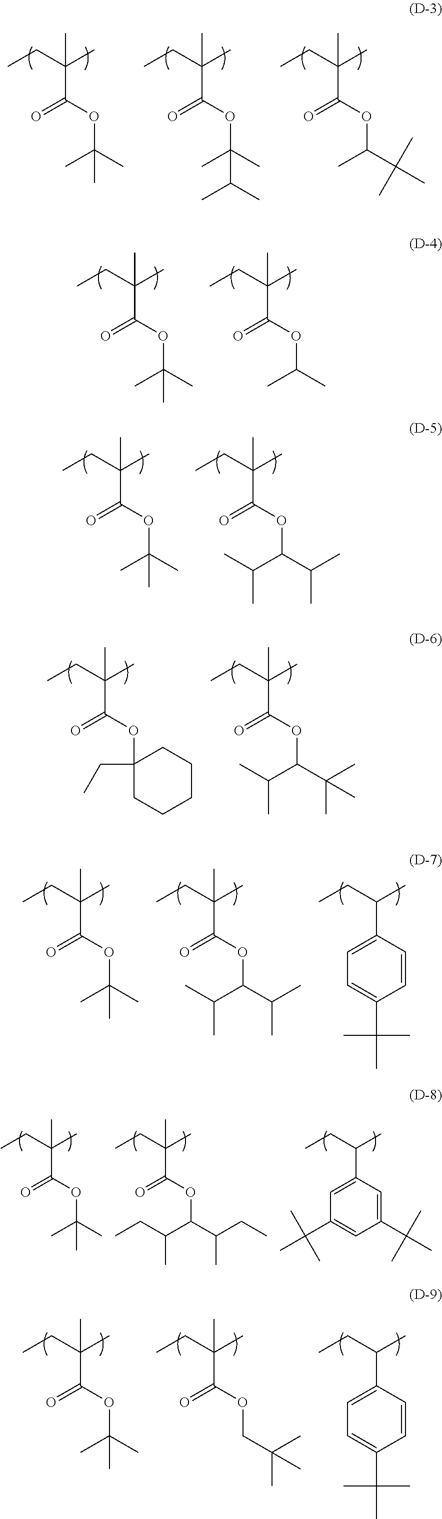

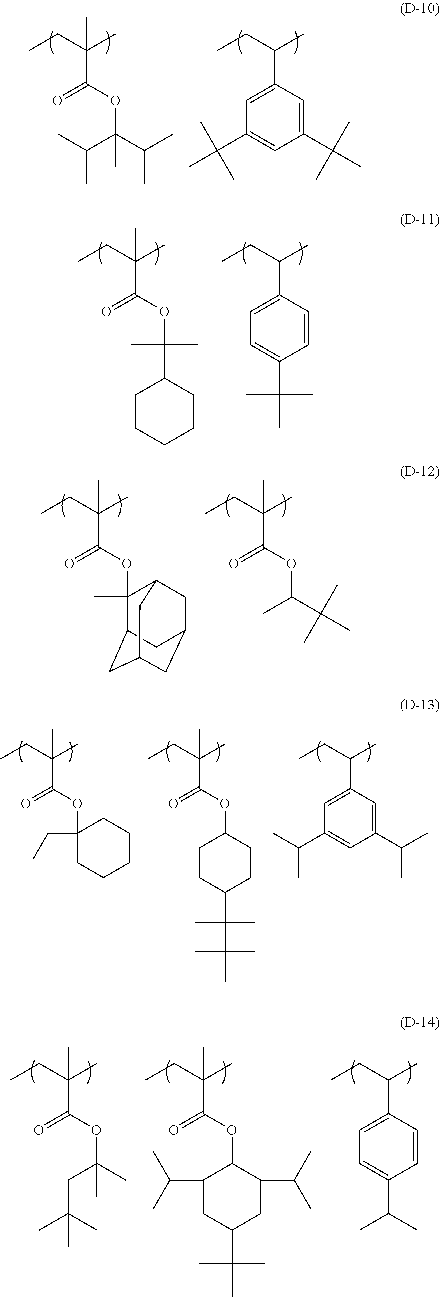

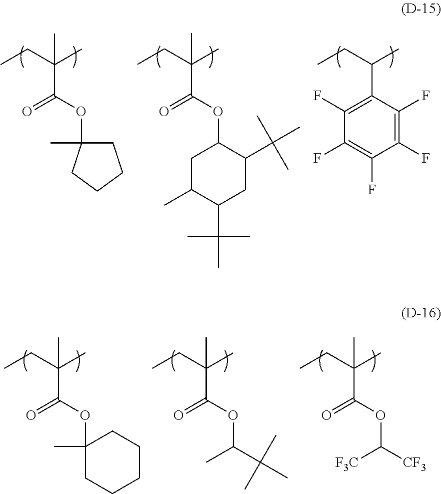

TABLE 2

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 3

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5] Basic Compound

The composition of the present invention preferably contains a basic compound. The basic compounds may be used alone or in combination of two or more kinds thereof.

(1) In one embodiment, the composition of the present invention preferably contains a basic compound or an ammonium salt compound (hereinafter, also referred to as a “compound (N)”) whose basicity is decreased by irradiation with actinic rays or radiation as the basic compound.

The compound (N) is preferably a compound (N-1) having a basic functional group or an ammonium group, and a group capable of generating an acidic functional group by irradiation with actinic rays or radiation. That is, the compound (N) is preferably a basic compound having a basic functional group, and a group capable of generating an acidic functional group by irradiation with actinic rays or radiation, or an ammonium salt compound having an ammonium group, and a group capable of generating an acidic functional group by irradiation with actinic rays or radiation.

Specific examples of the compound (N) include the following compounds. Further, in addition to the compounds mentioned above, as the compound (N), for example, the compounds of (A−1) to (A-44) described in US2010/0233629A and the compounds of (A−1) to (A-23) described in US2012/0156617A can also be preferably used in the present invention.

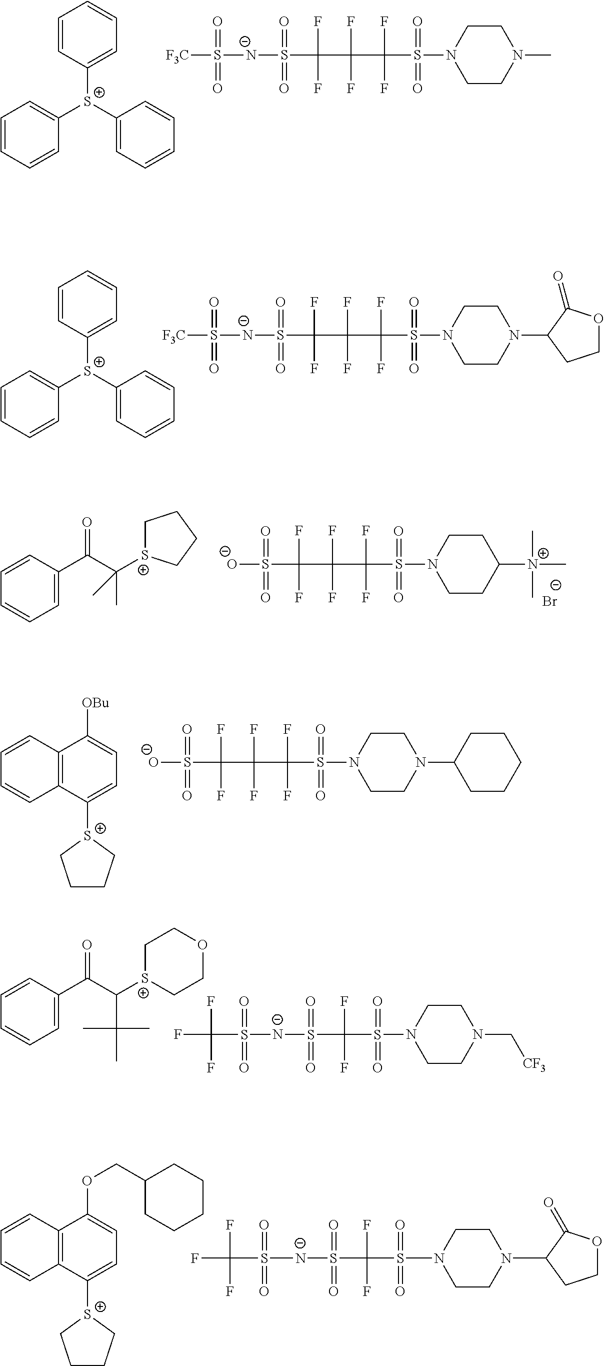

These compounds can be synthesized in accordance with Synthesis Examples described in JP2006-330098A, or the like.

The molecular weight of the compound (N) is preferably from 500 to 1000.

The composition of the present invention may or may not contain a compound (N), but in the case where the compound (N) is contained, the content of the compound (N) is preferably from 0.1% by mass to 20% by mass, and more preferably from 0.1% by mass to 10% by mass, based on the solid content of the composition.

(2) In another embodiment, the composition of the present invention may contain a basic compound (N′) other than the compound (N) as the basic compound in order to reduce a change in performance with aging from exposure to heating.

Preferred examples of the basic compound (N′) include compounds having structures represented by the following General Formulae (A′) to (E′).

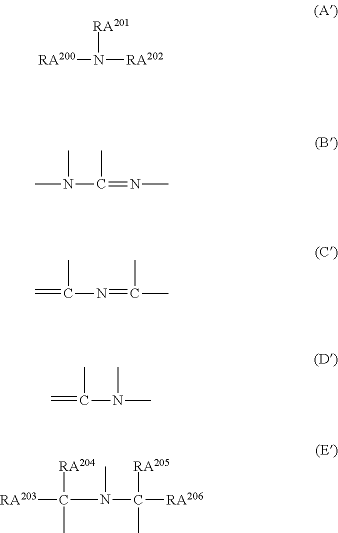

In General Formulae (A′) and (E′),

RA²⁰⁰, RA²⁰¹, and RA²⁰², which may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), and RA²⁰¹ and RA²⁰² may be bonded to each other to form a ring. RA²⁰³, RA²⁰⁴, RA²⁰⁵, and RA²⁰⁶, which may be the same as or different from each other, each represent an alkyl group (preferably having 1 to 20 carbon atoms).

The alkyl group may have a substituent, and as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferred.

It is more preferable for the alkyl groups in General Formulae (A′) and (E′) to be unsubstituted.

Specific preferred examples of the basic compound (N′) include guanidine, aminopyrrolidine, pyrazole, pyrazoline, piperazine, aminomorpholine, aminoalkylmorpholine, and piperidine. More specific preferred examples thereof include compounds having an imidazole structure, a diazabicyclo structure, an onium hydroxide structure, an onium carboxylate structure, a trialkylamine structure, an aniline structure, or a pyridine structure; alkylamine derivatives having a hydroxyl group and/or an ether bond; and aniline derivatives having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]nona-5-ene, and 1,8-diazabicyclo[5,4,0]undeca-7-ene. Examples of the compound having an onium hydroxide structure include triarylsulfonium hydroxide, phenacylsulfonium hydroxide, sulfonium hydroxide having 2-oxoalkyl group, specifically triphenylsulfonium hydroxide, tris(t-butyl phenyl)sulfonium hydroxide, bis(t-butyl phenyl)iodonium hydroxide, phenacylthiophenium hydroxide, and 2-oxopropylthiophenium hydroxide. The compound having an onium carboxylate structure is a compound in which the anion moiety of the compound having an onium hydroxide structure becomes a carboxylate, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Preferred examples of the basic compound include an amine compound having a phenoxy group, an ammonium salt compound having a phenoxy group, an amine compound having a sulfonic ester group, and an ammonium salt compound having a sulfonic ester group. Specific examples thereof include, but are not limited thereto, the compounds (C1-1) to (C3-3) exemplified in paragraph “0066” of US2007/0224539A.

(3) In another embodiment, the composition of the present invention may contain a nitrogen-containing organic compound having a group capable of leaving by the action of an acid as one of the basic compounds. As the examples of this compound, specific examples of the compound are shown below.

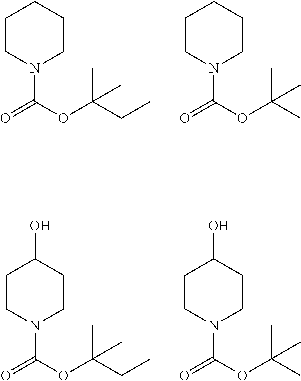

The compound can be synthesized in accordance with, for example, the method described in JP2009-199021A.

Furthermore, as the basic compound (N′), a compound having an amine oxide structure can also be used. As the specific examples of this compound, triethylaminepyridine N-oxide, tributyl amine N-oxide, triethanolamine N-oxide, tris(methoxyethyl)amine N-oxide, tris(2-(methoxymethoxy)ethyl)amine oxide, 2,2′,2″-nitrilotriethylpropionate N-oxide, N-2-(2-methoxyethoxy)methoxyethylmorpholine N-oxide, and the amine oxide compounds exemplified in JP2008-102383A in addition to these can also be used.

The molecular weight of the basic compound (N′) is preferably from 250 to 2000, and more preferably from 400 to 1000. From the viewpoints of further reduction in LWR (Line Width Roughness) and local pattern dimensional uniformity, the molecular weight of the basic compound is preferably 400 or more, more preferably 500 or more, and still more preferably 600 or more.

This basic compound (N′) may be used in combination with the compound (N), or may be used alone or in combination of two or more kinds thereof.

The chemical amplification resist composition in the present invention may or may not contain the basic compound (N′), but in the case where the composition contains the basic compound (N′), the amount of the basic compound (N′) used is usually from 0.001% by mass to 10% by mass, and preferably from 0.01% by mass to 5% by mass, based on the solid content of the chemical amplification resist composition.

(4) In another embodiment, the composition of the present invention may include an onium salt represented by the following General Formula (6A) or (6B) as the basic compound. It is expected that this onium salt regulates the diffusion of generated acids in a resist system in relation to the acid strength of photoacid generators usually used in resist compositions.

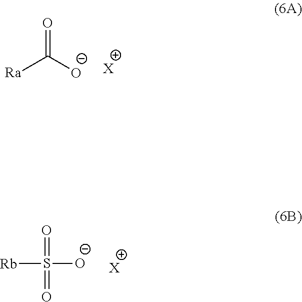

In General Formula (6A),

Ra represents an organic group, provided that any one in which the carbon atom directly bonded to the carboxyl group in the formula is substituted with a fluorine atom is excluded.

X⁺ represents an onium cation.

In General Formula (6B),

Rb represents an organic group, provided that any one in which the carbon atom directly bonded to the sulfonic acid group in the formula is substituted with a fluorine atom is excluded.

X⁺ represents an onium cation.

For organic groups represented by Ra and Rb, the atom directly bonded to the carboxylic acid group, or sulfonic acid group in the formula is preferably a carbon atom. However, in this case, for the realization of a relatively weak acid as compared to the acids generated from the above photoacid generators, the carbon atom directly bonded to the sulfonic acid group or carboxylic acid group is not substituted with a fluorine atom in any case.

Examples of the organic groups represented by Ra and Rb include an alkyl group having 1 to 20 carbon atoms, a cycloalkyl group having 3 to 20 carbon atoms, an aryl group having 6 to 30 carbon atoms, an aralkyl group having 7 to 30 carbon atoms, and a heterocyclic group having 3 to 30 carbon atoms. In these groups, the hydrogen atoms may be partially or entirely replaced.

Examples of the substituents which the alkyl group, the cycloalkyl group, the aryl group, the aralkyl group, and the heterocyclic group can have include a hydroxyl group, a halogen atom, an alkoxy group, a lactone group, and an alkylcarbonyl group.

Examples of the onium cations represented by X⁺ in General Formulae (6A) and (6B) include a sulfonium cation, an ammonium cation, an iodonium cation, a phosphonium cation, and a diazonium cation, among which the sulfonium cation is more preferred.

As the sulfonium cation, for example, an arylsulfonium cation containing at least one aryl group is preferred, and a triarylsulfonium cation is more preferred. The aryl group may have a substituent, and as the aryl group, a phenyl group is preferred.

Preferred examples of the sulfonium cations and iodonium cations include the structures described with respect to the compound (B).

Specific structures of the onium salt represented by General Formula (6A) or (6B) are shown below.

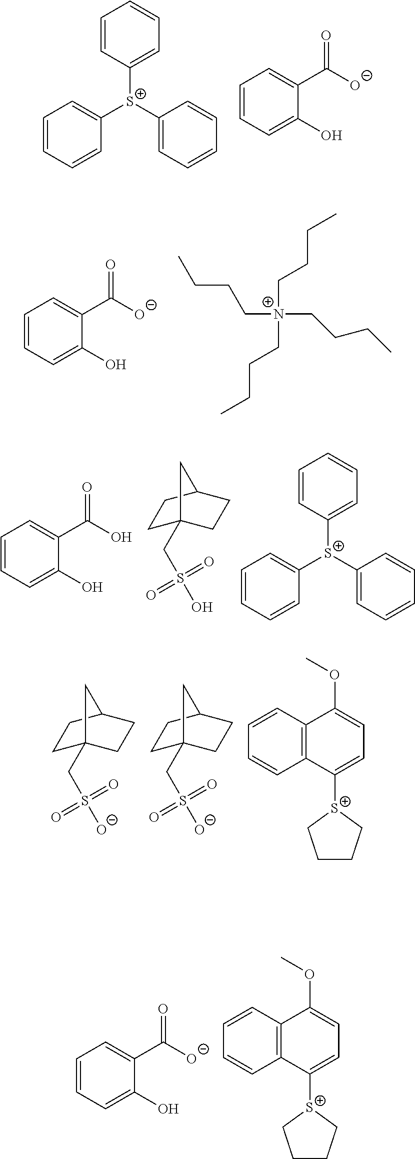

(5) In another embodiment, the composition of the present invention may contain, as the basic compound, a compound (hereinafter also referred to as a “betaine compound”) containing both an onium salt structure and an acid anion structure in one molecule, such as the compound represented by Formula (I) in JP2012-189977A, the compound represented by Formula (I) in JP2013-6827A, the compound represented by Formula (I) in JP2013-8020A, and the compound represented by Formula (I) in JP2012-252124A. Examples of the onium salt structure include sulfonium, iodonium, and ammonium structures, among which the sulfonium or iodonium salt structure is preferred. Further, the acid anion structure is preferably a sulfonic acid anion or a carboxylic acid anion. Examples of these compounds include the following ones.

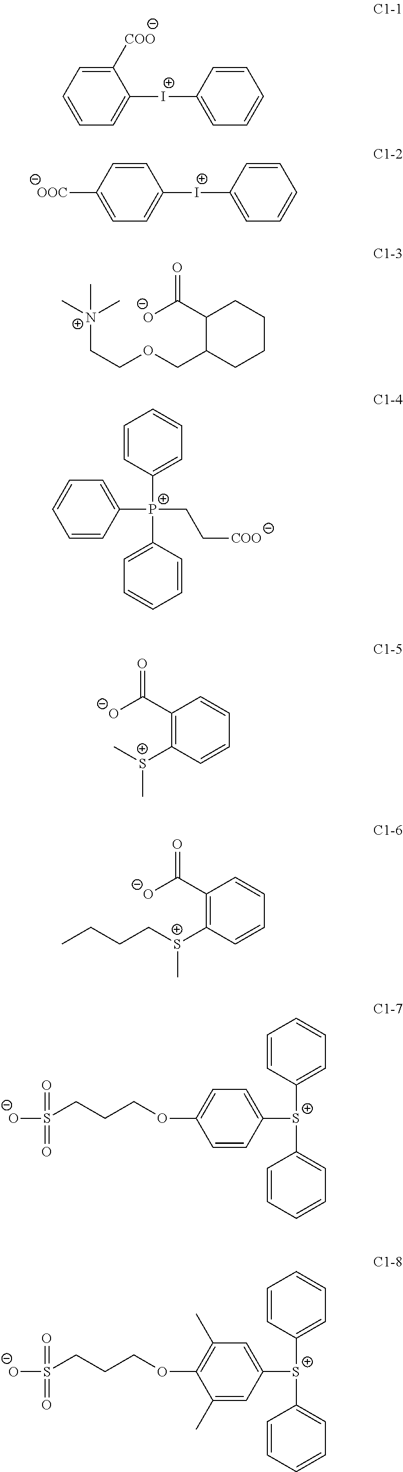

[6] Surfactant

The composition of the present invention may further contain a surfactant. In the case where the composition of the present invention contains the surfactant, it preferably contains any one of fluorine- and/or silicon-based surfactants (a fluorine-based surfactant, a silicon-based surfactant, and a surfactant having both a fluorine atom and a silicon atom), or two or more kinds thereof.

By incorporating the surfactant into the composition of the present invention, it becomes possible to provide a resist pattern which is improved in adhesion and decreased in development defects with good sensitivity and resolution when an exposure light source of 250 nm or less, and particularly 220 nm or less, is used.

Examples of the fluorine- and/or silicon-based surfactants include the surfactants described in “0276” of US2008/0248425A, and examples thereof include EFtop EF301 and EF303 (manufactured by Shin-Akita Kasei K. K.); Florad FC430, 431, and 4430 (manufactured by Sumitomo 3M Inc.); Megaface F171, F173, F176, F189, F113, F110, F177, F120, and R08 (manufactured by DIC Corp.); Surflon S-382, SC101, 102, 103, 104, 105, and 106, and KH-20 (manufactured by Asahi Glass Co., Ltd.); Troysol S-366 (manufactured by Troy Chemical Corp.); GF-300 and GF-150 (manufactured by Toagosei Chemical Industry Co., Ltd.); Surflon S-393 (manufactured by Seimi Chemical Co., Ltd.); EFtop EF121, EF122A, EF122B, RF122C, EF125M, EF135M, EF351, EF352, EF801, EF802, and EF601 (manufactured by JEMCO Inc.); PF636, PF656, PF6320, and PF6520 (manufactured by OMNOVA); and FTX-204G, 208G, 218G, 230G, 204D, 208D, 212D, 218D, and 222D (manufactured by NEOS Co., Ltd.). In addition, Polysiloxane Polymer KP-341 (manufactured by Shin-Etsu Chemical Co., Ltd.) can also be used as the silicon-based surfactant.

Furthermore, in addition to those known surfactants as described above, a surfactant using a polymer having a fluoro-aliphatic group derived from a fluoro-aliphatic compound which is produced by a telomerization method (also referred to as a telomer method) or an oligomerization method (also referred to as an oligomer method), can be used as the surfactant. The fluoro-aliphatic compound can be synthesized in accordance with the method described in JP2002-90991A.

Examples of the surfactant corresponding to the above include Megaface F178, F-470, F-473, F-475, F-476, and F-472 (manufactured by DIC Corp.); a copolymer of an acrylate (or methacrylate) having a C₆F₁₃ group with a (poly(oxyalkylene)) acrylate (or methacrylate); and a copolymer of an acrylate (or methacrylate) having a C₃F₇ group with a (poly(oxyethylene)) acrylate (or methacrylate) and a (poly(oxypropylene)) acrylate (or methacrylate).

In addition, in the present invention, a surfactant other than the fluorine- and/or silicon-based surfactants described in “0280” of US2008/0248425A can also be used.

These surfactants may be used alone or in combination of a few surfactants.

In the case where the composition of the present invention contains the surfactant, the amount of the surfactant used is preferably from 0.0001% by mass to 2% by mass, and more preferably from 0.0005% by mass to 1% by mass, with respect to the total amount of the composition (excluding the solvent).

On the other hand, by setting the amount of the surfactant added to 10 ppm or less with respect to the total amount (excluding the solvent) of the actinic ray-sensitive or radiation-sensitive resin composition, the hydrophobic resin is more unevenly distributed to the surface, so that the surfactant of the resist film can be made more hydrophobic, which can enhance the followability of water during the liquid immersion exposure.

[7] Other Additives (G)

The composition of the present invention may contain an onium carboxylate salt. Examples of such an onium carboxylate salt include ones described in “0605” to “0606” of US2008/0187860A.

In the case where the composition of the present invention contains an onium carboxylate salt, the content of the salt is generally from 0.1% by mass to 20% by mass, preferably from 0.5 to 10% by mass, and still more preferably from 1% by mass to 7% by mass, with respect to the total solid content of the composition.

Furthermore, the composition of the present invention may contain a so-called acid-increasing agent, if desired. It is preferable that the acid-increasing agent is used, particularly when the pattern forming method of the present invention is carried out by EUV exposure or irradiation with electron beams. Specific examples of the acid-increasing agent are not particularly limited, and examples thereof are shown below.

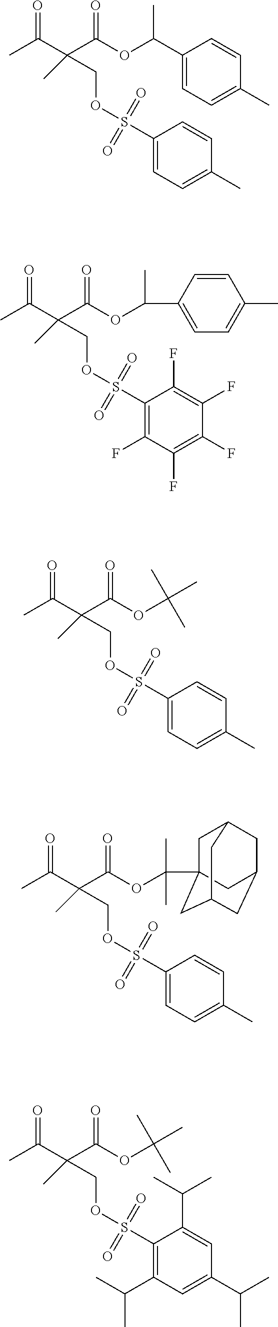

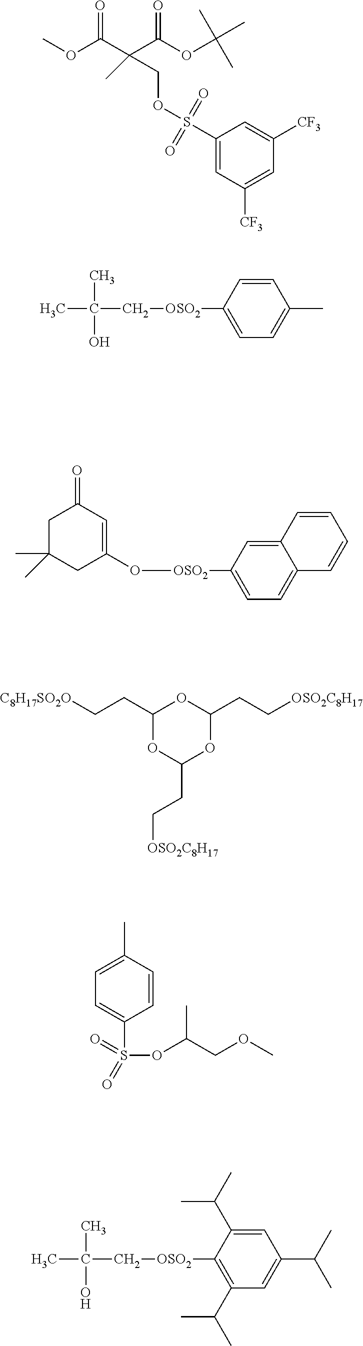

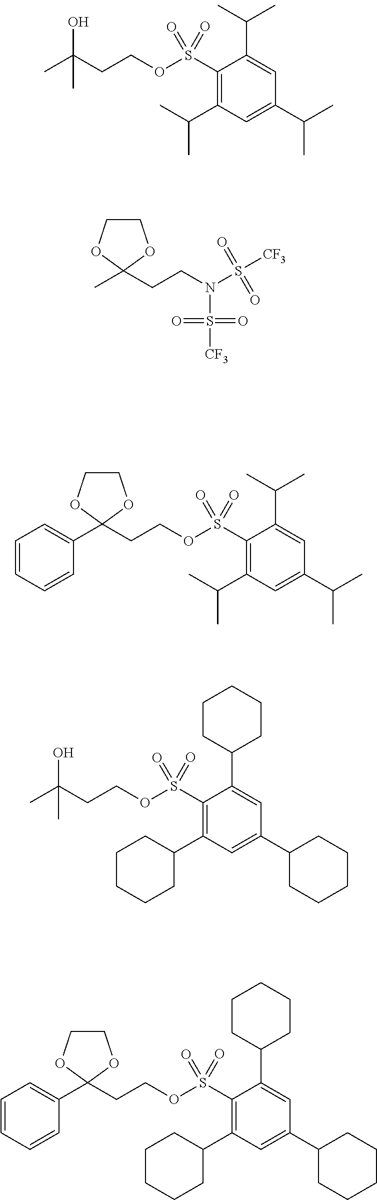

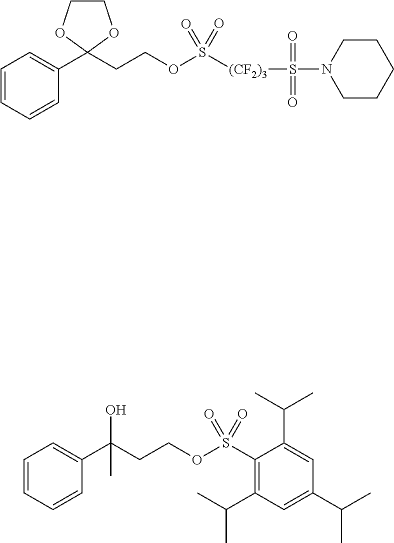

The composition of the present invention can contain a dye, a plasticizer, a photosensitizer, a light absorber, an alkali-soluble resin, a dissolution inhibitor, a compound for accelerating dissolution in a developing liquid (for example, a phenol compound having a molecular weight of 1000 or less, or a carboxyl group-containing alicyclic or aliphatic compound), or the like, if desired.

From the viewpoint of enhancing the resolving power, the composition of the present invention is preferably used in a film thickness of 30 nm to 250 nm, and more preferably from 30 nm to 200 nm.

The solid content concentration of the composition of the present invention is usually from 1.0% by mass to 10% by mass, preferably from 2.0% by mass to 5.7% by mass, and more preferably from 2.0% by mass to 5.3% by mass. By setting the solid content concentration to the above range, the resist solution can be uniformly coated on a substrate.

The solid content concentration is a weight percentage of the weight of the other resist components excluding the solvent, with respect to the total weight of the chemical amplification resist composition.

The composition of the present invention is used by dissolving the components in a predetermined organic solvent, and preferably the mixed solvent, filtered through a filter, and then applied onto a predetermined support (substrate). A filter used in the filtration through the filter is preferably a polytetrafluoroethylene-, polyethylene-, or nylon-made filter having a pore size of 0.1 μm or less, more preferably 0.05 μm or less, and still more preferably 0.03 μm or less. In the filtration through a filter, cyclic filtration is carried out as in, for example, JP2002-62667A, or filtration may be carried out by connecting multiple types of filters in series or in parallel. Further, the composition may be carried out multiple times. In addition, before and after the filtration through the filter, the composition may be subjected to a deaeration treatment or the like.

### EXAMPLES

Hereinafter, the present invention will be described with reference to Examples, but the contents of the present invention are not limited thereto.

<Preparation 1 of Resist>

The components shown in the following table were dissolved in the solvents shown in the same table to yield a solid content of 3.5% by mass, followed by filtering through a polyethylene filter having a pore size of 0.03 μm, to prepare an actinic ray-sensitive or radiation-sensitive resin composition (resist composition).

TABLE 4

| | | | | | | | Basic |
|---|---|---|---|---|---|---|---|
| | | | | | | | compound |
| | | | | | Basic | | used in |
| Resist | Resin (A) | Mass/g | PAG | Mass/g | compound | Mass/g | combination |
| Ar-01 | Pol-01 | 10 | PAG-1/PAG-2 | 0.3/0.2 | N-1 | 0.02 | N-5 |
| Ar-02 | Pol-02 | 10 | PAG-8/PAG-9 | 0.3/0.2 | N-2 | 0.02 | N-6 |
| Ar-03 | Pol-03 | 10 | PAG-11/PAG-12 | 0.3/0.2 | N-2 | 0.03 | — |
| Ar-04 | Pol-04 | 10 | PAG-5/PAG-6 | 0.3/0.2 | N-1 | 0.02 | N-8 |
| Ar-05 | Pol-05 | 10 | PAG-10/PAG-9 | 0.3/0.2 | N-9 | 0.03 | — |
| Ar-06 | Pol-06 | 10 | PAG-12 | 0.5 | N-3 | 0.03 | — |
| Ar-07 | Pol-01/Pol-07 | 8/2 | PAG-2 | 0.5 | N-3 | 0.02 | N-7 |
| Ar-08 | Pol-07 | 10 | PAG-7/PAG-2 | 0.3/0.2 | N-4 | 0.02 | N-5 |
| Ar-09 | Pol-08 | 10 | PAG-8/PAG-4 | 0.3/0.2 | N-1 | 0.03 | — |
| Ar-10 | Pol-09/Pol-08 | 8/2 | PAG-13/PAG-12 | 0.3/0.2 | N-3 | 0.02 | N-6 |
| Ar-11 | Pol-10 | 10 | PAG-15/PAG-3 | 0.3/0.2 | N-8 | 0.03 | — |
| Ar-12 | Pol-11 | 10 | PAG-7/PAG-9 | 0.3/0.2 | N-2 | 0.03 | — |
| Ar-13 | Pol-12 | 10 | PAG-5/PAG-12 | 0.3/0.2 | N-2 | 0.02 | N-6 |
| Ar-14 | Pol-13 | 10 | PAG-8/PAG-9 | 0.3/0.2 | N-1 | 0.02 | N-7 |
| Ar-15 | Pol-14 | 10 | PAG-12 | 0.5 | N-3 | 0.03 | — |
| Ar-16 | Pol-15 | 10 | PAG-10/PAG-9 | 0.3/0.2 | N-1 | 0.02 | N-9 |
| Ar-17 | Pol-16 | 10 | PAG-6 | 0.5 | N-4 | 0.02 | N-7 |
| Ar-18 | Pol-17 | 10 | PAG-7/PAG-2 | 0.3/0.2 | N-4 | 0.03 | — |
| Ar-19 | Pol-18 | 10 | PAG-11/PAG-4 | 0.3/0.2 | N-2 | 0.02 | N-8 |
| Ar-20 | Pol-19 | 10 | PAG-6 | 0.5 | N-3 | 0.02 | N-7 |
| Ar-21 | Pol-20 | 10 | PAG-16/PAG-9 | 0.3/0.2 | N-4 | 0.03 | — |
| Ar-22 | Pol-01 | 10 | PAG-1 | 0.5 | N-1 | 0.02 | N-6 |
| Ar-23 | Pol-02 | 10 | PAG-8 | 0.5 | N-6 | 0.03 | — |
| Ar-24 | Pol-03 | 10 | PAG-11 | 0.5 | N-3 | 0.03 | — |
| Ar-25 | Pol-07 | 10 | PAG-5 | 0.5 | N-2 | 0.02 | N-9 |
| Ar-26 | Pol-08 | 10 | PAG-10 | 0.5 | N-1 | 0.02 | N-8 |
| Ar-27 | Pol-09 | 10 | PAG-13 | 0.5 | N-4 | 0.03 | — |
| Ar-28 | Pol-10 | 10 | PAG-10 | 0.5 | N-2 | 0.02 | N-9 |
| Ar-29 | Pol-11 | 10 | PAG-7 | 0.5 | N-7 | 0.03 | — |
| Ar-30 | Pol-12 | 10 | PAG-10 | 0.5 | N-3 | 0.03 | — |
| Ar-31 | Pol-03 | 10 | PAG-14 | 0.5 | N-3 | 0.03 | — |
| Ar-32 | Pol-21 | 10 | PAG-11/PAG-12 | 0.3/0.2 | N-1 | 0.03 | — |

| | | | | Hydrophobic | | | Mass |
|---|---|---|---|---|---|---|---|
| Resist | Mass/g | Surfactant | Mass/g | resin | Mass/g | Solvent | ratio |
| Ar-01 | 0.01 | W-1 | 0.03 | 1b | 0.05 | SL-1/SL-4 | 80/20 |
| Ar-02 | 0.01 | — | — | 4b | 0.05 | SL-1/SL-4 | 70/30 |
| Ar-03 | — | W-2 | 0.03 | 2b | 0.05 | SL-1/SL-5 | 98/2 |
| Ar-04 | 0.01 | W-3 | 0.03 | 3b | 0.05 | SL-1/SL-2 | 80/20 |
| Ar-05 | — | — | — | 1b | 0.05 | SL-1 | 100 |
| Ar-06 | — | W-1 | 0.03 | 4b | 0.05 | SL-1/SL-3 | 70/30 |
| Ar-07 | 0.01 | — | — | 4b | 0.05 | SL-1/SL-2 | 80/20 |
| Ar-08 | 0.01 | W-4 | 0.03 | 3b | 0.05 | SL-1/SL-4 | 95/5 |
| Ar-09 | — | — | — | 2b | 0.05 | SL-1/SL-3 | 80/20 |
| Ar-10 | 0.01 | W-1 | 0.03 | 1b | 0.05 | SL-1/SL-2 | 90/10 |
| Ar-11 | — | — | — | 1b | 0.05 | SL-1/SL-3 | 65/35 |
| Ar-12 | — | W-1 | 0.03 | 2b | 0.05 | SL-1/SL-4 | 70/30 |
| Ar-13 | 0.01 | — | — | 4b | 0.05 | SL-1/SL-3 | 70/30 |
| Ar-14 | 0.01 | W-6 | 0.03 | 4b | 0.05 | SL-1/SL-4 | 65/35 |
| Ar-15 | — | W-5 | 0.03 | 2b | 0.05 | SL-1/SL-4 | 55/45 |
| Ar-16 | 0.01 | — | — | 1b | 0.05 | SL-1/SL-4 | 90/10 |
| Ar-17 | 0.01 | — | — | 3b | 0.05 | SL-1 | 100 |
| Ar-18 | — | — | — | 4b | 0.05 | SL-1/SL-4 | 80/20 |
| Ar-19 | 0.01 | W-4 | 0.03 | 1b | 0.05 | SL-1/SL-3 | 65/35 |
| Ar-20 | 0.01 | — | — | 1b | 0.05 | SL-1 | 100 |
| Ar-21 | — | — | — | 4b | 0.05 | SL-1/SL-4 | 95/5 |
| Ar-22 | 0.01 | — | — | 3b | 0.05 | SL-1/SL-4 | 85/15 |
| Ar-23 | — | W-6 | 0.03 | 2b | 0.05 | SL-1/SL-4 | 80/20 |
| Ar-24 | — | — | — | 4b | 0.05 | SL-1/SL-5 | 95/5 |
| Ar-25 | 0.01 | W-1 | 0.03 | 4b | 0.05 | SL-1/SL-3 | 70/30 |
| Ar-26 | 0.01 | W-1 | 0.03 | 4b | 0.05 | SL-1/SL-4 | 70/30 |
| Ar-27 | — | — | — | 2b | 0.05 | SL-1/SL-4 | 95/5 |
| Ar-28 | 0.01 | W-3 | 0.03 | 1b | 0.05 | SL-1/SL-4 | 90/10 |
| Ar-29 | — | — | — | 1b | 0.05 | SL-1/SL-4 | 95/5 |
| Ar-30 | — | — | — | 1b | 0.05 | SL-1/SL-4 | 95/5 |
| Ar-31 | — | W-1 | 0.03 | 1b | 0.05 | SL-1/SL-3 | 70/30 |
| Ar-32 | — | — | — | 2b | 0.05 | SL-1/SL-4 | 95/5 |

<Resin (A)>

Pol-01 to Pol-21 shown below were used as the resin (A). Further, these resins were synthesized by a known radical polymerization method and purified. Further, the weight-average molecular weight (Mw: in terms of polystyrene), the number-average molecular weight (Mn: in terms of polystyrene), and the dispersity (Mw/Mn, hereinafter referred to as “Pd”) of these resins were calculated by means of GPC (solvent: THF) measurement. Further, the compositional ratio (molar ratio) was calculated by means of ¹H-NMR measurement.

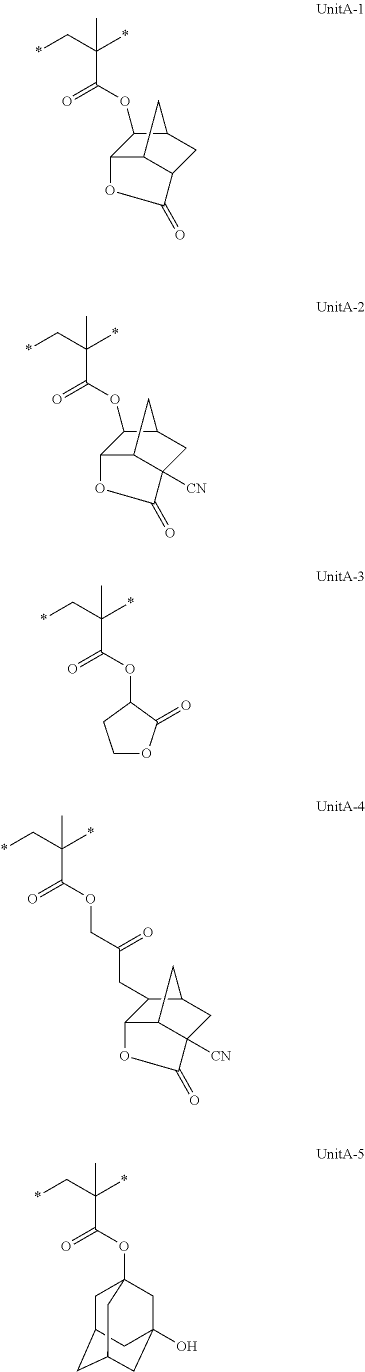 [SMILES: *CC(*)(C)C(=O)OC1C2CC3C(=O)OC1C3C2 ; *CC(*)(C)C(=O)OC1C2CC3C1OC(=O)C3(C#N)C2 ; *CC(*)(C)C(=O)OC1CCOC1=O ; *CC(*)(C)C(=O)OCC(=O)CC1C2CC3C1OC(=O)C3(C#N)C2 ; *CC(*)(C)C(=O)OC12CC3CC(CC(O)(C3)C1)C2]

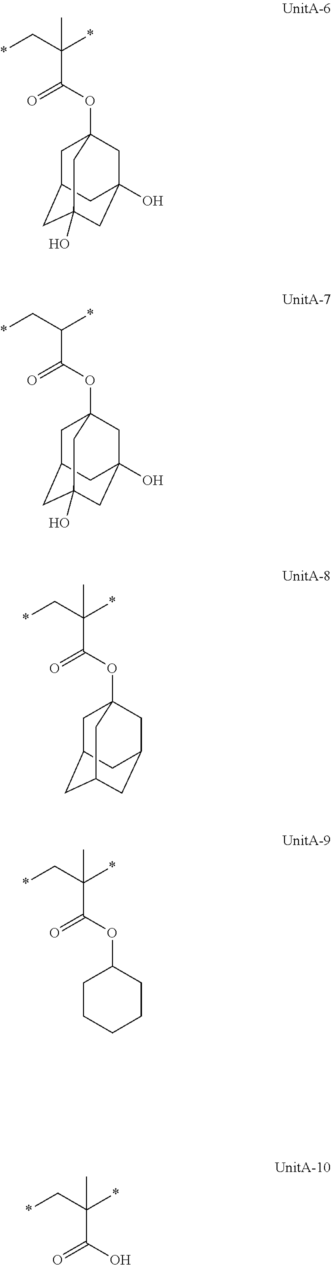

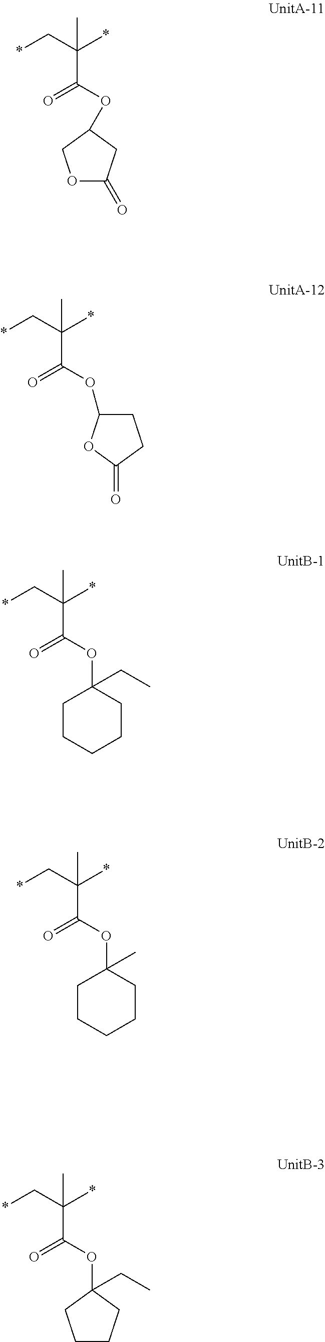 [SMILES: *CC(*)(C)C(=O)OC1COC(=O)C1 ; *CC(*)(C)C(=O)OC1CCC(=O)O1 ; *CC(*)(C)C(=O)OC1(CC)CCCCC1 ; *CC(*)(C)C(=O)OC1(C)CCCCC1 ; *CC(*)(C)C(=O)OC1(CC)CCCC1]

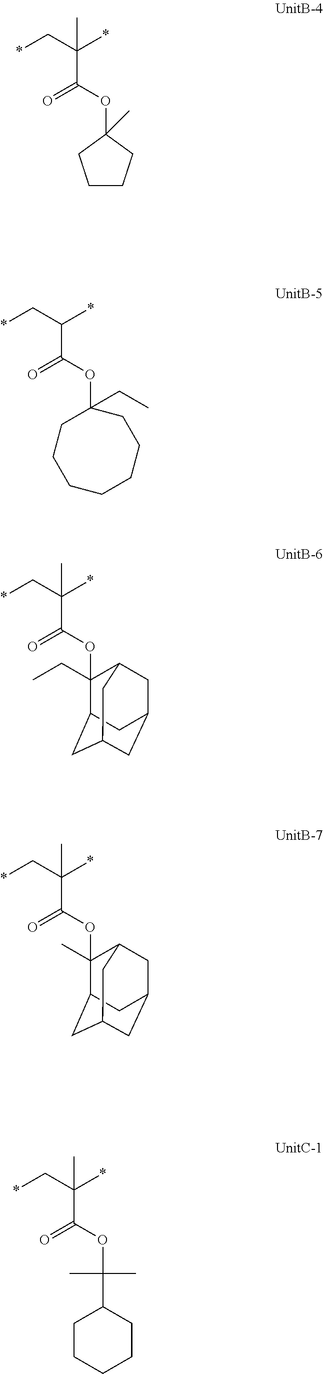 [SMILES: *CC(*)(C)C(=O)OC1(C)CCCC1 ; *CC(*)C(=O)OC1(CC)CCCCCCC1 ; *CC(*)(C)C(=O)OC1(CC)C2CC3CC(C2)CC1C3 ; *CC(*)(C)C(=O)OC1(C)C2CC3CC(C2)CC1C3 ; *CC(*)(C)C(=O)OC(C)(C)C1CCCCC1]

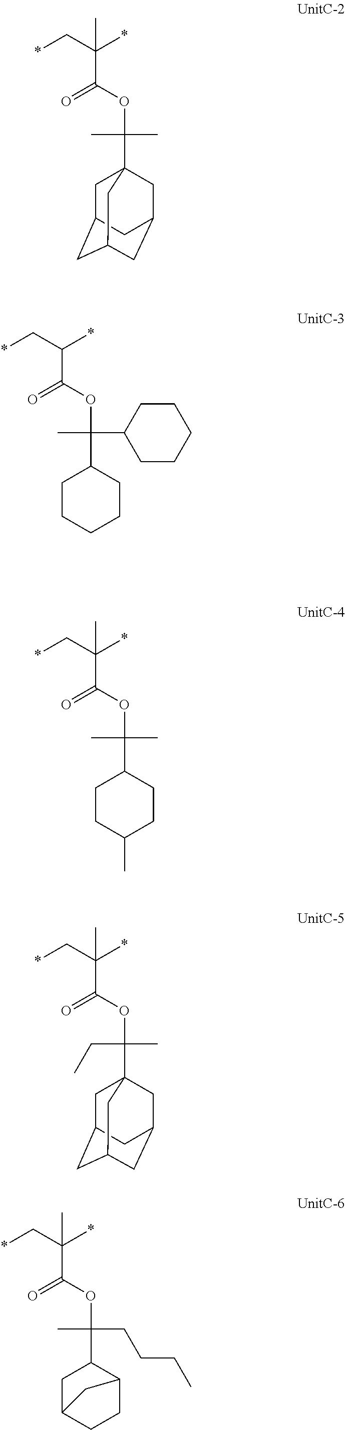

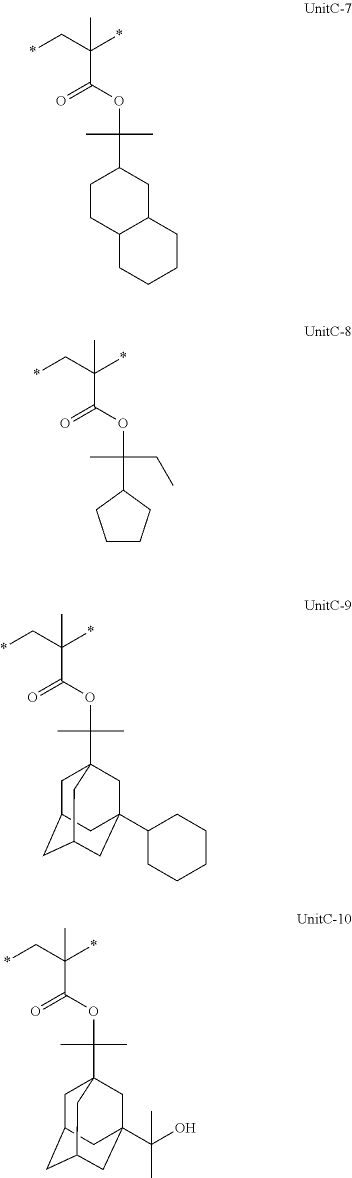 [SMILES: *CC(*)(C)C(=O)OC(C)(C)C1CCC2CCCCC2C1 ; *CC(*)(C)C(=O)OC(C)(CC)C1CCCC1 ; *CC(*)(C)C(=O)OC(C)(C)C12CC3CC(CC(C4CCCCC4)(C3)C1)C2 ; *CC(*)(C)C(=O)OC(C)(C)C12CC3CC(CC(C(C)(C)O)(C3)C1)C2]

TABLE 5

| Resin | Unit-1 | | Unit-2 | | Unit-3 | | Unit-4 | | Unit-5 | | Mw | Pd |
|---|---|---|---|---|---|---|---|---|---|---|---|---|
| Pol-01 | UnitA-1 | 30 | UnitB-3 | 40 | UnitC-1 | 25 | UnitA-9 | 5 | | | 11200 | 1.6 |
| Pol-02 | UnitA-11 | 40 | UnitB-1 | 50 | UnitC-2 | 10 | | | | | 9600 | 1.7 |
| Pol-03 | UnitA-2 | 45 | UnitB-2 | 40 | UnitC-3 | 5 | UnitA-7 | 5 | UnitA-10 | 5 | 9800 | 1.6 |
| Pol-04 | UnitA-3 | 40 | UnitC-4 | 50 | UnitA-5 | 10 | | | | | 10500 | 2.0 |
| Pol-05 | UnitA-5 | 40 | UnitC-5 | 60 | | | | | | | 20300 | 1.5 |
| Pol-06 | UnitA-1 | 40 | UnitC-6 | 55 | UnitA-6 | 5 | | | | | 15300 | 1.7 |
| Pol-07 | UnitA-2 | 40 | UnitB-4 | 20 | UnitC-7 | 35 | UnitA-8 | 5 | | | 9400 | 1.6 |
| Pol-08 | UnitA-3 | 35 | UnitB-5 | 25 | UnitC-8 | 35 | UnitA-4 | 5 | | | 13200 | 1.6 |
| Pol-09 | UnitA-2 | 30 | UnitB-6 | 35 | UnitC-9 | 35 | | | | | 11400 | 1.6 |
| Pol-10 | UnitA-12 | 30 | UnitC-10 | 65 | UnitA-4 | 5 | | | | | 13200 | 1.5 |
| Pol-11 | UnitA-5 | 35 | UnitC-4 | 65 | | | | | | | 16900 | 1.7 |
| Pol-12 | UnitA-2 | 25 | UnitC-3 | 65 | UnitA-10 | 10 | | | | | 14400 | 1.6 |
| Pol-13 | UnitA-3 | 50 | UnitB-7 | 10 | UnitC-9 | 40 | | | | | 8400 | 1.6 |
| Pol-14 | UnitA-4 | 20 | UnitB-6 | 40 | UnitC-10 | 40 | | | | | 10900 | 1.6 |
| Pol-15 | UnitA-2 | 35 | UnitB-5 | 25 | UnitC-6 | 40 | | | | | 11000 | 1.6 |
| Pol-16 | UnitA-2 | 30 | UnitC-3 | 70 | | | | | | | 15200 | 1.6 |
| Pol-17 | UnitA-1 | 20 | UnitC-8 | 70 | UnitA-8 | 10 | | | | | 13100 | 1.5 |
| Pol-18 | UnitA-6 | 20 | UnitC-9 | 70 | UnitA-9 | 10 | | | | | 9900 | 2.2 |
| Pol-19 | UnitA-2 | 45 | UnitB-7 | 10 | UnitC-7 | 45 | | | | | 10400 | 1.9 |
| Pol-20 | UnitA-7 | 20 | UnitC-6 | 80 | | | | | | | 11200 | 1.6 |
| Pol-21 | UnitA-1 | 40 | UnitB-3 | 50 | UnitB-6 | 10 | | | | | 10600 | 1.5 |

<Acid Generator (B)>

PAG-1 to PAG-16 shown below were used as the acid generator (B).

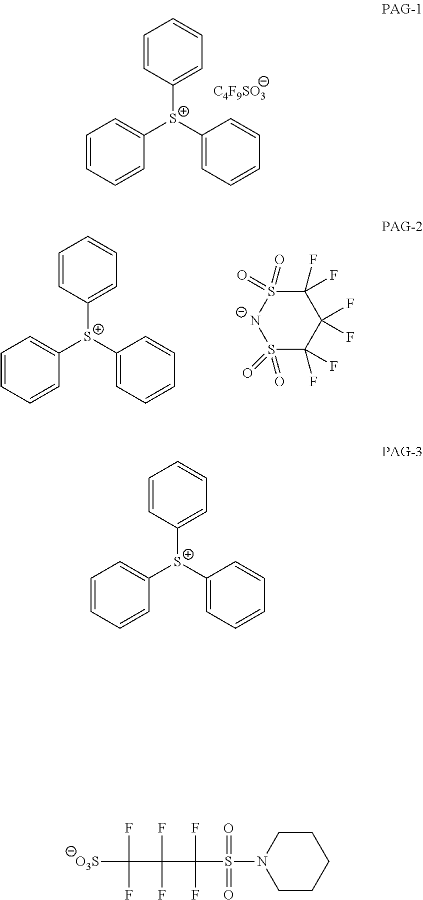

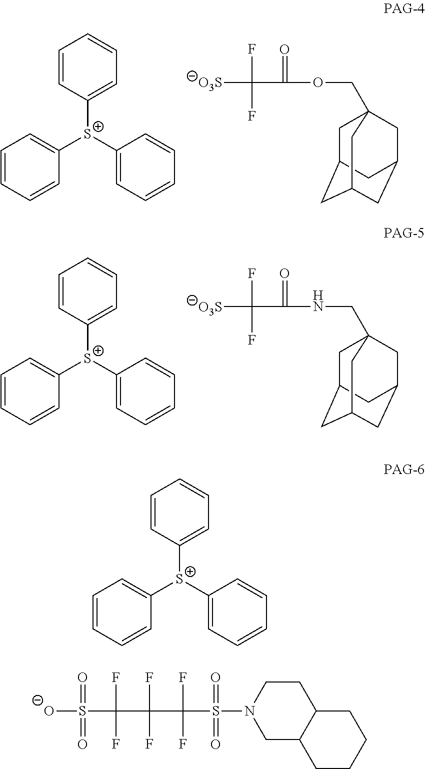

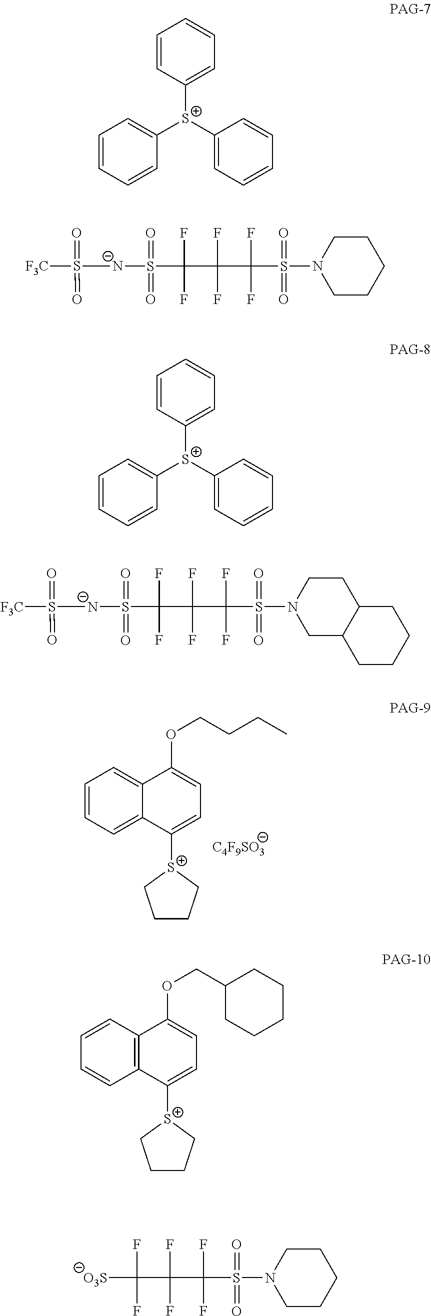

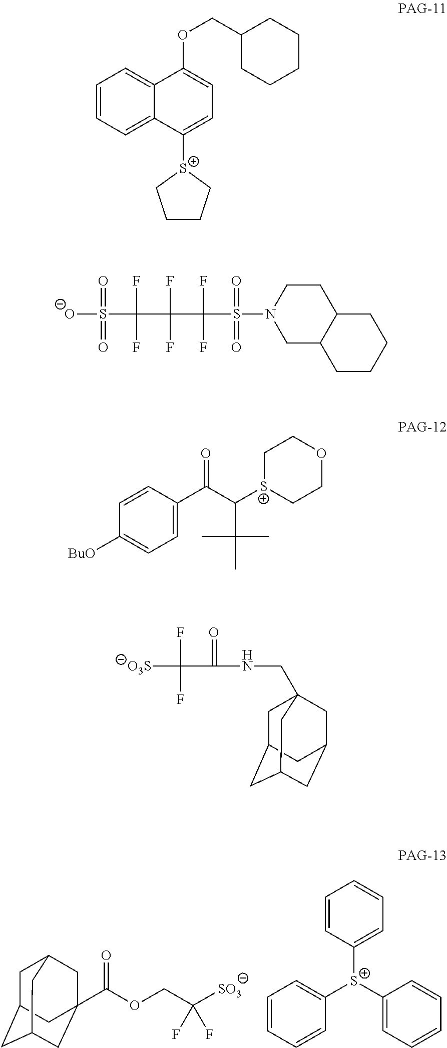

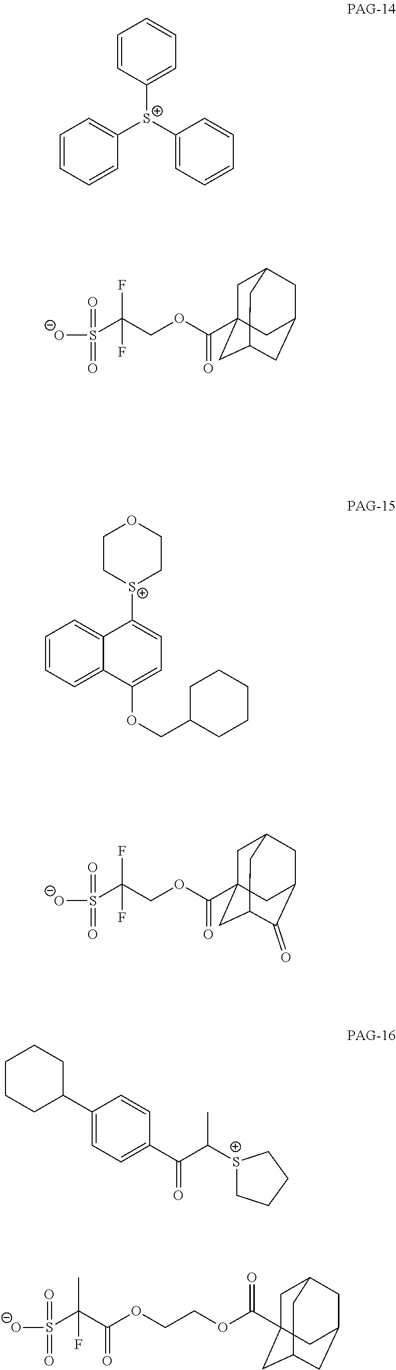 [SMILES: c1ccc([S+](c2ccccc2)c2ccccc2)cc1 ; O=C(OCC(F)(F)S(=O)(=O)[O-])C12CC3CC(CC(C3)C1)C2 ; c1ccc2c([S+]3CCOCC3)ccc(OCC3CCCCC3)c2c1 ; O=C1C2CC3CC1CC(C(=O)OCC(F)(F)S(=O)(=O)[O-])(C3)C2 ; CC(C(=O)c1ccc(C2CCCCC2)cc1)[S+]1CCCC1 ; CC(F)(C(=O)OCCOC(=O)C12CC3CC(CC(C3)C1)C2)S(=O)(=O)[O-]]

<Hydrophobic Resin>

1b to 4b shown below were used as the hydrophobic resin.

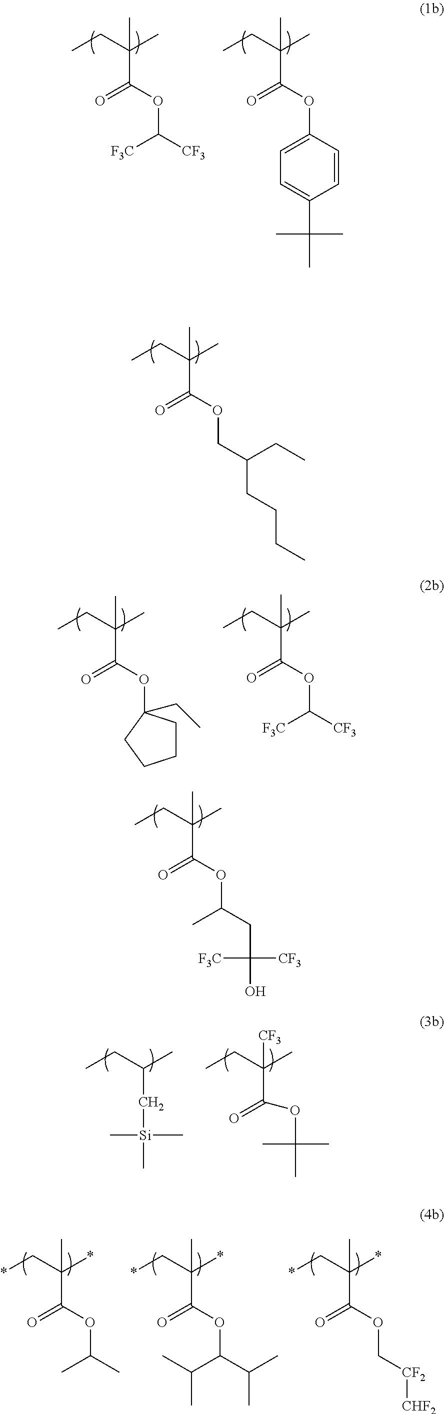

<Basic Compound>

The compounds N-1 to N-9 shown below were used as the basic compound.

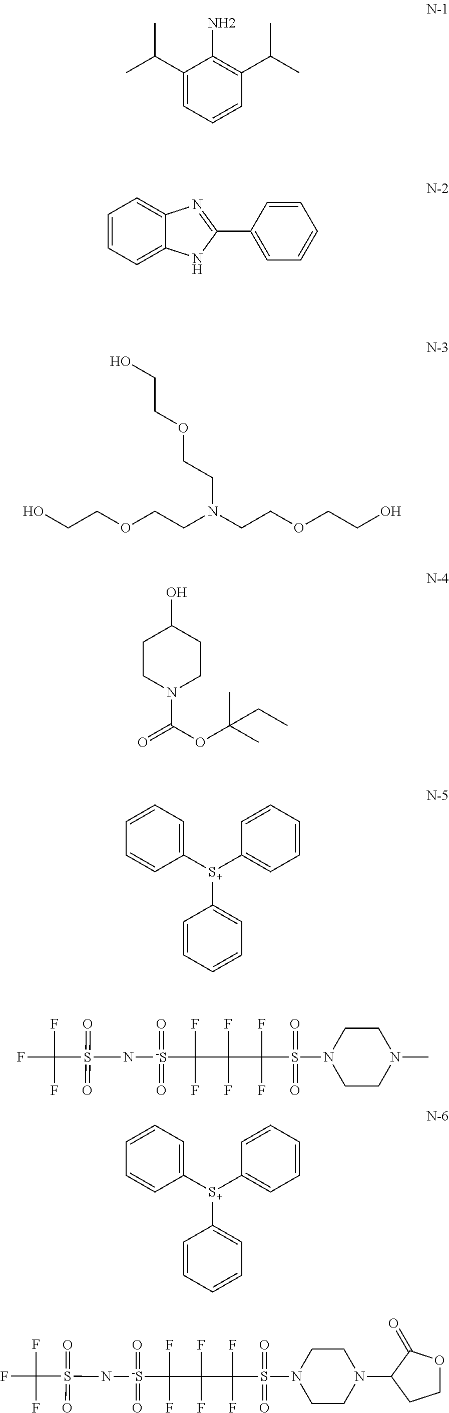

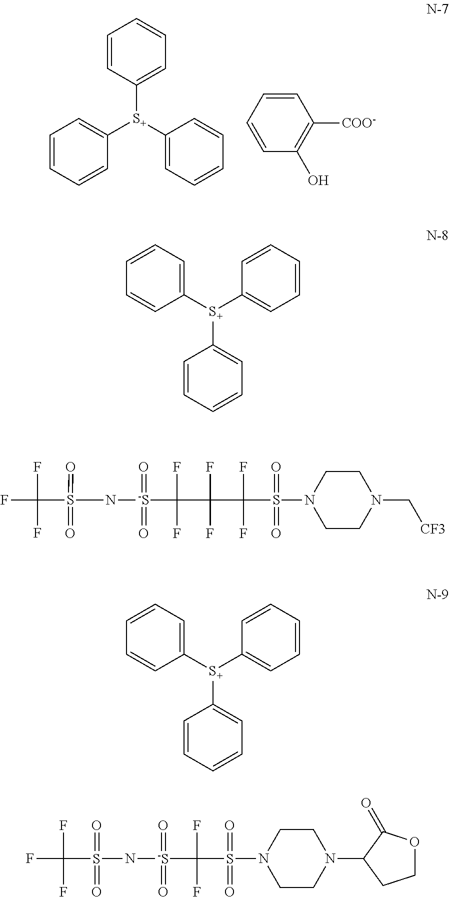

<Surfactant>

W-1 to W-6 shown below were used as the surfactant.

W-1: Megaface F176 (manufactured by DIC Corp.; fluorine-based)

W-2: Megaface R08 (manufactured by DIC Corp.; fluorine- and silicon-based)

W-3: Polysiloxane Polymer KP-341 (manufactured by Shin-Etsu Chemical Co., Ltd.; silicon-based)

W-4: Troysol S-366 (manufactured by Troy Chemical Corp.)

W-5: KH-20 (manufactured by Asahi Glass Co., Ltd.)

W-6: PolyFox PF-6320 (manufactured by OMNOVA Solutions Inc.; fluorine-based)

<Solvent>

SG-1 to SG-5 shown below were used as the solvent.

SL-1: Propylene glycol monomethyl ether acetate (PGMEA)

SL-2: Ethyl lactate

SL-3: Propylene glycol monomethyl ether (PGME)

SL-4: Cyclohexanone

SL-5: γ-Butyrolactone

<Pattern Formation>

A silicon wafer with a 300-mm aperture (12-inch aperture) was subjected to a hexamethyldisilazane (HMDS) treatment, and baked at 115° C. for 60 seconds.

Then, an antireflection film was formed, or an SOC film and an antireflection film were sequentially formed (Table 6). Each of an antireflection film ARC29SR (95 nm/manufactured by Nissan Chemical Industries, Ltd.), a silicon-containing antireflection film HM825 (30 nm/manufactured by Brewer Science, Inc.), and an SOC film 110D (100 nm/manufactured by Brewer Science, Inc.) was applied onto a substrate, and then baked at 205° C. for 60 seconds to form a film.

2 ml of the solvent described in Table 6 as the solvent (S) was applied onto the film in the state where the wafer was held thereon, and the wafer was rotated at the rotating speed described in Table 6 for 1.5 seconds. A resist composition was applied thereonto and baked (Pre Bake; PB) to form a resist film having a film thickness of 90 nm. Further, the time taken from the completion of ejection of the solvent (S) to the initiation of ejection of the resist liquid was arbitrarily controlled (Table 6).

Then, the film was exposed through a 6% half-tone mask having a line-and-space pattern with a pitch of 100 nm and an opening of 50 nm, using an ArF excimer laser liquid immersion scanner (manufactured by ASML, XT1700i, NA1.20, Annular, outer sigma 0.940, inner sigma 0.740, XY deflection). Ultrapure water was used as the immersion liquid. Thereafter, the film was post-baked (Post Exposure Bake; PEB) and developed with the developing liquid described in Table 6 for 30 seconds, and in the case of carrying out rinsing, rinsed with the rinsing liquid described in Table 6. Then, the wafer was rotated at a rotational speed of 4000 rpm for 30 seconds to obtain a 50 nm (1:1) line-and-space resist pattern.

<Evaluation Method>

Evaluation of Scum

With respect to the sensitivity obtained above, the bottom portion between the resist patterns was observed by a scanning type electron microscope (S-4800 manufactured by Hitachi, Ltd.), and evaluated in the following 5 stages.

A: A case where there is no scum and the substrate surface is clean

B: A case where scum is slightly seen and the resist film slightly remaining on the substrate is occasionally seen

C: A case where scum can be clearly identified and the resist film remaining on the substrate is occasionally seen

D: A case where there is much scum and the thick resist film remaining on the substrate is occasionally seen

E: A case where connection by the residues is found in the bottom portion between the patterns due to scum

Evaluation of CDU (Line Width Uniformity)

The repeating patterns obtained above were measured for the line width with respect to 55 shots in total in the wafer plane by 59380 (manufactured by Hitachi Ltd.) (threshold=50), and the line width uniformity in the wafer plane was evaluated. The evaluation results are shown by the standard deviation (nm, 3σ) from the average value obtained. A smaller value indicates higher performance.

TABLE 6

| | | | | | | | Time taken from |
|---|---|---|---|---|---|---|---|
| | | | | | | | completion of |
| | | | | | | | ejection of |
| | | | | | | | solvent (S) to |
| | | | | Solvent (S) | | | initiation of |
| | | | | | Vapor | Rotational | ejection of resist |
| Example | Resist | Antireflection film | SOC | Type of solvent | pressure | speed | liquid |
| 1 | Ar-01 | ARC29SR | — | MMP | 0.2 kPa | 500 rpm | 2.0 sec |
| 2 | Ar-02 | ARC29SR | — | MAK | 0.3 kPa | 500 rpm | 2.0 sec |
| 3 | Ar-03 | ARC29SR | — | EL | 0.4 kPa | 500 rpm | 2.0 sec |
| 4 | Ar-04 | ARC29SR | — | PGMEA | 0.4 kPa | 500 rpm | 2.0 sec |
| 5 | Ar-05 | ARC29SR | — | Cyclohexanone | 0.5 kPa | 500 rpm | 2.0 sec |
| 6 | Ar-06 | ARC29SR | — | n-Pentyl acetate | 0.7 kPa | 500 rpm | 2.0 sec |
| 7 | Ar-07 | ARC29SR | — | Ethylene glycol | 0.7 kPa | 500 rpm | 2.0 sec |
| 8 | Ar-08 | ARC29SR | — | Isopentyl | 0.8 kPa | 500 rpm | 2.0 sec |
| | | | | acetate | | | |
| 9 | Ar-09 | ARC29SR | — | Butyl acetate | 1.2 kPa | 500 rpm | 2.0 sec |
| 10 | Ar-10 | ARC29SR | — | PGME | 1.2 kPa | 500 rpm | 2.0 sec |
| 11 | Ar-11 | ARC29SR | — | Cyclohexanone | 0.5 kPa | 1500 rpm | 2.0 sec |
| 12 | Ar-12 | ARC29SR | — | Cyclohexanone | 0.5 kPa | 3000 rpm | 2.0 sec |
| 13 | Ar-13 | ARC29SR | — | Cyclohexanone | 0.5 kPa | 500 rpm | 4.0 sec |
| 14 | Ar-14 | ARC29SR | — | Cyclohexanone | 0.5 kPa | 500 rpm | 7.0 sec |
| 15 | Ar-15 | ARC29SR | — | Cyclohexanone | 0.5 kPa | 500 rpm | 2.0 sec |
| 16 | Ar-16 | ARC29SR | — | Cyclohexanone | 0.5 kPa | 500 rpm | 2.0 sec |
| 17 | Ar-17 | ARC29SR | — | Cyclohexanone | 0.5 kPa | 500 rpm | 2.0 sec |
| 18 | Ar-18 | ARC29SR | — | Cyclohexanone | 0.5 kPa | 500 rpm | 2.0 sec |
| 19 | Ar-19 | ARC29SR | — | Cyclohexanone | 0.5 kPa | 500 rpm | 2.0 sec |
| 20 | Ar-20 | ARC29SR | — | Cyclohexanone | 0.5 kPa | 500 rpm | 2.0 sec |
| 21 | Ar-21 | ARC29SR | — | Cyclohexanone | 0.5 kPa | 500 rpm | 2.0 sec |
| 22 | Ar-22 | ARC29SR | — | Cyclohexanone | 0.5 kPa | 500 rpm | 2.0 sec |
| 23 | Ar-23 | ARC29SR | — | Cyclohexanone | 0.5 kPa | 500 rpm | 2.0 sec |
| 24 | Ar-24 | ARC29SR | — | Cyclohexanone | 0.5 kPa | 500 rpm | 2.0 sec |
| 25 | Ar-25 | ARC29SR | — | Cyclohexanone | 0.5 kPa | 500 rpm | 2.0 sec |
| 26 | Ar-26 | ARC29SR | — | Cyclohexanone | 0.5 kPa | 500 rpm | 2.0 sec |
| 27 | Ar-27 | ARC29SR | — | Cyclohexanone | 0.5 kPa | 500 rpm | 2.0 sec |
| 28 | Ar-28 | ARC29SR | — | Cyclohexanone | 0.5 kPa | 500 rpm | 2.0 sec |
| 29 | Ar-29 | ARC29SR | — | Cyclohexanone | 0.5 kPa | 500 rpm | 2.0 sec |
| 30 | Ar-30 | ARC29SR | — | Cyclohexanone | 0.5 kPa | 500 rpm | 2.0 sec |
| 31 | Ar-31 | ARC29SR | — | Cyclohexanone | 0.5 kPa | 500 rpm | 2.0 sec |
| 32 | Ar-32 | ARC29SR | — | Cyclohexanone | 0.5 kPa | 500 rpm | 2.0 sec |
| 33 | Ar-05 | HM825 | 110D | Cyclohexanone | 0.5 kPa | 500 rpm | 2.0 sec |
| Comparative | Ar-19 | ARC29SR | — | — | — | — | — |
| Example 1 | | | | | | | |

| | | | | | Evaluation | |
|---|---|---|---|---|---|---|
| | | | Developing | | results | |
| Example | PB | PEB | liquid | Rinsing liquid | CDU | Scum |
| 1 | 90° C./60 s | 95° C./60 s | Butyl | — | 4.2 | A |
| | | | acetate | | | |
| 2 | 100° C./60 s | 100° C./60 s | Butyl | — | 4.2 | A |
| | | | acetate | | | |
| 3 | 90° C./50 s | 100° C./60 s | Butyl | 1-Hexanol | 4.2 | A |
| | | | acetate | | | |
| 4 | 95° C./60 s | 95° C./50 s | Isopentyl | — | 4.9 | B |
| | | | acetate | | | |
| 5 | 90° C./60 s | 95° C./60 s | Pentyl | 4-Methyl-2-pentanol | 4.9 | B |
| | | | acetate | | | |
| 6 | 90° C./60 s | 95° C./60 s | Butyl | — | 5.6 | B |
| | | | acetate | | | |
| 7 | 100° C./60 s | 95° C./60 s | 2-Heptanone | 1-Hexanol | 5.6 | B |
| 8 | 105° C./60 s | 100° C./60 s | Isopentyl | — | 6.3 | C |
| | | | acetate | | | |
| 9 | 90° C./60 s | 105° C./60 s | Butyl | 1-Octanol | 7.0 | C |
| | | | acetate | | | |
| 10 | 90° C./50 s | 100° C./60 s | Butyl | — | 7.0 | C |
| | | | acetate | | | |
| 11 | 105° C./60 s | 100° C./60 s | Isopentyl | — | 6.3 | C |
| | | | acetate | | | |
| 12 | 90° C./60 s | 95° C./60 s | Butyl | — | 7.7 | D |
| | | | acetate | | | |
| 13 | 90° C./50 s | 90° C./60 s | Isopentyl | 4-Methyl-2-pentanol | 5.6 | B |
| | | | acetate | | | |
| 14 | 90° C./60 s | 95° C./60 s | Butyl | — | 7.0 | D |
| | | | acetate | | | |
| 15 | 90° C./50 s | 95° C./60 s | Butyl | 4-Methyl-2-pentanol | 4.9 | B |
| | | | acetate | | | |
| 16 | 100° C./60 s | 100° C./60 s | Butyl | — | 4.9 | B |
| | | | acetate | | | |
| 17 | 95° C./60 s | 95° C./60 s | Butyl | 4-Methyl-2-pentanol | 4.9 | B |
| | | | acetate | | | |
| 18 | 100° C./60 s | 95° C./60 s | Butyl | — | 4.9 | B |
| | | | acetate | | | |
| 19 | 95° C./60 s | 95° C./60 s | 2-Heptanone | 1-Hexanol | 4.9 | B |
| | | | acetate | | | |
| 20 | 100° C./60 s | 100° C./60 s | Butyl | — | 4.9 | B |
| | | | acetate | | | |
| 21 | 90° C./60 s | 95° C./60 s | Butyl | — | 4.9 | B |
| | | | acetate | | | |
| 22 | 100° C./60 s | 100° C./60 s | Butyl | — | 4.9 | B |
| | | | acetate | | | |
| 23 | 105° C./60 s | 105° C./60 s | Butyl | Decane | 4.9 | B |
| | | | acetate | | | |
| 24 | 90° C./60 s | 100° C./60 s | Butyl | — | 4.9 | B |
| | | | acetate | | | |
| 25 | 95° C./60 s | 100° C./60 s | Butyl | — | 4.9 | B |
| | | | acetate | | | |
| 26 | 90° C./60 s | 95° C./60 s | Pentyl | — | 4.9 | B |
| | | | acetate | | | |
| 27 | 90° C./60 s | 95° C./60 s | 2-Heptanone | 4-Methyl-2-pentanol | 4.9 | B |
| | | | acetate | | | |
| 28 | 90° C./60 s | 100° C./60 s | 2-Heptanone | — | 4.9 | B |
| | | | acetate | | | |
| 29 | 95° C./60 s | 90° C./60 s | Butyl | — | 4.9 | B |
| | | | acetate | | | |
| 30 | 100° C./60 s | 90° C./60 s | Butyl | 1-Octanol | 4.9 | B |
| | | | acetate | | | |
| 31 | 105° C./60 s | 100° C./60 s | Butyl | — | 4.9 | B |
| | | | acetate | | | |
| 32 | 100° C./60 s | 95° C./60 s | Butyl | — | 4.9 | B |
| | | | acetate | | | |
| 33 | 100° C./60 s | 95° C./60 s | Butyl | — | 4.4 | A |
| | | | acetate | | | |
| Comparative | 90° C./60 s | 95° C./60 s | Butyl | — | 8.5 | E |
| Example 1 | | | acetate | | | |

<Preparation 2 of Resist>

The components shown in Table 7 were dissolved in the solvents shown in the same table to have a solid content of 1.6% by mass, and each of the solutions was filtered through a polyethylene filter having a pore size of 0.05 μm, thereby to prepare actinic ray-sensitive or radiation-sensitive resin compositions (chemical amplification resist compositions) Ar-33 and Ar-34.

TABLE 7

| | Resin | | | | Basic | | | | | Mass |
|---|---|---|---|---|---|---|---|---|---|---|
| Resist | (A) | Mass/g | PAG | Mass/g | compound | Mass/g | Surfactant | Mass/g | Solvent | ratio |
| Ar-33 | Pol-22 | 10 | PAG-17 | 3.00 | N-3 | 0.90 | W-1 | 0.003 | SL-1/SL-3 | 60/40 |
| Ar-34 | Pol-23 | 10 | PAG-18 | 3.00 | N-7 | 0.90 | W-1 | 0.003 | SL-1/SL-3 | 60/40 |

Regarding the symbols in Table 7, those not described above are as follows.

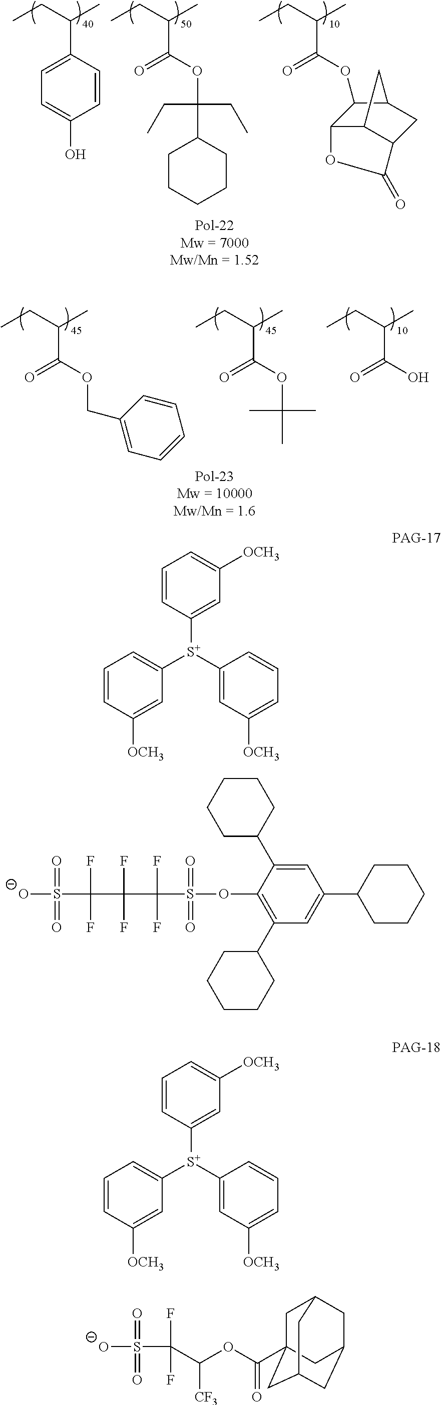

### Example 34

### Formation of Resist Film

In accordance with Example 1 above, the chemical amplification resist composition Ar-33 was subjected to evaluation of pattern formation, including ejecting the solvent (S), except that the exposure source was changed to EUV (extreme ultraviolet) rays, and thus, a good pattern could be formed.

### Example 35

In the same manner as above, formation of a resist pattern could also be carried out with the chemical amplification resist composition Ar-34 in Table 7.

Furthermore, the same evaluation as in Examples 1 to 3 except that a solution obtained by adding 2% by mass of tri-n-octylamine was added to butyl acetate was used as the developing liquid was carried out. In this case, formation of a good pattern could be formed.

In addition, formation of a pattern was carried out in the same manner as in Examples 1 to 3 except that the mask pattern was changed to form a trench pattern with line:space=3:1, and then a developing treatment using a 2.38%-by-mass aqueous tetramethylammonium hydroxide solution was further carried out, thereby obtaining a pattern in which only a region having an intermediate exposure amount remained.

What is claimed is:

1. A pattern forming method comprising:
a step of applying a solvent (S) onto a substrate;
a step of applying an actinic ray-sensitive or radiation-sensitive resin composition onto a substrate, on which the solvent (S) remains, to form an actinic ray-sensitive or radiation-sensitive film;
a step of exposing the actinic ray-sensitive or radiation-sensitive film; and
a step of developing the exposed actinic ray-sensitive or radiation-sensitive film with a developing liquid containing an organic solvent to form a negative-type pattern,
wherein the actinic ray-sensitive or radiation-sensitive resin composition contains a resin whose solubility in a developing liquid containing an organic solvent is decreased by the action of an acid, a compound capable of generating an acid by irradiation with actinic rays or radiation, and a solvent.

2. The pattern forming method according to claim 1, wherein the vapor pressure of the solvent (S) at 20° C. is 0.7 kPa or less.

3. The pattern forming method according to claim 1, wherein application of the solvent (S) is carried out by ejecting the solvent (S) onto the substrate, and application of the actinic ray-sensitive or radiation-sensitive resin composition is carried out by ejecting the composition onto the substrate, in which the method includes rotating the substrate at a predetermined time from the completion of ejection of the solvent (S) to the initiation of ejection of the actinic ray-sensitive or radiation-sensitive resin composition to form the liquid film of the solvent (S), the rotational speed is 3000 rpm or less, and further, the time taken from the completion of ejection of the solvent (S) to the initiation of ejection of the actinic ray-sensitive or radiation-sensitive resin composition is 7.0 seconds or less.

4. The pattern forming method according to claim 1, wherein the exposure is carried out through an immersion liquid.

5. The pattern forming method according to claim 1, wherein the exposure is carried out at a wavelength of 193 nm or less.

6. A method for manufacturing an electronic device, comprising the pattern forming method according to claim 1.

7. The pattern forming method according to claim 1, wherein a ratio of repeating unit containing an aromatic ring in the resin whose solubility in a developing liquid containing an organic solvent is decreased by the action of an acid is 0 to 5% by mole.

8. The pattern forming method according to claim 1, wherein the resin whose solubility in a developing liquid containing an organic solvent is decreased by the action of an acid contains neither a fluorine atom nor a silicon atom.

9. The pattern forming method according to claim 1, wherein the actinic ray-sensitive or radiation-sensitive resin composition further comprises a hydrophobic resin.

10. The pattern forming method according to claim 1, wherein the developing liquid containing an organic solvent for use in the step of developing contains at least one organic solvent selected from the group consisting of a ketone-based solvent and an ester-based solvent.

11. The pattern forming method according to claim 1, wherein the developing liquid containing an organic solvent for use in the step of developing contains at least either butyl acetate or 2-heptanone.
